(19) United States
(12) Patent Application Publication
(10) Pub. No.: US 2025/0246226 A1
(43) Pub. Date: Jul. 31, 2025

(54) SEMICONDUCTOR DEVICE

(71) Applicant: Semiconductor Energy Laboratory Co., Ltd., Atsugi-shi, Kanagawa-ken (JP)

(72) Inventors: Kazuma FURUTANI, Atsugi (JP); Hiromichi GODO, Isehara (JP); Yoshiyuki KUROKAWA, Sagamihara (JP)

(21) Appl. No.: 18/858,439

(22) PCT Filed: Apr. 28, 2023
(86) PCT No.: PCT/IB2023/054418

§ 371 Date: Oct. 21, 2024

(30) Foreign Application Priority Data
May 13, 2022 (JP) 2022-079149

(51) Int. Cl. G11C 11/4076; G11C 11/405; G11C 11/4096; H01L 25/065; H01L 25/18; H10B 12/00; H10B 80/00

(52) U.S. Cl. CPC G11C 11/4076; G11C 11/405; G11C 11/4096; H01L 25/0657; H01L 25/18; H10B 12/00; H10B 80/00; H01L 2225/06513; H01L 2225/06541

(57) ABSTRACT

A semiconductor device with high memory density and high reliability is provided. A first to a third layers are stacked in the semiconductor device. The first layer includes a delay signal generation circuit and a row circuit. The second layer includes a first delay addition circuit and a first memory cell, and the third layer includes a second delay addition circuit and a second memory cell. The delay signal generation circuit has a function of generating a first and a second delay signals representing a first and a second delay times, respectively, and supplying the first and the second delay signals to the first and the second delay addition circuits, respectively. The row circuit has a function of generating a row selection signal for selecting a first or a second memory cell performing reading operation and supplying it to the first or the second delay addition circuit. The first delay addition circuit has a function of supplying the row selection signal to the first memory cell after the first delay time elapses. The second delay addition circuit has a function of supplying the row selection signal to the second memory cell after the second delay time elapses. The first delay time is longer than the second delay time.

### TECHNICAL FIELD

One embodiment of the present invention relates to a semiconductor device. One embodiment of the present invention relates to a driving method of a semiconductor device. One embodiment of the present invention relates to a memory device. One embodiment of the present invention relates to a driving method of a memory device. One embodiment of the present invention relates to an electronic device.

Note that one embodiment of the present invention is not limited to the above technical field. The technical field of the invention disclosed in this specification and the like relates to an object, a method, or a manufacturing method. Alternatively, one embodiment of the present invention relates to a process, a machine, manufacture, or a composition of matter. Thus, more specifically, examples of the technical field of one embodiment of the present invention disclosed in this specification include a semiconductor device, a display device, a light-emitting device, a power storage device, a storage device, a driving method thereof, and a manufacturing method thereof.

### BACKGROUND ART

With a recent increase in the amount of data dealt with, memory devices having larger memory capacity have been required. To increase memory capacity per unit area, stacking memory cells as in the case of a 3D NAND memory device or the like is effective (see Patent Document 1 to Patent Document 3). Stacking memory cells can increase memory capacity per unit area in accordance with the number of stacked memory cells.

### REFERENCE

### Patent Document

[Patent Document 1] United States Patent Application Publication No. 2011/0065270
[Patent Document 2] United States Patent Application Publication No. 2016/0149004
[Patent Document 3] United States Patent Application Publication No. 2013/0069052

### SUMMARY OF THE INVENTION

### Problems to be Solved by the Invention

In a memory device in which, for example, a plurality of memory cell arrays are stacked over a silicon die provided with a driver circuit that controls writing and reading of data to/from memory cells, the wiring distances from the driver circuit to the memory cell arrays vary depending on tiers of the memory cell arrays. Specifically, the wiring distance from the driver circuit to the memory cell array becomes longer as the tier where the memory cell array is provided gets higher. As the wiring distance becomes longer, the wiring resistance increases; thus, in some cases, the time from when a signal is generated by the driver circuit to when the signal is supplied to a memory cell array and the time from when data is read from the memory cell array to when the data is supplied to the driver circuit become longer. For this reason, for example, when data needs to be read at the same time from two memory cell arrays provided in different blocks in different tiers, the data is not read at the same time in some cases. Specifically, data retained in a memory cell in an upper tier is read at a lower speed than data retained in a memory cell in a lower tier in some cases. This might cause a malfunction of the semiconductor device.

One object of one embodiment of the present invention is to provide a highly reliable semiconductor device. Another object of one embodiment of the present invention is to provide a semiconductor device having large memory capacity. Another object of one embodiment of the present invention is to provide a semiconductor device having high memory density. Another object of one embodiment of the present invention is to provide a small-size semiconductor device. Another object of one embodiment of the present invention is to provide a semiconductor device with low power consumption. Another object of one embodiment of the present invention is to provide a novel semiconductor device.

Note that the objects of one embodiment of the present invention are not limited to the objects listed above. The objects listed above do not preclude the presence of other objects. Note that the other objects are objects that are not described in this section and will be described below. The objects that are not described in this section can be derived from the description of the specification, the drawings, and the like and can be extracted as appropriate from the description by those skilled in the art. Note that one embodiment of the present invention is to achieve at least one of the objects listed above and/or the other objects.

### Means for Solving the Problems

One embodiment of the present invention is a semiconductor device including a first layer, a second layer over the first layer, and a third layer over the second layer. The first layer includes a delay signal generation circuit and a row circuit. The second layer includes a first delay addition circuit and a first memory portion where first memory cells are arranged in a matrix. The third layer includes a second delay addition circuit and a second memory portion where second memory cells are arranged in a matrix. The delay signal generation circuit has a function of generating a first delay signal representing a first delay time and supplying it to the first delay addition circuit and has a function of generating a second delay signal representing a second delay time and supplying it to the second delay addition circuit. The row circuit has a function of generating a row selection signal for selecting the first or the second memory cell performing reading operation and supplying it to the first or the second delay addition circuit. The first delay addition circuit has a function of supplying the row selection signal supplied to the first delay addition circuit to the first memory portion after the first delay time elapses. The second delay addition circuit has a function of supplying the row selection signal supplied to the second delay addition circuit to the second memory portion after the second delay time elapses. The first delay time is longer than the second delay time.

One embodiment of the present invention is a semiconductor device including a first layer, a second layer over the first layer, and a third layer over the second layer. The first layer includes a selection signal generation circuit, a delay signal generation circuit, and a row circuit. The second layer includes a first selection circuit, a first delay addition circuit, and a first memory portion where first memory cells are arranged in a matrix. The third layer includes a second selection circuit, a second delay addition circuit, and a second memory portion where second memory cells are arranged in a matrix. The selection signal generation circuit has a function of generating a selection signal and supplying it to the delay signal generation circuit, the first selection circuit, and the second selection circuit. The delay signal generation circuit has a function of generating a first delay signal representing a first delay time and a function of generating a second delay signal representing a second delay time. The delay signal generation circuit has a function of outputting one of the first delay signal and the second delay signal on the basis of the selection signal and supplying it to the first delay addition circuit and the second delay addition circuit. The row circuit has a function of generating a row selection signal for selecting the first or the second memory cell performing reading operation. The row circuit has a function of supplying the row selection signal to the first selection circuit and the second selection circuit. The first selection circuit has a function of supplying the row selection signal to the first delay addition circuit in the case where the delay signal generation circuit outputs the first delay signal. The second selection circuit has a function of supplying the row selection signal to the second delay addition circuit in the case where the delay signal generation circuit outputs the second delay signal. The first delay addition circuit has a function of supplying the row selection signal supplied to the first delay addition circuit to the first memory portion after the first delay time elapses. The second delay addition circuit has a function of supplying the row selection signal supplied to the second delay addition circuit to the second memory portion after the second delay time elapses. The first delay time is longer than the second delay time.

In the above embodiments, the first layer may include a reference signal generation circuit. The second layer may include a first buffer circuit. The third layer may include a second buffer circuit. The reference signal generation circuit may have a function of generating a reference signal and supplying it to the delay signal generation circuit, the first buffer circuit, and the second buffer circuit. The first buffer circuit may have a function of supplying the reference signal supplied to the first buffer circuit to the delay signal generation circuit as a first delay time detection signal. The second buffer circuit may have a function of supplying the reference signal supplied to the second buffer circuit to the delay signal generation circuit as a second delay time detection signal. The delay signal generation circuit may have a function of generating a first digital signal representing a difference between a first moment when the reference signal is input and a second moment when the first delay time detection signal is input and generating the first delay signal on the basis of the first digital signal. The delay signal generation circuit may have a function of generating a second digital signal representing a difference between the first moment and a third moment when the second delay time detection signal is input and generating the second delay signal on the basis of the second digital signal.

In the above embodiments, the delay signal generation circuit may include a first inverter circuit and a second inverter circuit. The first inverter circuit may have a function of generating the first delay signal in the case where the first digital signal is supplied to the first inverter circuit. The second inverter circuit may have a function of generating the second delay signal in the case where the second digital signal is supplied to the second inverter circuit.

In the above embodiments, the delay signal generation circuit may include a first transistor. The first memory cell may include a second transistor. The second memory cell may include a third transistor. The first transistor may include silicon in a channel formation region. The second transistor and the third transistor may each include metal oxide in a channel formation region.

One embodiment of the present invention is a semiconductor device including a first block and a second block. The first block includes a first layer, a second layer over the first layer, and a third layer over the second layer. The second block includes a fourth layer, a fifth layer over the fourth layer, and a sixth layer over the fifth layer. The first layer includes a first delay signal generation circuit and a first row circuit. The second layer includes a first delay addition circuit and a first memory portion where first memory cells are arranged in a matrix. The third layer includes a second delay addition circuit and a second memory portion where second memory cells are arranged in a matrix. The fourth layer includes a second delay signal generation circuit and a second row circuit. The fifth layer includes a third delay addition circuit and a third memory portion where third memory cells are arranged in a matrix. The sixth layer includes a fourth delay addition circuit and a fourth memory portion where fourth memory cells are arranged in a matrix. The first delay signal generation circuit has a function of generating a first delay signal representing a first delay time and supplying it to the first delay addition circuit and a function of generating a second delay signal representing a second delay time and supplying it to the second delay addition circuit. The second delay signal generation circuit has a function of generating a third delay signal representing a third delay time and supplying it to the third delay addition circuit and a function of generating a fourth delay signal representing a fourth delay time and supplying it to the fourth delay addition circuit. The first row circuit has a function of generating a first row selection signal for selecting the first or the second memory cell performing reading operation and supplying it to the first or the second delay addition circuit. The second row circuit has a function of generating a second row selection signal for selecting the third or the fourth memory cell performing reading operation and supplying it to the third or the fourth delay addition circuit. The first delay addition circuit has a function of supplying the first row selection signal supplied to the first delay addition circuit to the first memory portion after the first delay time elapses. The second delay addition circuit has a function of supplying the first row selection signal supplied to the second delay addition circuit to the second memory portion after the second delay time elapses. The third delay addition circuit has a function of supplying the second row selection signal supplied to the third delay addition circuit to the third memory portion after the third delay time elapses. The fourth delay addition circuit has a function of supplying the second row selection signal supplied to the fourth delay addition circuit to the fourth memory portion after the fourth delay time elapses. The first delay time is longer than the second delay time. The third delay time is longer than the fourth delay time.

One embodiment of the present invention is a semiconductor device including a first block and a second block. The first block includes a first layer, a second layer over the first layer, and a third layer over the second layer. The second block includes a fourth layer, a fifth layer over the fourth layer, and a sixth layer over the fifth layer. The first layer includes a first selection signal generation circuit, a first delay signal generation circuit, and a first row circuit. The second layer includes a first selection circuit, a first delay addition circuit, and a first memory portion where first memory cells are arranged in a matrix. The third layer includes a second selection circuit, a second delay addition circuit, and a second memory portion where second memory cells are arranged in a matrix. The fourth layer includes a second selection signal generation circuit, a second delay signal generation circuit, and a second row circuit. The fifth layer includes a third selection circuit, a third delay addition circuit, and a third memory portion where third memory cells are arranged in a matrix. The sixth layer includes a fourth selection circuit, a fourth delay addition circuit, and a fourth memory portion where fourth memory cells are arranged in a matrix. The first selection signal generation circuit has a function of generating a first selection signal and supplying it to the first delay signal generation circuit, the first selection circuit, and the second selection circuit. The second selection signal generation circuit has a function of generating a second selection signal and supplying it to the second delay signal generation circuit, the third selection circuit, and the fourth selection circuit. The first delay signal generation circuit has a function of generating a first delay signal representing a first delay time and a function of generating a second delay signal representing a second delay time. The first delay signal generation circuit has a function of outputting one of the first delay signal and the second delay signal on the basis of the first selection signal and supplying it to the first delay addition circuit and the second delay addition circuit. The second delay signal generation circuit has a function of generating a third delay signal representing a third delay time and a function of generating a fourth delay signal representing a fourth delay time. The second delay signal generation circuit has a function of outputting one of the third delay signal and the fourth delay signal on the basis of the second selection signal and supplying it to the third delay addition circuit and the fourth delay addition circuit. The first row circuit has a function of generating a first row selection signal for selecting the first or the second memory cell performing reading operation. The first row circuit has a function of supplying the first row selection signal to the first selection circuit and the second selection circuit. The second row circuit has a function of generating a second row selection signal for selecting the third or the fourth memory cell performing reading operation. The second row circuit has a function of supplying the second row selection signal to the third selection circuit and the fourth selection circuit. The first selection circuit has a function of supplying the first row selection signal to the first delay addition circuit in the case where the first delay signal generation circuit outputs the first delay signal. The second selection circuit has a function of supplying the first row selection signal to the second delay addition circuit in the case where the first delay signal generation circuit outputs the second delay signal. The third selection circuit has a function of supplying the second row selection signal to the third delay addition circuit in the case where the second delay signal generation circuit outputs the third delay signal. The fourth selection circuit has a function of supplying the second row selection signal to the fourth delay addition circuit in the case where the second delay signal generation circuit outputs the fourth delay signal. The first delay addition circuit has a function of supplying the first row selection signal supplied to the first delay addition circuit to the first memory portion after the first delay time elapses. The second delay addition circuit has a function of supplying the first row selection signal supplied to the second delay addition circuit to the second memory portion after the second delay time elapses. The third delay addition circuit has a function of supplying the second row selection signal supplied to the third delay addition circuit to the third memory portion after the third delay time elapses. The fourth delay addition circuit has a function of supplying the second row selection signal supplied to the fourth delay addition circuit to the fourth memory portion after the fourth delay time elapses. The first delay time is longer than the second delay time. The third delay time is longer than the fourth delay time.

In the above embodiments, the first layer may include a first reference signal generation circuit. The second layer may include a first buffer circuit. The third layer may include a second buffer circuit. The fourth layer may include a second reference signal generation circuit. The fifth layer may include a third buffer circuit. The sixth layer may include a fourth buffer circuit. The first reference signal generation circuit may have a function of generating a first reference signal and supplying it to the first delay signal generation circuit, the first buffer circuit, and the second buffer circuit. The second reference signal generation circuit may have a function of generating a second reference signal and supplying it to the second delay signal generation circuit, the third buffer circuit, and the fourth buffer circuit. The first buffer circuit may have a function of supplying the first reference signal supplied to the first buffer circuit to the first delay signal generation circuit as a first delay time detection signal. The second buffer circuit may have a function of supplying the first reference signal supplied to the second buffer circuit to the first delay signal generation circuit as a second delay time detection signal. The third buffer circuit may have a function of supplying the second reference signal supplied to the third buffer circuit to the second delay signal generation circuit as a third delay time detection signal. The fourth buffer circuit may have a function of supplying the second reference signal supplied to the fourth buffer circuit to the second delay signal generation circuit as a fourth delay time detection signal. The first delay signal generation circuit may have a function of generating a first digital signal representing a difference between a first moment when the first reference signal is input and a second moment when the first delay time detection signal is input and generating the first delay signal on the basis of the first digital signal. The first delay signal generation circuit may have a function of generating a second digital signal representing a difference between the first moment and a third moment when the second delay time detection signal is input and generating the second delay signal on the basis of the second digital signal. The second delay signal generation circuit may have a function of generating a third digital signal representing a difference between a third moment when the second reference signal is input and a fourth moment when the third delay time detection signal is input and generating the third delay signal on the basis of the third digital signal. The second delay signal generation circuit may have a function of generating a fourth digital signal representing a difference between the third moment and a fourth moment when the fourth delay time detection signal is input and generating the fourth delay signal on the basis of the fourth digital signal.

In the above embodiment, the first delay signal generation circuit may include a first inverter circuit and a second inverter circuit. The second delay signal generation circuit may include a third inverter circuit and a fourth inverter circuit. The first inverter circuit may include a function of generating the first delay signal in the case where the first digital signal is supplied to the first inverter circuit. The second inverter circuit may include a function of generating the second delay signal in the case where the second digital signal is supplied to the second inverter circuit. The third inverter circuit may include a function of generating the third delay signal in the case where the third digital signal is supplied to the third inverter circuit. The fourth inverter circuit may include a function of generating the fourth delay signal in the case where the fourth digital signal is supplied to the fourth inverter circuit.

In the above embodiments, the first delay signal generation circuit may include a first transistor. The first memory cell may include a second transistor. The second memory cell may include a third transistor. The second delay signal generation circuit may include a fourth transistor. The third memory cell may include a fifth transistor. The fourth memory cell may include a sixth transistor. The first transistor and the fourth transistor may each include silicon in a channel formation region. The second transistor, the third transistor, the fifth transistor, and the sixth transistor may each include metal oxide in a channel formation region.

In the above embodiments, a timing when the first row circuit outputs the first row selection signal and a timing when the second row circuit outputs the second row selection signal may be synchronized.

### Effect of the Invention

One embodiment of the present invention can provide a highly reliable semiconductor device. Another embodiment of the present invention can provide a semiconductor device with large memory capacity. Another embodiment of the present invention can provide a semiconductor device having high memory density. Another embodiment of the present invention can provide a small-size semiconductor device. Another embodiment of the present invention can provide a semiconductor device with low power consumption. Another embodiment of the present invention can provide a novel semiconductor device.

Note that the description of these effects does not preclude the existence of other effects. One embodiment of the present invention does not need to have all these effects. Other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1 is a perspective view illustrating a structure example of a semiconductor device.

FIG. 2 is a perspective view illustrating a structure example of a semiconductor device.

FIG. 3 is a cross-sectional view illustrating a structure example of a semiconductor device.

FIG. 4 is a block diagram illustrating a configuration example of a semiconductor device.

FIG. 5A is a block diagram illustrating a configuration example of a semiconductor device. FIG. 5B is a timing chart showing an example of a driving method of the semiconductor device.

FIG. 6 is a block diagram illustrating a configuration example of a semiconductor device.

FIG. 7 is a circuit diagram illustrating a configuration example of a semiconductor device.

FIG. 8A is a circuit diagram illustrating a configuration example of an inverter circuit. FIG. 8B is a circuit diagram illustrating a configuration example of a delay circuit.

FIG. 9 is a perspective view illustrating a structure example of a semiconductor device.

FIG. 10 is a perspective view illustrating a structure example of a semiconductor device.

FIG. 11 is a cross-sectional view illustrating a structure example of a semiconductor device.

FIG. 12A is a block diagram illustrating a configuration example of a semiconductor device. FIG. 12B is a circuit diagram illustrating a configuration example of a memory cell.

FIG. 13A to FIG. 13D are circuit diagrams each illustrating a configuration example of a memory cell.

FIG. 14 is a cross-sectional view illustrating a structure example of a semiconductor device.

FIG. 15A to FIG. 15C are cross-sectional views each illustrating a structure example of a transistor.

FIG. 16 is a cross-sectional view illustrating a structure example of a semiconductor device.

FIG. 17A is a cross-sectional view illustrating a structure example of a semiconductor device.

FIG. 17B is a circuit diagram illustrating a configuration example of a memory cell.

FIG. 18 is a cross-sectional view illustrating a structure example of a semiconductor device.

FIG. 19A is a cross-sectional view illustrating a structure example of a semiconductor device.

FIG. 19B is a circuit diagram illustrating a configuration example of a memory cell.

FIG. 20A and FIG. 20B are diagrams each illustrating an example of an electronic component.

FIG. 21A and FIG. 21B are diagrams each illustrating an example of an electronic device. FIG. 21C to FIG. 21E are diagrams illustrating an example of a large computer.

FIG. 22 is a diagram illustrating an example of a device for space.

FIG. 23 is a diagram illustrating an example of a storage system that can be used in a data center.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

In addition, in the drawings, the size, the layer thickness, or the region is exaggerated for clarity in some cases. Therefore, the size, the layer thickness, or the region is not limited to the illustrated scale. Note that the drawings schematically illustrate ideal examples, and embodiments of the present invention are not limited to shapes, values, and the like illustrated in the drawings.

Furthermore, unless otherwise specified, off-state current in this specification and the like refers to drain current of a transistor in an off state (also referred to as a non-conduction state or a cutoff state). Unless otherwise specified, an off state in an n-channel transistor refers to a state where voltage V_{gs} between its gate and source is lower than threshold voltage Vₜₕ (in a p-channel transistor, higher than Vₜₕ).

In this specification and the like, a metal oxide is an oxide of metal in a broad sense. Metal oxides are classified into an oxide insulator, an oxide conductor (including a transparent oxide conductor), an oxide semiconductor (also simply referred to as an OS), and the like. For example, in the case where a metal oxide is used for an active layer of a transistor, the metal oxide is referred to as an oxide semiconductor in some cases. That is, in the case where an OS transistor is stated, the OS transistor can also be referred to as a transistor including a metal oxide or an oxide semiconductor.

### Embodiment 1

In this embodiment, structure examples of a semiconductor device will be described. A semiconductor device described in one embodiment of the present invention can be a memory device, for example.

One embodiment of the present invention relates to a semiconductor device including a plurality of blocks. In each block, a plurality of layers each including a memory portion in which memory cells are arranged in a matrix are stacked over a layer including a driver circuit. Stacking the plurality of memory portions can increase the memory capacity per unit area when the semiconductor device is seen from above, for example. Thus, the memory density of the semiconductor device can be higher than that in the case where only one memory portion is provided. Furthermore, the semiconductor device can be downsized while the memory capacity is ensured. Note that since the memory cells are arranged in a matrix in the memory portion, the memory portion is also referred to as a memory cell array.

The driver circuit has a function of controlling writing and reading of data to/from the memory cells. Here, the wiring distances from the driver circuit to the memory cells vary depending on tiers where the memory cells are included even when the memory cells are located in the same row and the same column. Specifically, the wiring distance from the driver circuit to the memory cell becomes longer as the tier where the memory cell is provided gets higher. As the wiring distance becomes longer, the wiring resistance increases; thus, in some cases, the time from when a signal is generated by the driver circuit to when the signal is supplied to a memory cell and the time from when data is read from the memory cell to when the data is supplied to the driver circuit become longer. For this reason, for example, when data needs to be read at the same time from a plurality of memory cells provided in different blocks in different tiers, the data is not read at the same time in some cases. Specifically, data retained in a memory cell in an upper tier is read at a lower speed than data retained in a memory cell in a lower tier in some cases. This might cause a malfunction of the semiconductor device.

In view of the above, in the semiconductor device of one embodiment of the present invention, a delay addition circuit is provided for each layer including memory cells. A signal generated by the driver circuit is supplied to the delay addition circuit. The signal supplied to the delay addition circuit is supplied to a memory cell after a predetermined time. Thus, it can be said that the delay addition circuit has a function of adding a predetermined delay time to a signal generated by the driver circuit. Here, the delay addition circuit provided in a lower tier adds a longer delay time to the signal generated by the driver circuit. In the case where the delay addition circuit is not provided in the semiconductor device, as described above, the time from the generation of a signal by the driver circuit to the supply of the signal to the memory cell is longer as the memory cell is provided in an upper tier. Accordingly, by providing the delay addition circuit in the semiconductor device of one embodiment of the present invention, for example, the time from when the signal is generated by the driver circuit and supplied to the memory cell to when the data is read from the memory cell in accordance with the signal can be equal or substantially equal across the layers including memory cells. Thus, for example, data can be read at the same time or substantially at the same time from a plurality of memory cells provided in different blocks in different tiers. In the above manner, a malfunction of the semiconductor device is inhibited, and a highly reliable semiconductor device can be provided.

Accordingly, the semiconductor device of one embodiment of the present invention can have a high memory density and high reliability.

### Structure Example_1 of Semiconductor Device

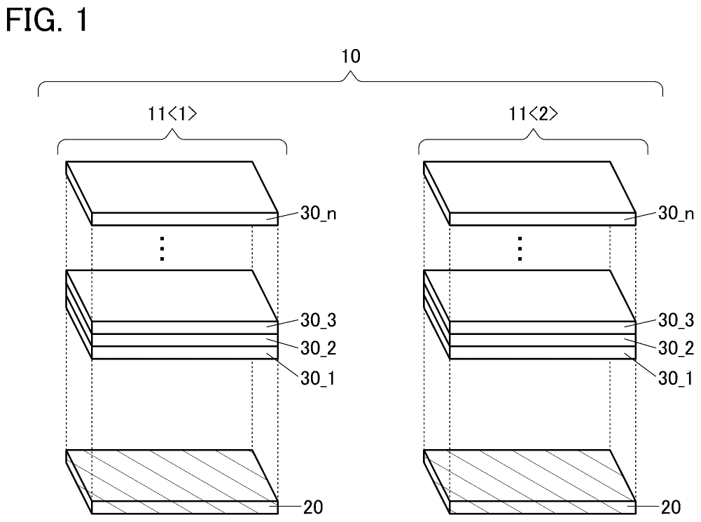

FIG. 1 is a perspective view illustrating a structure example of a semiconductor device 10 that is the semiconductor device of one embodiment of the present invention. The semiconductor device 10 can be a memory device, for example.

The semiconductor device 10 includes a block 11<1> and a block 11<2>. Each of the block 11<1> and the block 11<2> includes a layer 20 and a layer 30_1 to a layer 30_n (n is an integer greater than or equal to 2). The layer 30_1 to the layer 30_n are stacked in this order over the layer 20. FIG. 1 illustrates the layer 301, the layer 302, the layer 303, and the layer 30_n as the layers 30. Note that the semiconductor device 10 may include three or more blocks 11. Alternatively, the semiconductor device 10 may include only one block 11.

In this specification and the like, when a plurality of components are denoted by the same reference numeral and in particular need to be distinguished from each other, an identification sign such as “< >”, “_”, or “( )” is sometimes added to the reference numerals. For example, two blocks 11 are distinguished from each other by being referred to as the block 11<1> and the block 11<2>. Furthermore, the n layers 30 are distinguished from each other by being referred to as the layer 30_1 to the layer 30_n.

In different blocks 11, layers denoted by the same reference numeral are provided in the same tier. For example, the layer 20 in the block 11<1> and the layer 20 in the block 11<2> are provided in the same tier. The layer 301 in the block 11<1> and the layer 301 in the block 11<2> are provided in the same tier. In contrast, the layer 30_1 in the block 11<1> and the layer 30_n in the block 11<1> are provided in different tiers.

In each of the layer 301 to the layer 30_n, memory cells (not illustrated) are arranged in a matrix. The layer 20 is provided with a driver circuit (not illustrated) having a function of controlling writing and reading of data to/from a memory cell.

In the semiconductor device 10 illustrated in FIG. 1, data retained in a memory cell in the block 11<1> and data retained in a memory cell in the block 11<2> can be read in parallel. That is, data retained in a plurality of memory cells provided in the different blocks 11 can be read in parallel. Here, between the different blocks 11, data can be read in parallel from the plurality of memory cells provided in the layers 30 in different tiers. For example, data retained in a memory cell in the layer 30_1 in the block 11<1> and data retained in a memory cell in the layer 30_3 in the block 11<2> can be read in parallel.

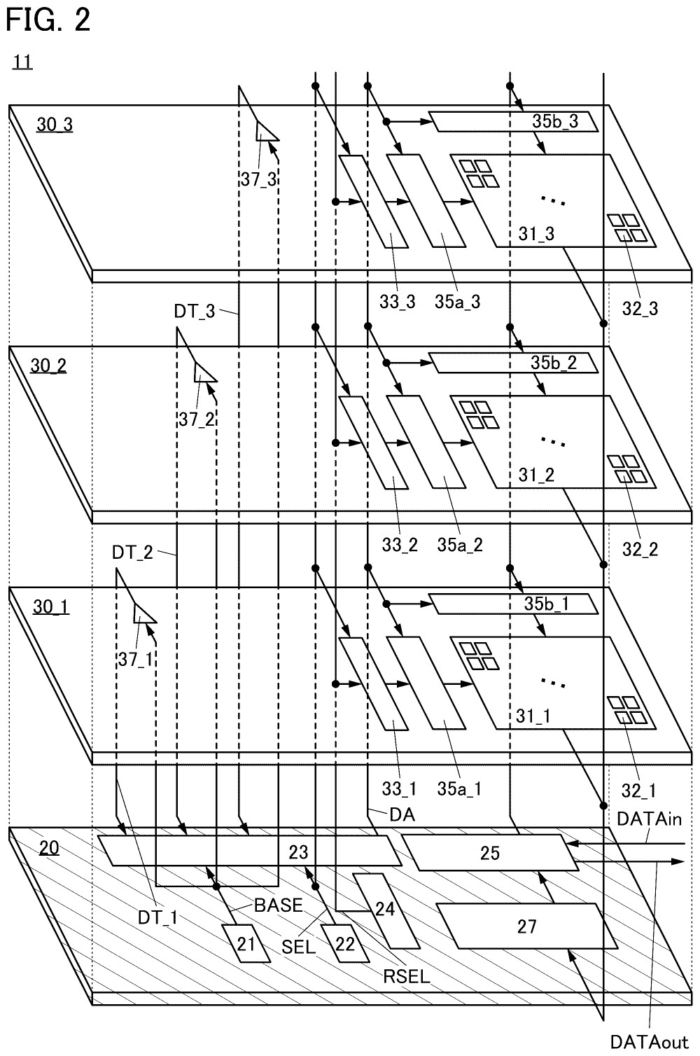

FIG. 2 is a perspective view illustrating a structure example of the block 11. Specifically, FIG. 2 illustrates structure examples of the layer 20, the layer 301, the layer 302, and the layer 30_3. As illustrated in FIG. 2, the layer 301 is provided over the layer 20, the layer 302 is provided over layer 301, and the layer 303 is provided over the layer 302.

The layer 20 includes a reference signal generation circuit 21, a selection signal generation circuit 22, a delay signal generation circuit 23, a row circuit 24, a column circuit 25, and a sense amplifier circuit 27. The layer 30_1 includes a memory portion 31_1, a selection circuit 33_1, a delay addition circuit 35a_1, a delay addition circuit 35b_1, and a buffer circuit 37_1. In the memory portion 31_1, memory cells 32_1 are arranged in a matrix. The layer 30_2 includes a memory portion 312, a selection circuit 332, a delay addition circuit 35a_2, a delay addition circuit 35b_2, and a buffer circuit 37_2. In the memory portion 312, memory cells 32_2 are arranged in a matrix. The layer 30_3 includes a memory portion 313, a selection circuit 33_3, a delay addition circuit 35a_3, a delay addition circuit 35b_3, and a buffer circuit 37_3. In the memory portion 31_3, memory cells 32_3 are arranged in a matrix. Although not illustrated in FIG. 2, the memory cell 32 is electrically connected to the delay addition circuit 35a row by row through a word line and electrically connected to the delay addition circuit 35b and the sense amplifier circuit 27 column by column through a bit line.

A circuit provided in the layer 20 and a circuit provided in the layer 30 are circuits for controlling the driving of the semiconductor device 10. Thus, the circuit provided in the layer 20 and the circuit provided in the layer 30 can be referred to as driver circuits. Alternatively, circuits excluding the memory cell 32 among the circuits provided in the layer 20 and the circuits provided in the layer 30 may be referred to as driver circuits.

In FIG. 2, flows of a signal or data between components of the block 11 are indicated by arrows. Here, the signal or data indicated by the arrow is not limited to a 1-bit digital signal or 1-bit digital data, and may be a 2-bit or more digital signal or 2-bit or more digital data, for example. Note that the exchange of the signals or data shown in FIG. 2 is an example, and the signals or data can be sometimes exchanged between components that are not connected by an arrow, for example. Signals or data can be sometimes exchanged between components connected by an arrow in a direction opposite to that of the arrow. The same applies to the drawings other than FIG. 2.

The reference signal generation circuit 21 has a function of generating a reference signal BASE and supplying it to the delay signal generation circuit 23 and the buffer circuit 37. The reference signal BASE can be a 1-bit digital signal, for example.

The buffer circuit 37 includes an input terminal and an output terminal, and has a function of supplying the reference signal BASE supplied to the input terminal to the delay signal generation circuit 23 as a delay time detection signal DT. For example, the reference signal BASE supplied to an input terminal of the buffer circuit 37_1 is output from an output terminal of the buffer circuit 37_1 as the delay time detection signal DT_1, and supplied to the delay signal generation circuit 23. The reference signal BASE supplied to an input terminal of the buffer circuit 37_2 is output from an output terminal of the buffer circuit 37_2 as the delay time detection signal DT_2, and supplied to the delay signal generation circuit 23. Furthermore, the reference signal BASE supplied to an input terminal of the buffer circuit 37_3 is output from an output terminal of the buffer circuit 37_3 as the delay time detection signal DT_3, and supplied to the delay signal generation circuit 23. Note that the buffer circuit 37 is not necessarily provided in the layer 30.

The selection signal generation circuit 22 has a function of generating a selection signal SEL and supplying it to the delay signal generation circuit 23 and the selection circuit 33. The delay signal generation circuit 23 has a function of generating a delay signal DA on the basis of the reference signal BASE and the delay time detection signal DT and supplying it to the delay addition circuit 35a and the delay addition circuit 35b. Specifically, the delay signal generation circuit 23 has a function of generating the delay signal DA on the basis of the reference signal BASE and any one of the plurality of delay time detection signals DT and supplying it to all of the delay addition circuits 35a and the delay addition circuits 35b included in the block 11, for example. The delay signal DA is a signal for determining time, and is generated on the basis of a difference between the first moment when the reference signal BASE is supplied to the delay signal generation circuit 23 and the second moment when the delay time detection signal DT is supplied to the delay signal generation circuit 23. Although the details will be described later, as the difference between the times becomes larger, the time determined by the delay signal DA becomes shorter.

In this specification and the like, a difference in time refers to an absolute value of the difference in time.

The delay time detection signal DT that is used for generating the delay signal DA is selected by the selection signal SEL. For example, the delay signal generation circuit 23 generates the delay signal DA using the reference signal BASE, the selection signal SEL, and any one of the delay time detection signal DT_1 to the delay time detection signal DT_3 which is selected by the selection signal SEL.

The row circuit 24 has a function of generating a row selection signal RSEL and supplying it to the selection circuit 33. The row selection signal RSEL is a signal for selecting the memory cell 32 to which data is written or the memory cell 32 from which data is read among the memory cells 32 arranged in a matrix. Specifically, the row selection signal RSEL is a signal for selecting a row of the memory cells 32 to which data is to be written or a row of the memory cells 32 from which data is to be read. The row selection signal RSEL is supplied to all the selection circuits 33 included in the block 11, for example. Here, the row selection signal RSEL is supplied to the memory cell 32 through the above-described word line. Thus, the row circuit 24 can be referred to as a word line driver circuit.

The column circuit 25 has a function of writing data DATAin to the memory cell 32 through the delay addition circuit 35b. The column circuit 25 also has a function of outputting data read from the memory cell 32 as data DATAout. Furthermore, the column circuit 25 has a function of generating a precharge signal for precharging the bit line before data is read from the memory cell 32 and supplying it to the delay addition circuit 35b.

As described above, the row circuit 24 and the column circuit 25 have a function of controlling writing and reading of data to/from the memory cells 32.

The sense amplifier circuit 27 has a function of amplifying data read from the memory cell 32. In the case where data is read from the memory cell 32, first, the column circuit 25 generates a precharge signal as described above, so that the potential of the bit line is set to a precharge potential. Next, the potential of the bit line is set to a potential corresponding to data to be read. For example, in the case where 1-bit digital data is retained in the memory cell 32, the potential of the bit line is set to a data potential higher than the precharge potential when data whose digital value is “1” is read, and the potential of the bit line is set to a data potential lower than the precharge potential when data whose digital value is “0” is read. After that, the sense amplifier circuit 27 amplifies a difference between the data potential and the precharge potential. The amplified data is output as the data DATAout from the column circuit 25. For example, in the case where the data DATAout is 1-bit digital data, the potential of a signal representing the data DATAout becomes a high potential when the digital value of the data DATAout is “1”, and the potential of the signal representing the data DATAout becomes a low potential when the digital value of the data DATAout is “0”.

In this specification and the like, not all potentials described as high potentials are necessarily the same potential, and not all potentials described as low potentials are necessarily the same potential. For example, in the case where a high power supply potential is supplied to one of a source and a drain of a transistor in an on state, the potential of the other of the source and the drain of the transistor might be lower than the high power supply potential because of the resistance between the drain and the source of the transistor, for example. Even in such a case, the potentials of both the source and the drain of the transistor can sometimes be referred to as high potentials.

As described above, writing of data to the memory cell 32 and reading of data from the memory cell 32 are performed using the column circuit 25 through the bit line. Thus, the column circuit 25 can be referred to as a bit line driver circuit.

In this specification and the like, operations from generation of a row selection signal by a row circuit and generation of a precharge signal by a column circuit to output of data by the column circuit are referred to as reading operations.

The selection circuit 33 has a function of determining whether the row selection signal RSEL is supplied to the delay addition circuit 35a on the basis of the selection signal SEL. Specifically, the row selection signal RSEL is supplied to the delay addition circuit 35a from one selection circuit 33 among the n selection circuits 33 included in the block 11. For example, in the case where the selection circuit 331 outputs the row selection signal RSEL and supplies it to the delay addition circuit 35a_1, the other selection circuits 33 included in the block 11 do not output the row selection signal RSEL. Thus, the row selection signal RSEL is not supplied to the delay addition circuits 35a other than the delay addition circuit 35a_1. For example, the row selection signal RSEL is not supplied to the delay addition circuit 35a_2, the delay addition circuit 35a_3, and the like.

In the above manner, the row selection signal RSEL generated by the row circuit 24 is supplied to the delay addition circuit 35a through the selection circuit 33. Here, in this specification and the like, the description “the row circuit 24 has a function of supplying the row selection signal RSEL to the delay addition circuit 35a” includes the case where the row circuit 24 supplies the row selection signal RSEL to the delay addition circuit 35a through the selection circuit 33.

Here, a signal used by the delay signal generation circuit 23 to select the delay time detection signal DT used for generating the delay signal DA and a signal used by the selection circuit 33 to determine whether the row selection signal RSEL is output and supplied to the delay addition circuit 35a are both the selection signal SEL and the same signal. Thus, the delay time detection signal DT used for generating the delay signal DA and the selection circuit 33 which outputs the row selection signal RSEL can correspond to each other. For example, in the case where the delay signal generation circuit 23 generates the delay signal DA using the delay time detection signal DT_1, the selection circuit 331 outputs the row selection signal RSEL to the delay addition circuit 35a_1. In the case where the delay signal generation circuit 23 generates the delay signal DA using the delay time detection signal DT_2, the selection circuit 33_2 outputs the row selection signal RSEL to the delay addition circuit 35a_2. Furthermore, in the case where the delay signal generation circuit 23 generates the delay signal DA using the delay time detection signal DT_3, the selection circuit 33_3 outputs the row selection signal RSEL to the delay addition circuit 35a_3.

The delay addition circuit 35a has a function of supplying the row selection signal RSEL to the memory portion 31, specifically, to the memory cell 32. Note that the row selection signal RSEL is output from the delay addition circuit 35a after a predetermined time has elapsed since being supplied to the delay addition circuit 35a. The predetermined time is determined by the delay signal DA. For example, the delay addition circuit 35a_1 has a function of supplying the row selection signal RSEL to the memory portion 31_1, specifically, to the memory cell 321. The row selection signal RSEL is output from the delay addition circuit 35a_1 after the predetermined time has elapsed since being supplied to the delay addition circuit 35a_1.

The delay addition circuit 35b has a function of, for example, outputting a precharge signal after the predetermined time, which is determined by the delay signal DA, has elapsed since the precharge signal is supplied to the delay addition circuit 35b. The precharge signal output from the delay addition circuit 35b is supplied to a bit line electrically connected to the memory cell 32. The delay addition circuit 35b_1 has a function of, for example, outputting a precharge signal supplied to the delay addition circuit 35b_1 after the predetermined time elapses to a bit line electrically connected to the memory cell 32_1.

Accordingly, the delay addition circuit 35a and the delay addition circuit 35b have a function of adding a delay for the predetermined time determined by the delay signal DA to a signal input thereto and outputting it. Thus, the delay signal DA is also referred to as a delay addition signal. The predetermined time can be referred to as a delay time.

The semiconductor device 10 illustrated in FIG. 1 and FIG. 2 includes a plurality of blocks 11. In each block 11, a plurality of layers 30 each including the memory portion 31 in which memory cells are arranged in a matrix are stacked over the layer 20 including a driver circuit. Stacking the plurality of memory portions 31 can increase the memory capacity per unit area when the semiconductor device 10 is seen from above, for example. Thus, the memory density of the semiconductor device can be higher than that in the case where only one layer 30 including the memory portion 31 is provided. Furthermore, the semiconductor device can be downsized while the memory capacity is ensured.

Here, the wiring distances from the circuit provided in the layer 20 to the memory cells 32 vary depending on tiers of the layers 30 even when the memory cells 32 are located in the same row and the same column. For example, the wiring distance from the row circuit 24 to the memory cell 32 and the wiring distance from the column circuit 25 to the memory cell 32 vary depending on the tiers of the layers 30. Specifically, the wiring distance from the row circuit 24 to the memory cell 32 and the wiring distance from the column circuit 25 to the memory cell 32 become longer as the tier of the layer 30 where the memory cell 32 is provided gets higher. As the wiring distance becomes longer, the wiring resistance increases; thus, in some cases, the time from when a signal is generated by the row circuit 24 and the column circuit 25 to when the signal is supplied to the memory cell 32 and the time from when data is read from the memory cell 32 to when the data is supplied to the sense amplifier circuit 27 provided in the layer 20 become longer. For this reason, for example, when data needs to be read at the same time from a plurality of memory cells 32 provided in different blocks 11 in different layers 30, the data is not read at the same time in some cases. Specifically, data retained in the memory cell 32 in an upper layer 30 is read at a lower speed than data retained in the memory cell 32 in a lower layer 30 in some cases. This might cause a malfunction of the semiconductor device.

Thus, in the semiconductor device 10, the delay addition circuit 35a and the delay addition circuit 35b are provided in the layer 30. As described above, the row selection signal RSEL generated by the row circuit 24 provided in the layer 20 is supplied to the delay addition circuit 35a, and a precharge signal generated by the column circuit 25 is supplied to the delay addition circuit 35b. The row selection signal RSEL supplied to the delay addition circuit 35a, the precharge signal supplied to the delay addition circuit 35b, and the like are output from the delay addition circuit 35a and the delay addition circuit 35b after a predetermined time determined by the delay signal DA. As described above, the delay signal DA is generated by the delay signal generation circuit 23 on the basis of the reference signal BASE generated by the reference signal generation circuit 21 included in the layer 20 and the delay time detection signal DT output from the buffer circuit 37 included in the layer 30. The delay signal DA is generated on the basis of a difference between the first moment when the reference signal BASE is supplied to the delay signal generation circuit 23 and the second moment when the delay time detection signal DT is supplied to the delay signal generation circuit 23. Here, the delay time detection signal DT is generated by inputting the reference signal BASE to the buffer circuit 37; thus, a difference between the first moment and the second moment becomes larger as the tier of the layer 30 provided with the buffer circuit 37 outputting the delay time detection signal DT is higher. For example, the difference between the first moment and the second moment in the delay time detection signal DT_3 is longer than the difference between the first moment and the second moment in the delay time detection signal DT_1.

In the semiconductor device 10, in the case where data is read from the memory cell 32 provided in the layer 30 in a lower tier, the time determined by the delay signal DA is made longer than in the case where data is read from the memory cell 32 provided in the layer 30 in an upper tier. For example, in the case where data is read from the memory cell 32_1, the time determined by the delay signal DA is made longer than in the case where data is read from the memory cell 32_3. Accordingly, a longer delay time can be added to the row selection signal RSEL in the delay addition circuit 35a provided in the layer 30 in a lower tier, and a longer delay time can be added to the precharge signal in the delay addition circuit 35b provided in the layer 30 in a lower tier. For example, a longer delay time can be added to the row selection signal RSEL in the delay addition circuit 35a_1 than in the delay addition circuit 35a_3. A longer delay time can be added to the precharge signal in the delay addition circuit 35b_1 than in the delay addition circuit 35b_3.

In the case where the delay addition circuit 35a is not provided in the semiconductor device 10, the time from when the row selection signal RSEL is generated by the row circuit 24 to when the row selection signal RSEL is supplied to the memory cell 32 becomes longer as the tier of the layer 30 provided with the memory cell 32 is higher. In the case where the delay addition circuit 35b is not provided in the semiconductor device 10, the time from when the precharge signal is generated by the column circuit 25 to when the precharge signal is supplied to a bit line electrically connected to the memory cell 32 becomes longer as the tier of the layer 30 provided with the memory cell 32 electrically connected to a bit line is higher. Accordingly, in the semiconductor device 10, by providing the delay addition circuit 35a and the delay addition circuit 35b, for example, the time from when the row circuit 24 or the column circuit 25 generates a signal and supplies the signal to the memory cell 32 until when data is read from the memory cell 32 and output as the data DATAout from the column circuit 25 is equal or substantially equal between the layers 30. Thus, for example, data can be read at the same time or substantially at the same time from the plurality of memory cells 32 provided in the layers 30 in different tiers in the different blocks 11. Specifically, for example, data retained in the memory cell 32_1 in the block 11<1> and data retained in the memory cell 32_3 in the block 11<2> can be read at the same time or substantially at the same time. Therefore, the semiconductor device 10 can be a highly reliable semiconductor device in which a malfunction is inhibited.

Accordingly, the semiconductor device 10 can have a high memory density and high reliability. The semiconductor device 10 can optimize the read time of data retained in the memory cell 32, for example. Specifically, the semiconductor device 10 can optimize the time from when, for example, the row circuit 24 or the column circuit 25 generates a signal and supplies it to the memory cell 32 until when data is read from the memory cell 32 and output as the data DATAout from the column circuit 25. The above effect is obtained even when the semiconductor device 10 includes only one block 11. Thus, the semiconductor device 10 can have a high memory density and high reliability even when including only one block 11.

Note that in this specification, it can be considered that the operations of the circuits provided in the layer 20 are synchronized in different blocks 11. For example, it can be considered that the reference signal generation circuit 21 in the block 11<1> and the reference signal generation circuit 21 in the block 11<2> each generate the reference signal BASE at the same timing.

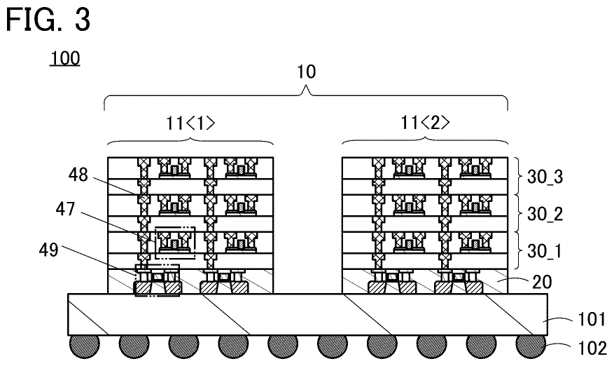

FIG. 3 is a cross-sectional view illustrating an example of an integrated circuit (also referred to as an IC chip) including the semiconductor device 10 illustrated in FIG. 1 and FIG. 2. The semiconductor device 10 can be one IC chip 100 by mounting a plurality of dies on a packaging substrate.

In this specification and the like, a die refers to a chip obtained by, for example, forming a circuit pattern on a disc-like substrate (also referred to as a wafer) and cutting the substrate into dices in a manufacturing process of a semiconductor chip.

The IC chip 100 includes the block 11 over a package substrate 101. FIG. 3 illustrates an example in which the block 11<1> and the block 11<2> are provided over the package substrate 101, and the block 11 includes the layer 20 and the layer 30_1 to the layer 30_3 over the layer 20.

Solder balls 102 for connecting the IC chip 100 to, for example, a printed circuit board are provided on the package substrate 101. The layer 20 includes a transistor 49, and the layer 30 includes a transistor 47. The transistor 49 can be provided in the reference signal generation circuit 21, the selection signal generation circuit 22, the delay signal generation circuit 23, the row circuit 24, the column circuit 25, and the sense amplifier circuit 27 illustrated in FIG. 2. The transistor 47 can be provided in the memory cell 32, the selection circuit 33, the delay addition circuit 35a, the delay addition circuit 35b, and the buffer circuit 37 illustrated in FIG. 2.

An electrode 48 is provided in the layer 30, and the electrode 48 enables, for example, transistors provided in different layers to be electrically connected to each other. The electrode 48 can be formed in parallel with the step of forming the transistor 49 or the transistor 47. Here, electrical connection between the layer 20 including the transistor 49 and the layer 30 including the transistor 47 can be performed without using a technique using a through electrode such as a TSV (Through Silicon Via) and a Cu-to-Cu (copper-to-copper) direct bonding technique (a technique for achieving electrical continuity by connecting Cu (copper) pads). Thus, the IC chip 100 can have a monolithic structure.

The transistor 49 provided in the layer 20 can be a transistor including silicon in a channel formation region (Si transistor). Thus, the reference signal generation circuit 21, the selection signal generation circuit 22, the delay signal generation circuit 23, the row circuit 24, the column circuit 25, and the sense amplifier circuit 27 can each include a Si transistor. In contrast, a transistor including a metal oxide in a channel formation region (OS transistor) can be provided in the layer 30. Thus, the memory cell 32, the selection circuit 33, the delay addition circuit 35a, the delay addition circuit 35b, and the buffer circuit 37 can each include an OS transistor.

The off-state current of an OS transistor is extremely low. Thus, when the memory cell 32 includes an OS transistor, the memory cell 32 can retain electric charge corresponding to data for a long time. Therefore, the memory cell 32 can be used as a nonvolatile memory.

The OS transistor operates stably even in a high-temperature environment and has a small fluctuation in characteristics. For example, the off-state current hardly increases even in the high-temperature environment. Specifically, the off-state current hardly increases even at an environmental temperature higher than or equal to room temperature and lower than or equal to 200° C. Furthermore, the on-state current is unlikely to decrease even in the high-temperature environment. Thus, the operation of the memory cell 32 including an OS transistor is stable even in a high-temperature environment. Accordingly, the semiconductor device 10 can be a highly reliable semiconductor device.

Meanwhile, a Si transistor, specifically a transistor including single crystal silicon in a channel formation region, has a higher on-state current than an OS transistor. Thus, when the reference signal generation circuit 21, the selection signal generation circuit 22, the delay signal generation circuit 23, the row circuit 24, the column circuit 25, and the sense amplifier circuit 27 include Si transistors, these circuits can be driven at high speed. A circuit including Si transistors can be a CMOS (Complementary Metal Oxide Semiconductor) circuit. Thus, the reference signal generation circuit 21, the selection signal generation circuit 22, the delay signal generation circuit 23, the row circuit 24, the column circuit 25, and the sense amplifier circuit 27 can be formed using a CMOS circuit.

Examples of a metal oxide used in the OS transistor include an indium oxide, a gallium oxide, and a zinc oxide. The metal oxide preferably includes two or three selected from indium, an element M, and zinc. Note that, as the element M, a metal oxide of one or more kinds selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like) or the like is preferably used. In particular, the element M is preferably one or more kinds selected from aluminum, gallium, yttrium, and tin.

It is particularly preferable to use an oxide containing indium (In), gallium (Ga), and zinc (Zn) (also referred to as IGZO) for the metal oxide. Alternatively, it is preferable to use an oxide containing indium, tin (Sn), and zinc (also referred to as ITZO (registered trademark)). Alternatively, it is preferable to use an oxide containing indium, gallium, tin, and zinc. Alternatively, it is preferable to use an oxide containing indium, aluminum (Al), and zinc (also referred to as IAZO). Alternatively, it is preferable to use an oxide containing indium, aluminum, gallium, and zinc (also referred to as IAGZO). Alternatively, it is preferable to use an oxide containing indium, gallium, zinc, and tin (also referred to as IGZTO).

The metal oxide used in an OS transistor may include two or more metal oxide layers with different compositions. For example, a stacked-layer structure of a first metal oxide layer having a composition of InM:Zn=1:3:4 [atomic ratio] or in the neighborhood thereof and a second metal oxide layer having a composition of In:M:Zn=1:1:1 [atomic ratio] or in the neighborhood thereof and being formed over the first metal oxide layer can be suitably employed.

Alternatively, a stacked-layer structure of one selected from an indium oxide, an indium gallium oxide, and IGZO, and one selected from IAZO, IAGZO, and ITZO may be employed, for example.

Note that the metal oxide used in the OS transistor preferably has crystallinity. As the oxide semiconductor having crystallinity, a CAAC (c-axis aligned crystalline)-OS, an nc (nanocrystalline)-OS, and the like can be given. When the oxide semiconductor having crystallinity is used, the semiconductor device 10 can have high reliability.

For the semiconductor included in the Si transistor, a single crystal semiconductor, a polycrystalline semiconductor, a microcrystalline semiconductor, an amorphous semiconductor, or the like can be used alone or in combination. Note that a semiconductor material included in the transistor 49 that can be a Si transistor is not limited to silicon, and germanium can be used, for example. Alternatively, a compound semiconductor such as silicon germanium, silicon carbide, gallium arsenide, or a nitride semiconductor may be used.

### Configuration Example of Delay Signal Generation Circuit

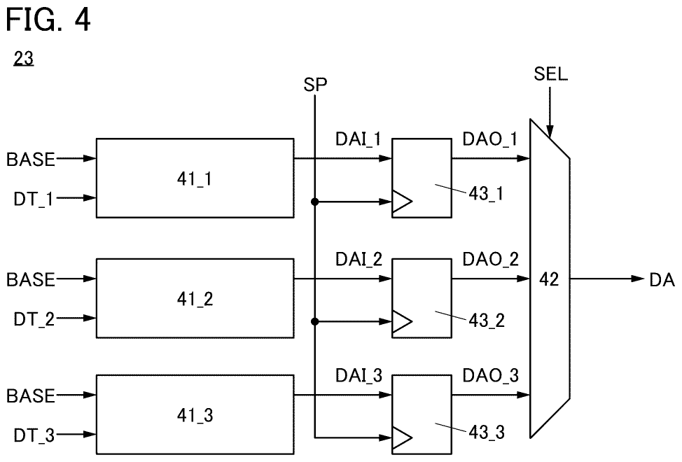

FIG. 4 is a block diagram illustrating a configuration example of the delay signal generation circuit 23. FIG. 4 illustrates a configuration example of the delay signal generation circuit 23 in the case where the block 11 includes the layer 301, the layer 302, and the layer 30_3 as the layers 30.

The delay signal generation circuit 23 includes a circuit 41_1, a circuit 412, a circuit 41_3, a flip-flop circuit 43_1, a flip-flop circuit 432, a flip-flop circuit 43_3, and a multiplexer circuit 42. That is, the delay signal generation circuit 23 includes three circuits 41, three flip-flop circuits 43, and one multiplexer circuit 42. Note that in the case where the block 11 includes the layer 30_1 to the layer 30_n, the delay signal generation circuit 23 includes n circuits 41, n flip-flop circuits 43, and one multiplexer circuit 42. As each of the flip-flop circuit 43_1 to the flip-flop circuit 43_3 illustrated in FIG. 4, a positive edge-triggered D flip-flop can be used, for example.

The reference signal BASE and the delay time detection signal DT are input to the circuit 41. For example, the reference signal BASE and the delay time detection signal DT_1 are input to the circuit 41_1. The reference signal BASE and the delay time detection signal DT_2 are input to the circuit 41_2. Furthermore, the reference signal BASE and the delay time detection signal DT_3 are input to the circuit 41_3. Here, the same reference signal BASE is input to the circuit 41_1, the circuit 412, and the circuit 41_3. In the case where the delay signal generation circuit 23 includes n circuits 41, the same reference signal BASE is input to the n circuits 41.

The circuit 41 outputs a delay signal DAI. For example, the circuit 41_1 outputs a delay signal DAI_1. The circuit 41_2 outputs a delay signal DAI_2. The circuit 41_3 outputs a delay signal DAI_3.

The delay signal DAI is input to an input terminal of the flip-flop circuit 43. For example, the delay signal DAI_1 is input to an input terminal of the flip-flop circuit 43_1. The delay signal DAI_2 is input to an input terminal of the flip-flop circuit 43_2. Furthermore, the delay signal DAI_3 is input to an input terminal of the flip-flop circuit 43_3.

A start pulse signal SP is input to a clock input terminal of the flip-flop circuit 43. Here, the same start pulse signal SP is input to the flip-flop circuit 43_1, the flip-flop circuit 432, and the flip-flop circuit 43_3. In the case where the delay signal generation circuit 23 includes n flip-flop circuits 43, the same start pulse signal SP is input to the n flip-flop circuits 43. Note that the start pulse signal SP can be supplied to circuits provided in the layer 20 other than the delay signal generation circuit 23. For example, the start pulse signal SP can be supplied to the row circuit 24 and the column circuit 25.

The flip-flop circuit 43 outputs a delay signal DAO. For example, the flip-flop circuit 43_1 outputs a delay signal DAO_1. The flip-flop circuit 43_2 outputs a delay signal DAO_2. Furthermore, the flip-flop circuit 433 outputs a delay signal DAO_3.

The delay signal DAO is input to an input terminal of the multiplexer circuit 42. In the example illustrated in FIG. 4, the delay signal DAO_1, the delay signal DAO_2, and the delay signal DAO_3 are input to the input terminal of the multiplexer circuit 42. Note that in the case where the delay signal generation circuit 23 includes n circuits 41 and n flip-flop circuits 43, n kinds of the delay signal DAO are input to the input terminal of the multiplexer circuit 42.

The selection signal SEL is input to a selection signal input terminal of the multiplexer circuit 42. An output terminal of the multiplexer circuit 42 outputs the delay signal DA.

In the delay signal generation circuit 23 with the configuration illustrated in FIG. 4, the circuit 411 generates the delay signal DAI_1 on the basis of the reference signal BASE and the delay time detection signal DT_1. The flip-flop circuit 43_1 outputs the delay signal DAI_1 as the delay signal DAO_1 when the start pulse signal SP is input. The circuit 412 generates the delay signal DAI_2 on the basis of the reference signal BASE and the delay time detection signal DT_2. The flip-flop circuit 43_2 outputs the delay signal DAI_2 as the delay signal DAO_2 when the start pulse signal SP is input. Furthermore, the circuit 413 generates the delay signal DAI_3 on the basis of the reference signal BASE and the delay time detection signal DT_3. The flip-flop circuit 43_3 outputs the delay signal DAI_3 as the delay signal DAO_3 when the start pulse signal SP is input.

The multiplexer circuit 42 outputs any one of the delay signal DAO_1, the delay signal DAO_2, and the delay signal DAO_3 as the delay signal DA on the basis of the selection signal SEL. Note that in the case where the delay signal generation circuit 23 includes n flip-flop circuits 43, the multiplexer circuit 42 outputs any one of the n kinds of the delay signal DAO as the delay signal DA.

Accordingly, the delay signal generation circuit 23 has a function of generating the delay signal DAI in the circuit 41 and retaining it in the flip-flop circuit 43, and outputting a desired delay signal from the multiplexer circuit 42 as the delay signal DA. As described above, the delay signal DA can also be referred to as a delay addition signal; thus, the delay signal DAI and the delay signal DAO can also be referred to as a delay addition signal.

Here, the selection signal SEL supplied to the multiplexer circuit 42 is also supplied to the selection circuit 33_1, the selection circuit 332, and the selection circuit 33_3 illustrated in FIG. 2. Thus, the delay signal DAO as the delay signal DA and the selection circuit 33 that outputs the row selection signal RSEL can correspond to each other. For example, in the case where the delay signal DAO_1 is set as the delay signal DA, the selection circuit 33_1 can output the row selection signal RSEL to the delay addition circuit 35a_1. In the case where the delay signal DAO_2 is set as the delay signal DA, the selection circuit 33_2 can output the row selection signal RSEL to the delay addition circuit 35a_2. Furthermore, in the case where the delay signal DAO_3 is set as the delay signal DA, the selection circuit 33_3 can output the row selection signal RSEL to the delay addition circuit 35a_3.

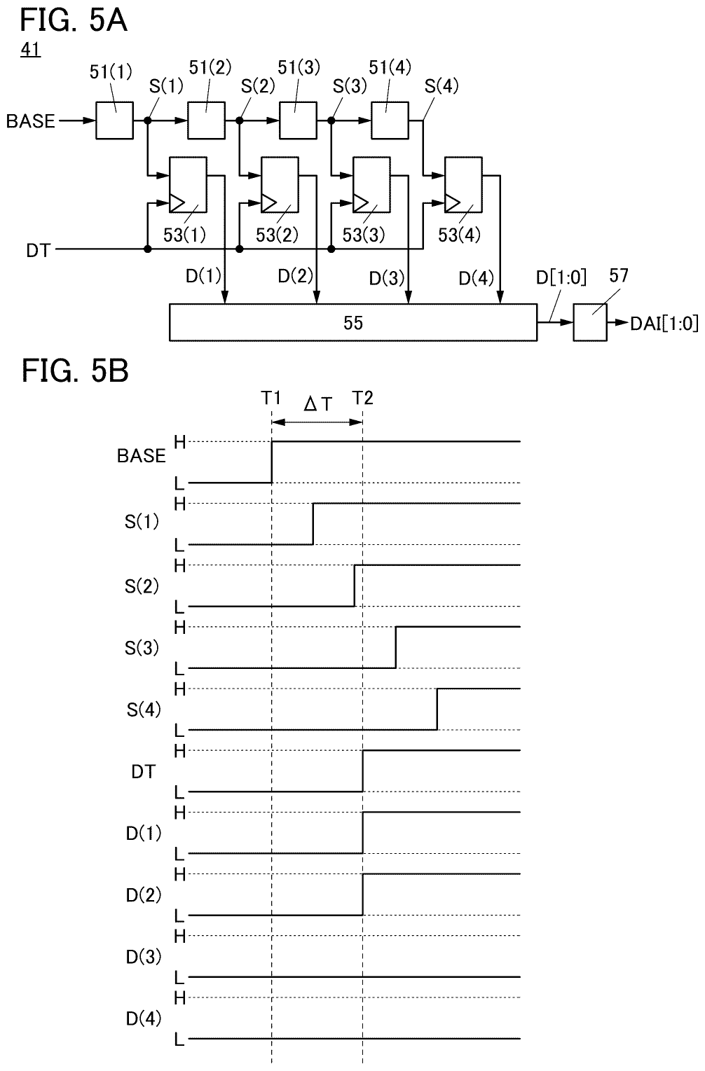

FIG. 5A is a block diagram illustrating a configuration example of the circuit 41. FIG. 5A illustrates an example in which the circuit 41 has a function of generating a 2-bit digital signal as the delay signal DAI.

The circuit 41 includes a delay circuit 51(1), a delay circuit 51(2), a delay circuit 51(3), a delay circuit 51(4), a flip-flop circuit 53(1), a flip-flop circuit 53(2), a flip-flop circuit 53(3), a flip-flop circuit 53(4), an encoder circuit 55, and an inverter circuit 57. Note that the encoder circuit 55 is not necessarily provided. As each of the flip-flop circuit 53(1) to the flip-flop circuit 53(4), a positive edge-triggered D flip-flop can be used, for example.

The reference signal BASE is input to the delay circuit 51(1). The reference signal BASE that has been input to the delay circuit 51(1) is output as a signal S(1) after a predetermined time.

The signal S(1) is input to the delay circuit 51(2). The signal S(1) that has been input to the delay circuit 51(2) is output as a signal S(2) after a predetermined time.

The signal S(2) is input to the delay circuit 51(3). The signal S(2) that has been input to the delay circuit 51(3) is output as a signal S(3) after a predetermined time.

The signal S(3) is input to the delay circuit 51(4). The signal S(3) that has been input to the delay circuit 51(4) is output as a signal S(4) after a predetermined time.

The signal S(1) is input to an input terminal of the flip-flop circuit 53(1). The signal S(2) is input to an input terminal of the flip-flop circuit 53(2). The signal S(3) is input to an input terminal of the flip-flop circuit 53(3). The signal S(4) is input to an input terminal of the flip-flop circuit 53(4). The delay time detection signal DT is input to clock input terminals of the flip-flop circuit 53(1) to the flip-flop circuit 53(4).

A digital signal D(1) is output from an output terminal of the flip-flop circuit 53(1). A digital signal D(2) is output from an output terminal of the flip-flop circuit 53(2). A digital signal D(3) is output from an output terminal of the flip-flop circuit 53(3). A digital signal D(4) is output from an output terminal of the flip-flop circuit 53(4). Each of the digital signal D(1) to the digital signal D(4) can be a 1-bit digital signal.

The encoder circuit 55 has a function of encoding the digital signal D(1) to the digital signal D(4) to generate a 2-bit digital signal D[1:0]. The inverter circuit 57 has a function of generating an inverted signal of the digital signal D[1:0] and outputting it as the delay signal DAI. Specifically, when the digital value of the digital signal D[1:0] is “00”, the digital value of the delay signal DAI becomes “11”; when the digital value of the digital signal D[1:0] is “01”, the digital value of the delay signal DAI becomes “10”; when the digital value of the digital signal D[1:0] is “10”, the digital value of the delay signal DAI becomes “01”; and when the digital value of the digital signal D[1:0] is “11”, the digital value of the delay signal DAI becomes “00”. Note that in FIG. 5A, the delay signal DAI is a 2-bit digital signal, which is denoted by a delay signal DAI[1:0].

FIG. 5B is a timing chart showing an example of a driving method for the circuit 41 illustrated in FIG. 5A. In FIG. 5B, “H” means a high potential and “L” means a low potential.

Before Time T1, the reference signal BASE, the signal S(1) to the signal S(4), the delay time detection signal DT, and the digital signal D(1) to the digital signal D(4) are all at low potentials.

In Time T1, the potential of the reference signal BASE is set to a high potential. Thus, it can be said that the reference signal BASE is input to the circuit 41 included in the delay signal generation circuit 23. After a predetermined time, the reference signal BASE is sequentially output from the delay circuit 51(1) to the delay circuit 51(4) as the signal S(1) to the signal S(4). Specifically, the reference signal BASE that has been input to the delay circuit 51(1) is output as the signal S(1) from the delay circuit 51(1) after a first time elapses. The signal S(1) that has been input to the delay circuit 51(2) is output as the signal S(2) from the delay circuit 51(2) after a second time elapses. The signal S(2) that has been input to the delay circuit 51(3) is output as the signal S(3) from the delay circuit 51(3) after a third time elapses. Furthermore, the signal S(3) that has been input to the delay circuit 51(4) is output as the signal S(4) from the delay circuit 51(4) after a fourth time elapses. Here, the first to the fourth times are preferably equal to each other; however, the first to the fourth times may differ due to variations in characteristics of transistors included in the delay circuit 51(1) to the delay circuit 51(4).

In Time T2, the potential of the delay time detection signal DT is set to a high potential. Thus, it can be said that the delay time detection signal DT is supplied to the clock input terminals of the flip-flop circuit 53(1) to the flip-flop circuit 53(4) included in the delay signal generation circuit 23. In FIG. 5B, the delay detection signal DT becomes a high potential after the signal S(2) becomes a high potential and before the signal S(3) becomes a high potential. Here, a difference between Time T1 and Time T2 is defined as Time ΔT, which is the time it takes for a reference signal to be generated by the reference signal generation circuit 21 provided in the layer 20 illustrated in FIG. 2, pass through the buffer circuit 37 provided in the layer 30, and be supplied to the delay signal generation circuit 23 provided in the layer 20 as the delay time detection signal DT.

As described above, the delay time detection signal DT is supplied to the clock input terminals of the flip-flop circuit 53(1) to the flip-flop circuit 53(4) provided in the delay signal generation circuit 23. Thus, the delay time detection signal DT is supplied to the circuit 41 included in the delay signal generation circuit 23, whereby the flip-flop circuit 53(1) to the flip-flop circuit 53(4) output the signal S(1) to the signal S(4) as the digital signal D(1) to the digital signal D(4), respectively. In the example illustrated in FIG. 5B, in Time T2 when the delay time detection signal DT becomes a high potential, the signal S(1) and the signal S(2) are at high potentials and the signal S(3) to the signal S(4) are at low potentials. Thus, the digital signal D(1) and the digital signal D(2) become high potentials, and the digital signal D(3) and the digital signal D(4) become low potentials.

After that, the encoder circuit 55 encodes the digital signal D(1) to the digital signal D(4) to generate the 2-bit digital signal D[1:0]. In the example illustrated in FIG. 5B, the digital signal D(1) and the digital signal D(2) are at high potentials and the digital signal D(3) and the digital signal D(4) are at low potentials; thus, the digital value represented by the digital signal D[1:0] is “01”. Note that when the digital signal D(1) is at a high potential and the digital signal D(2) to the digital signal D(4) are at low potentials, the digital value represented by the digital signal D[1:0] is “00”. When the digital signal D(1) to the digital signal D(3) are at high potentials and the digital signal D(4) is at a low potential, the digital value represented by the digital signal D[1:0] is “10”. Furthermore, when all of the digital signal D(1) to the digital signal D(4) are at high potentials, the digital value represented by the digital signal D[1:0] is “11”.

Accordingly, the digital signal D[1:0] can be a signal representing Time ΔT, which is time from when the reference signal BASE is supplied to the circuit 41 included in the delay signal generation circuit 23 to when the delay time detection signal DT is supplied. Specifically, as Time ΔT is longer, the digital value of the digital signal D[1:0] becomes larger.

After the encoder circuit 55 generates the digital signal D[1:0], the inverter circuit 57 generates the delay signal DAI[1:0] on the basis of the digital signal D[1:0]. As described above, as Time ΔT is longer, the digital value of the digital signal D[1:0] becomes larger, and the inverter circuit 57 has a function of generating an inverted signal of the digital signal D[1:0] and outputting it as the delay signal DAI[1:0]. Accordingly, as Time ΔT is longer, the digital value of the delay signal DAI[1:0] becomes smaller.

As described above, the delay signal DAI is supplied to the input terminal of the flip-flop circuit 43, and then supplied to the input terminal of the multiplexer circuit 42 as the delay signal DAO. After that, one delay signal DAO selected by the selection signal SEL among the plurality of delay signals DAO is output as the delay signal DA from the output terminal of the multiplexer circuit 42. Then, the row selection signal RSEL supplied to the delay addition circuit 35a, the precharge signal supplied to the delay addition circuit 35b, and the like are output from the delay addition circuit 35a and the delay addition circuit 35b after a predetermined time determined by the delay signal DA. Here, as the digital value of the delay signal DA is smaller, the time determined by the delay signal DA becomes shorter. Accordingly, as Time ΔT becomes longer, the digital value of the delay signal DAI becomes smaller, and as the digital value of the delay signal DA, which is a signal selected from the plurality of delay signals DAI, becomes smaller, the time determined by the delay signal DA becomes shorter. Therefore, as Time ΔT becomes longer, the delay time added to the row selection signal RSEL by the delay addition circuit 35a and the delay time added to the precharge signal by the delay addition circuit 35b become shorter. Note that as the digital value of the delay signal increases, the time determined by the delay signal may be shortened. In this case, the circuit 41 does not necessarily include the inverter circuit 57.

In the above-described manner, the circuit 41 can generate the delay signal DAI. Note that when the circuit 41 includes 2^{k} delay circuits 51 (k is an integer greater than or equal to 2) and 2^{k} flip-flop circuits 53, the circuit 41 can generate a k-bit delay signal DAI.

### Configuration Example of Delay Addition Circuit

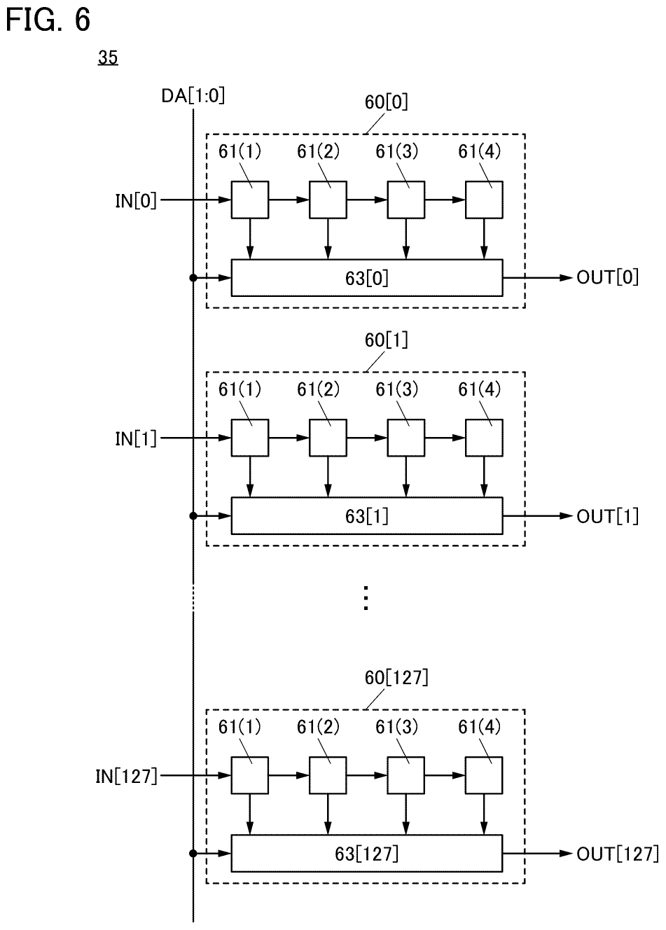

FIG. 6 is a block diagram illustrating a configuration example of the delay addition circuit 35 (the delay addition circuit 35a and the delay addition circuit 35b). FIG. 6 illustrates a configuration example of the delay addition circuit 35 having a function of outputting a signal IN as a 128-bit signal OUT (a signal OUT[0] to a signal OUT[127]) after a period of time represented by the 2-bit delay signal DA[1:0] has elapsed since a 128-bit signal IN (a signal IN[0] to a signal IN[127]) is input. The signal IN can be the row selection signal RSEL in the delay addition circuit 35a, and can be a precharge signal in the delay addition circuit 35b.

The delay addition circuit 35 includes a circuit 60[0] to a circuit 60[127]. For example, the circuit 60 includes a delay circuit 61(1), a delay circuit 61(2), a delay circuit 61(3), a delay circuit 61(4), and a selection circuit 63. Here, the selection circuits 63 included in the circuit 60[0] to the circuit 60[127] are referred to as a selection circuit 63[0] to a selection circuit 63[127] to be distinguished from each other. Note that in the case where the delay signal DA is a k-bit digital signal, the circuit 60 includes 2^{k} delay circuits 61. That is, the number of delay circuits 61 included in the circuit 60 can be the same as the number of delay circuits 51 included in the circuit 41.

The signal IN is input to the delay circuit 61(1). The signal IN input to the delay circuit 61(1) is output after a predetermined time elapses. The output signal is supplied to the delay circuit 61(2) and the selection circuit 63.

A signal output from the delay circuit 61(1) is input to the delay circuit 61(2). The signal input to the delay circuit 61(2) is output after a predetermined time elapses. The output signal is supplied to the delay circuit 61(3) and the selection circuit 63.

A signal output from the delay circuit 61(2) is input to the delay circuit 61(3). The signal input to the delay circuit 61(3) is output after a predetermined time elapses. The output signal is supplied to the delay circuit 61(4) and the selection circuit 63.

A signal output from the delay circuit 61(3) is input to the delay circuit 61(4). The signal input to the delay circuit 61(4) is output after a predetermined time elapses. The output signal is supplied to the selection circuit 63.

The delay signal DA[1:0] is supplied to the selection circuit 63. The selection circuit 63 has a function of outputting any one of the signals supplied from the delay circuit 61(1) to the delay circuit 61(4) as the signal OUT on the basis of the delay signal DA[1:0]. Specifically, the selection circuit 63 has a function of outputting a signal supplied from the delay circuit 61(1) as the signal OUT when the digital value of the delay signal DA[1:0] is “00”, a signal supplied from the delay circuit 61(2) as the signal OUT when the digital value of the delay signal DA[1:0] is “01”, a signal supplied from the delay circuit 61(3) as the signal OUT when the digital value of the delay signal DA[1:0] is “10”, and a signal supplied from the delay circuit 61(4) as the signal OUT when the digital value of the delay signal DA[1:0] is “11”. Here, since the signal IN is supplied to the delay circuit 61(1), the delay circuit 61(2), the delay circuit 61(3), and the delay circuit 61(4) in this order, the larger the digital value of the delay signal DA[1:0] is, the longer the time from when the signal IN is input to the circuit 60 to when it is output from the circuit 60 as the signal OUT becomes. Therefore, as the digital value of the delay signal DA[1:0] becomes larger, a longer delay time can be added to the signal IN.

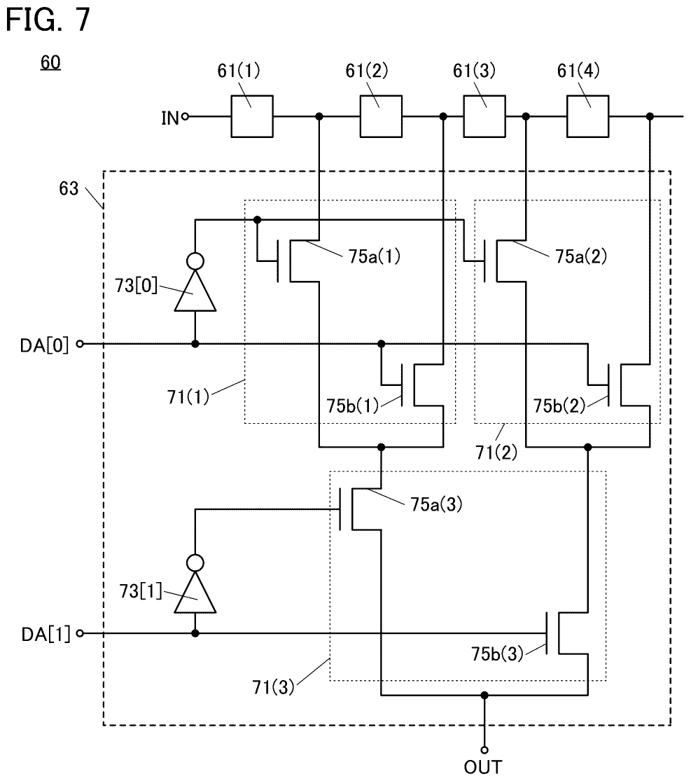

FIG. 7 is a circuit diagram illustrating a configuration example of the circuit 60. FIG. 7 illustrates a specific configuration example of the selection circuit 63.

The selection circuit 63 includes a circuit 71(1), a circuit 71(2), a circuit 71(3), an inverter circuit 73[0], and an inverter circuit 73[1]. The circuit 71(1) includes a transistor 75a(1) and a transistor 75b(1). The circuit 71(2) includes a transistor 75a(2) and a transistor 75b(2). The circuit 71(3) includes a transistor 75a(3) and a transistor 75b(3).

The delay signal DA is supplied to a gate of the transistor 75b and an input terminal of the inverter circuit 73. Specifically, the delay signal DA[0] is supplied to a gate of the transistor 75b(1), a gate of the transistor 75b(2), and an input terminal of the inverter circuit 73[0], and the delay signal DA[1] is supplied to a gate of the transistor 75b(3) and an input terminal of the inverter circuit 73[1]. A signal output from the inverter circuit 73 is supplied to a gate of the transistor 75a. Specifically, a signal output from the inverter circuit 73[0] is supplied to a gate of the transistor 75a(1) and a gate of the transistor 75a(2), and a signal output from the inverter circuit 73[1] is supplied to a gate of the transistor 75a(3). Accordingly, the signal input to the gate of the transistor 75a is an inverted signal of the signal input to the gate of the transistor 75b.

The selection circuit 63 has a configuration that branches into two circuits 71 for each 1-bit delay signal DA and includes four paths from the signal IN to the signal OUT. In other words, the circuits 71 are connected to each other in a tournament system. In the example illustrated in FIG. 7, the circuit 71(1) and the circuit 71(2), which are the circuits 71 in the first stage, are electrically connected to the delay circuit 61. Specifically, an output terminal of the delay circuit 61(1) is electrically connected to one of a source and a drain of the transistor 75a(1), an output terminal of the delay circuit 61(2) is electrically connected to one of a source and a drain of the transistor 75b(1), an output terminal of the delay circuit 61(3) is electrically connected to one of a source and a drain of the transistor 75a(2), and an output terminal of the delay circuit 61(4) is electrically connected to one of a source and a drain of the transistor 75b(2).

The other of the source and the drain of the transistor 75a(1) and the other of the source and the drain of the transistor 75b(1) are electrically connected to one of a source and a drain of the transistor 75a(3), and the other of the source and the drain of the transistor 75a(2) and the other of the source and the drain of the transistor 75b(2) are electrically connected to one of a source and a drain of the transistor 75b(3). Furthermore, the signal OUT is output from the circuit 71(3), which is the circuit 71 in the last stage. Specifically, the signal OUT is output from the other of the source and the drain of the transistor 75a(3) or the other of the source and the drain of the transistor 75b(3).

The above is an example of the configuration of the selection circuit 63. Note that in the case where the delay signal DA is a k-bit digital signal, the selection circuit 63 can include 2^{k}−1 circuits 71 and k inverter circuits 73. In the selection circuit 63 having the configuration illustrated in FIG. 7, as the digital value of the delay signal DA[1:0] increases, a signal obtained by adding a longer delay time to the signal IN is output as the signal OUT; however, one embodiment of the present invention is not limited thereto. The selection circuit 63 may have a configuration in which a signal obtained by adding a shorter delay time to the signal IN is output as the signal OUT as the digital value of the delay signal DA[1:0] increases.

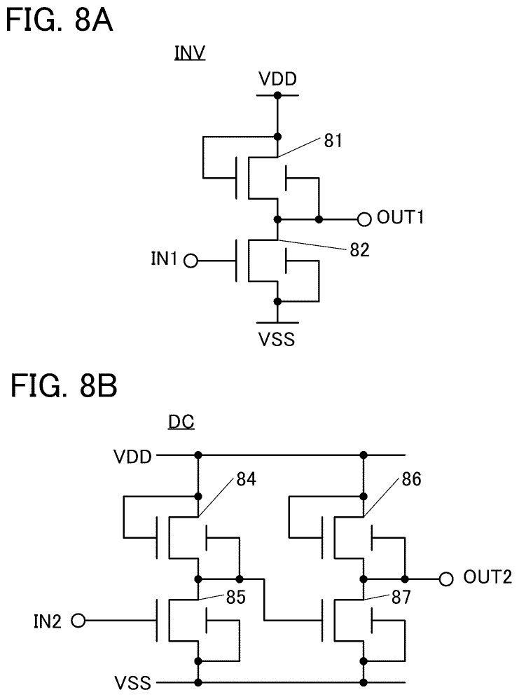

FIG. 8A is a circuit diagram illustrating a configuration example of an inverter circuit INV that can be used in the semiconductor device 10. The inverter circuit INV includes a transistor 81 and a transistor 82.

A potential VDD, which is a high potential, is supplied to one of a source and a drain of the transistor 81 and a gate of the transistor 81. A potential VSS, which is a low potential, is supplied to one of a source and a drain of the transistor 82 and a back gate of the transistor 82. A signal IN1 is supplied to a gate of the transistor 82. A signal OUT1, which is an inverted signal of the signal IN1, is output from the other of the source and the drain of the transistor 81, a back gate of the transistor 81, and the other of the source and the drain of the transistor 82.

The transistor 81 and the transistor 82 can be n-channel transistors. Thus, the inverter circuit INV can have a configuration not including a p-channel transistor. Accordingly, the transistor 81 and the transistor 82 can be OS transistors, for example. As described above, the OS transistors can be provided in the layer 30. Accordingly, the inverter circuit INV can be used as the inverter circuit provided in the layer 30. For example, the inverter circuit INV illustrated in FIG. 8A can be used as the inverter circuit 73 included in the selection circuit 63 provided in the delay addition circuit 35.

FIG. 8B is a circuit diagram illustrating a configuration example of a delay circuit DC. The delay circuit DC includes a transistor 84, a transistor 85, a transistor 86, and a transistor 87.

The potential VDD, which is a high potential, is supplied to one of a source and a drain of the transistor 84, a gate of the transistor 84, one of a source and a drain of the transistor 86, and a gate of the transistor 86. The potential VSS, which is a low potential, is supplied to one of a source and a drain of the transistor 85, a back gate of the transistor 85, one of a source and a drain of the transistor 87, and a back gate of the transistor 87. A signal IN2 is supplied to a gate of the transistor 85. The other of the source and the drain of the transistor 84, a back gate of the transistor 84, and the other of the source and the drain of the transistor 85 are electrically connected to a gate of the transistor 87. A signal OUT2 is output from the other of the source and the drain of the transistor 86, a back gate of the transistor 86, and the other of the source and the drain of the transistor 87. Here, in the case where the signal IN2 is at a high potential, the signal OUT2 becomes a high potential, and in the case where the signal IN2 is at a low potential, the signal OUT2 becomes a low potential. That is, in the case where the signal IN2 is a 1-bit digital signal, the delay circuit DC outputs a signal having the same digital value as the signal IN2, as the signal OUT2. Accordingly, the delay circuit DC has a function of outputting the signal IN2 as the signal OUT2 after a delay time determined by the characteristics of the transistor 84 to the transistor 87, the magnitude of the potential VDD, the magnitude of the potential VSS, and the like.

The delay circuit DC can be used as the delay circuit 51 included in the circuit 41 provided in the delay signal generation circuit 23 and the delay circuit 61 included in the circuit 60 provided in the delay addition circuit 35. Here, the delay circuit 51 and the delay circuit 61 may each have a plurality of components illustrated in FIG. 8B. For example, in the case where the delay circuit 51 includes two delay circuits DC illustrated in FIG. 8B, the signal OUT2 of one of the delay circuits DC can be the signal IN2 of the other of the delay circuits DC. The larger the number of delay circuits DC included in the delay circuit 51 and the delay circuit 61 is, the longer the delay time can be. The delay time can be increased also by increasing the channel lengths of the transistor 84 to the transistor 87 or decreasing the channel widths thereof, for example.

The delay circuit DC can also function as a buffer circuit. Furthermore, since the transistor 84 to the transistor 87 can be n-channel transistors, the delay circuit DC can have a configuration not including a p-channel transistor. Accordingly, the transistor 84 to the transistor 87 can be OS transistors, for example. As described above, the OS transistor can be provided in the layer 30. In the above manner, the delay circuit DC can be used as a buffer circuit provided in the layer 30, for example, the buffer circuit 37.

### Structure Example_2 of Semiconductor Device

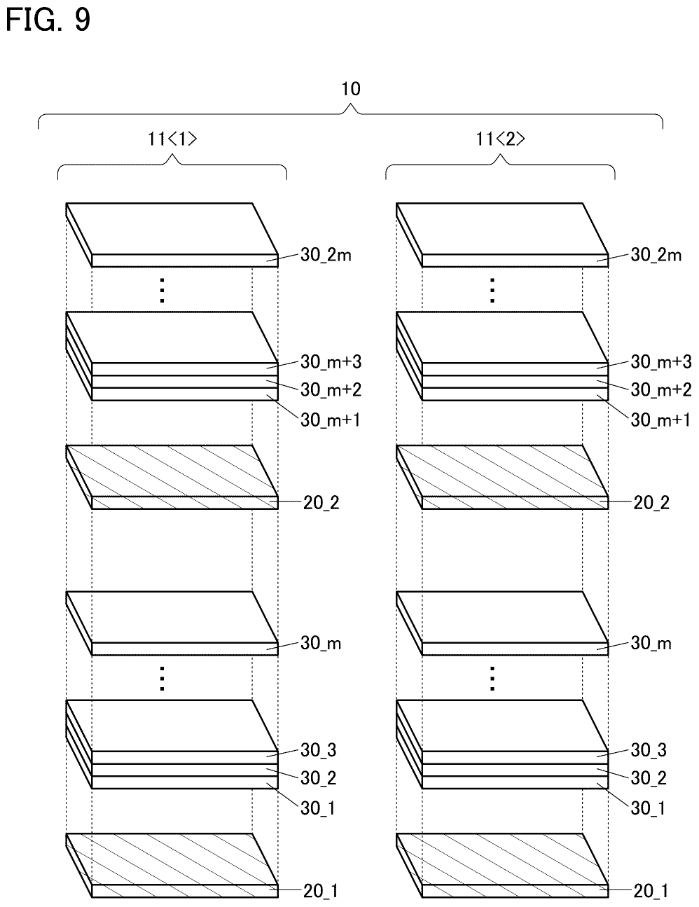

FIG. 9 is a perspective view illustrating a structure example of the semiconductor device 10, which is a modification example of the semiconductor device 10 illustrated in FIG. 1. The semiconductor device 10 illustrated in FIG. 1 is different from the semiconductor device 10 illustrated in FIG. 1 in that each of the block 11<1> and the block 11<2> includes two layers 20.

In the semiconductor device 10 illustrated in FIG. 9, each of the block 11<1> and the block 11<2> includes a layer 201, the layer 30_1 to a layer 30_m (m is an integer greater than or equal to 2) over the layer 20_1, a layer 202 over the layer 30_m, a layer 30_m+1 to a layer 30_2m over the layer 20_2. FIG. 9 illustrates the layer 301, the layer 302, the layer 303, the layer 30_m, the layer 30_m+1, a layer 30_m+2, a layer 30_m+3, and the layer 30_2m as the layers 30. Note that the semiconductor device 10 may include three or more layers 20.

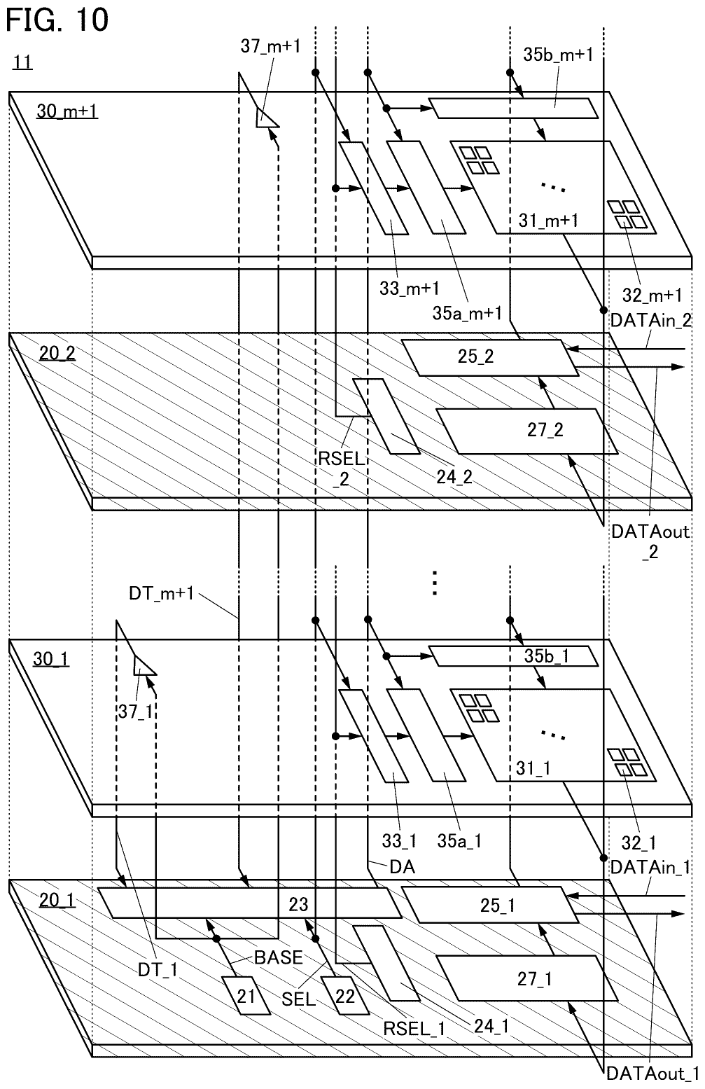

FIG. 10 is a perspective view illustrating a structure example of the block 11 illustrated in FIG. 9. Specifically, FIG. 10 illustrates a structure example of the layer 20_1, the layer 202, the layer 301, and the layer 30_m+1.

The layer 201 includes the reference signal generation circuit 21, the selection signal generation circuit 22, the delay signal generation circuit 23, a row circuit 241, a column circuit 25_1, and a sense amplifier circuit 27_1. The layer 20_2 includes a row circuit 24_2, a column circuit 25_2, and a sense amplifier circuit 27_2. That is, the reference signal generation circuit 21, the selection signal generation circuit 22, and the delay signal generation circuit 23 can be provided only in the layer 20_1. Even in the case where the block 11 includes three or more layers 20, the reference signal generation circuit 21, the selection signal generation circuit 22, and the delay signal generation circuit 23 can be provided only in the layer 20_1 which is the lowest layer. Note that the reference signal generation circuit 21, the selection signal generation circuit 22, and the delay signal generation circuit 23 may be provided in the plurality of layers 20.

The layer 301 includes the memory portion 31_1, the selection circuit 33_1, the delay addition circuit 35a_1, the delay addition circuit 35b_1, and the buffer circuit 37_1, and the memory cells 32_1 are arranged in a matrix in the memory portion 31_1. The layer 30_m+1 includes a memory portion 31_m+1, a selection circuit 33_m+1, a delay addition circuit 35a_m+1, a delay addition circuit 35b_m+1, and a buffer circuit 37_m+1, and memory cells 32_m+1 are arranged in a matrix in the memory portion 31_m+1.

In the example illustrated in FIG. 10, the reference signal BASE supplied to an input terminal of the buffer circuit 37_m+1 is output as a delay time detection signal DT_m+1 from the output terminal of the buffer circuit 37_m+1 and supplied to the delay signal generation circuit 23. As illustrated in FIG. 9, the block 11 includes 2m layers 30. The buffer circuit 37 is provided for each of the layers 30. Accordingly, 2m kinds of delay time detection signal DT are supplied to the delay signal generation circuit 23.

The row circuit 241 generates a row selection signal RSEL_1 and supplies it to the selection circuits 33 provided in the layer 301 to the layer 30_m. The row circuit 242 generates a row selection signal RSEL_2 and supplies it to the selection circuits 33 provided in the layer 30_m+1 to the layer 30_2m.

The column circuit 25_1 has a function of writing data DATAin_1 to the memory cells 32 through the delay addition circuits 35b provided in the layer 30_1 to the layer 30_m. The column circuit 25_1 has a function of outputting data read from the memory cells 32 provided in the layer 301 to the layer 30_m as data DATAout_1. Furthermore, the column circuit 25_1 has a function of generating a precharge signal before reading of data from the memory cell 32 provided in the layer 30_1 to the layer 30_m, and supplying it to the delay addition circuit 35b provided in the layer 301 to the layer 30_m.

The column circuit 25_2 has a function of writing data DATAin_2 to the memory cells 32 through the delay addition circuits 35b provided in the layer 30_m+1 to the layer 30_2m. The column circuit 25_2 has a function of outputting data read from the memory cells 32 provided in the layer 30_m+1 to the layer 30_2m as data DATAout_2. Furthermore, the column circuit 25_2 has a function of generating a precharge signal before reading of data from the memory cells 32 provided in the layer 30_m+1 to the layer 30_2m, and supplying it to the delay addition circuits 35b provided in the layer 30_m+1 to the layer 30_2m.

The sense amplifier circuit 27_1 has a function of amplifying data read from the memory cells 32 provided in the layer 301 to the layer 30_m. The sense amplifier circuit 27_2 has a function of amplifying data read from the memory cells 32 provided in the layer 30_m+1 to the layer 30_2m.

In the semiconductor device 10 illustrated in FIG. 9 and FIG. 10, for example, a CPU (Central Processing Unit) can be provided in a layer below the layer 201. For example, a CPU can be provided between the layer 20_1 and the package substrate 101 illustrated in FIG. 3. In this case, the data DATAin_1 which is supplied to the column circuit 25_1 provided in the layer 20_1 and the data DATAin_2 which is supplied to the column circuit 25_2 provided in the layer 20_2 can each be generated by the CPU provided in the layer below the layer 201. The data DATAout_1 output from the column circuit 25_1 and the data DATAout_2 output from the column circuit 25_2 are both supplied to the CPU provided in the layer below the layer 201. Thus, even in the case where the block 11 includes a plurality of layers 20, it is preferable that the reference signal generation circuit 21, the selection signal generation circuit 22, and the delay signal generation circuit 23 be provided only in the layer 201, which is the lowermost layer 20, and be not provided in the other layers 20. Note that in addition to the CPU, a GPU (Graphics Processing Unit), an FPGA (Field Programmable Gate Array), or the like may be provided in the layer below the layer 201. Alternatively, a CPU, a GPU, an FPGA, or the like may be provided in the layer 201.

In the semiconductor device 10 having the structure illustrated in FIG. 9 and FIG. 10, the wiring distances from the row circuit 24 to the layer 30_m+1 (the layer 30_n/2+1) to the layer 30_2m (the layer 30_n) can be shortened in the case where the number of layers 30 included in the block 11 is equal to that of the semiconductor device 10 illustrated in FIG. 1 and FIG. 2, i.e., in the case where n=2m. Furthermore, the wiring distances from the column circuit 25 to the layer 30_m+1 (the layer 30_n/2+1) to the layer 30_2m (the layer 30_n) and the wiring distances from the sense amplifier circuit 27 to the layer 30_m+1 (the layer 30_n/2+1) to the layer 30_2m (the layer 30_n) can be shortened. In the above manner, data writing to the memory cells 32 provided in the layer 30_m+1 (the layer 30_n/2+1) to the layer 30_2m (the layer 30_n) and data reading from the memory cells 32 can be performed at high speed. In addition, the number of selection circuits 33 electrically connected to one row circuit 24, the number of delay addition circuits 35b electrically connected to one column circuit 25, and the number of bit lines electrically connected to one sense amplifier circuit 27 can be reduced. Thus, the loads of the row circuit 24, the column circuit 25, and the sense amplifier circuit 27 can be reduced. Meanwhile, in the semiconductor device 10 illustrated in FIG. 1 and FIG. 2, a through electrode is not necessarily formed through TSV or the like in the layer 20 including an Si transistor, for example. Thus, the semiconductor device 10 illustrated in FIG. 1 and FIG. 2 can be manufactured more easily than the semiconductor device 10 illustrated in FIG. 9 and FIG. 10.

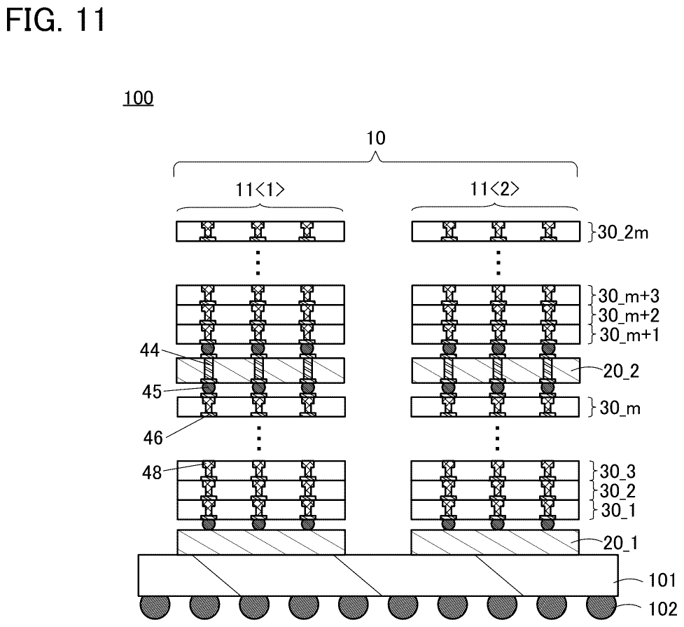

FIG. 11 is a cross-sectional view illustrating an example of an integrated circuit (also referred to as an IC chip) including the semiconductor device 10 illustrated in FIG. 9 and FIG. 10, and illustrates a modification example of the structure illustrated in FIG. 3. Note that the transistor 47 and the transistor 49 are omitted in FIG. 11.

FIG. 11 illustrates an example in which a through electrode 44 is provided in the layer 20_2. A metal bump 45 (also referred to as a micro-bump) is provided between the layer 20 and the layer 30. An electrode 46 is provided between two electrodes 48 provided in two layers 30 and between the through electrode 44 and the metal bump 45. In the example illustrated in FIG. 11, the layer 201, the layer 202, and the layer 30_1 to the layer 30_2m are electrically connected to one another through the through electrode 44, the metal bump 45, the electrode 46, and the electrode 48.

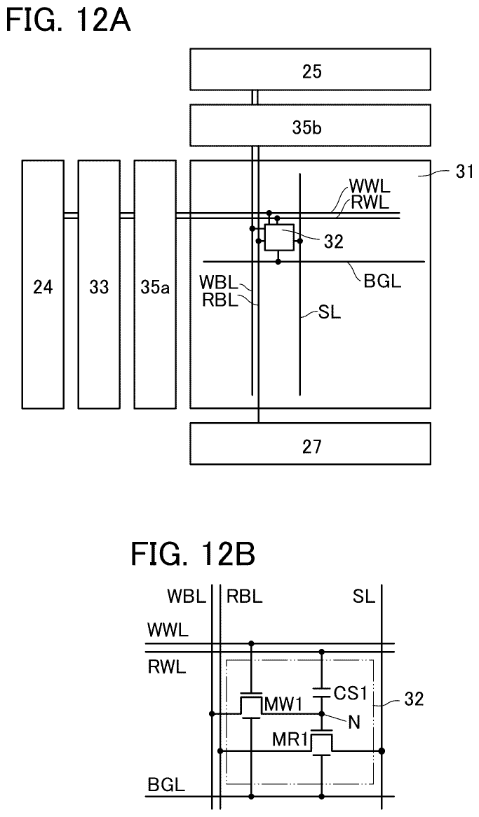

FIG. 12A is a block diagram illustrating an example of a wiring electrically connected to the memory cell 32 provided in the memory portion 31. Note that FIG. 12A also illustrates the row circuit 24, the column circuit 25, the sense amplifier circuit 27, the selection circuit 33, the delay addition circuit 35a, and the delay addition circuit 35b for description. FIG. 12A does not illustrate the connection relation between the column circuit 25 and the sense amplifier circuit 27.

A word line WWL, a word line RWL, a bit line WBL, a bit line RBL, a wiring SL, and a wiring BGL are electrically connected to the memory cell 32. The word line WWL and the word line RWL are electrically connected to the delay addition circuit 35a. The bit line WBL is electrically connected to the delay addition circuit 35b. The bit line RBL is electrically connected to the delay addition circuit 35b and the sense amplifier circuit 27.

### Configuration Example of Memory Cell

FIG. 12B is a circuit diagram illustrating a configuration example of the memory cell 32. The memory cell 32 illustrated in FIG. 12B is a 2-transistor (2T) gain cell. The memory cell 32 includes a transistor MW1, a transistor MR1, and a capacitor CS1.

One of a source and a drain of the transistor MW1I is electrically connected to one electrode of the capacitor CS1. The one electrode of the capacitor CS1 is electrically connected to a gate of the transistor MR1. Here, a node where the one of the source and the drain of the transistor MW1, the one electrode of the capacitor CS1, and the gate of the transistor MR1 are electrically connected to each other is referred to as a node N.

The other of the source and the drain of the transistor MW1 is electrically connected to the bit line WBL. A gate of the transistor MW1 is electrically connected to the word line WWL. The other electrode of the capacitor CS1 is electrically connected to the word line RWL. One of a source and a drain of the transistor MR1 is electrically connected to the bit line RBL. The other of the source and the drain of the transistor MR1 is electrically connected to the wiring SL. A back gate of the transistor MW1 and a back gate of the transistor MR1 are electrically connected to the wiring BGL. A constant potential is supplied to the wiring SL, for example.

When data is written to the memory cell 32, the row circuit 24 generates the row selection signal RSEL for turning on the transistor MW1 and supplies it to the word line WWL. Thus, data corresponding to the potential of the bit line WBL is written to the memory cell 32. Specifically, charge corresponding to the potential of the bit line WBL is supplied to the node N. Accordingly, the transistor MW1 can be referred to as a write transistor, the word line WWL can be referred to as a write word line, and the bit line WBL can be referred to as a write bit line.

Then, the transistor MW1 is turned off, whereby data written to the memory cell 32 is retained. Specifically, charge of the node N corresponding to data written to the memory cell 32 is retained.

In the case where data is read from the memory cell 32, first, the column circuit 25 generates a precharge signal and supplies the precharge signal to the bit line RBL, whereby the bit line RBL is precharged. Next, the row circuit 24 generates the row selection signal RSEL and supplies it to the word line RWL, whereby the potential of the other electrode of the capacitor CS1 is increased. Accordingly, the potential of the node N is increased, and current having a magnitude corresponding to data retained in the memory cell 32 flows between the bit line RBL and the wiring SL through the transistor MR1. Thus, the potential of the bit line RBL changes in accordance with data retained in the memory cell 32. Specifically, for example, in the case where 1-bit digital data is retained in the memory cell 32, when the digital value of the digital data is “1”, the potential of the bit line RBL becomes higher than the precharge potential. On the other hand, when the digital value is “0”, the potential of the bit line RBL becomes lower than the precharge potential. After that, the sense amplifier circuit 27 amplifies a difference between the precharge potential and the potential of the bit line RBL. In the above manner, data is read from the memory cell 32. Here, the transistor MR1 can be referred to as a read transistor, the word line RWL can be referred to as a read word line, and the bit line RBL can be referred to as a read bit line.

Note that the row selection signal RSEL supplied to the word line WWL when data is written to the memory cell 32 and the row selection signal RSEL supplied to the word line RWL when data is read from the memory cell 32 can be different signals, and for example, can be signals with different potentials. For example, even in the case where the row selection signal RSEL supplied to the word line WWL and the row selection signal RSEL supplied to the word line RWL are each set to high potentials, these two high potentials can be made different.

The transistor MW1 and the transistor MR1 can be OS transistors. When the transistor MW1 is an OS transistor, the off-state current of the transistor MW1I can be extremely low; thus, the charge of the node N can be retained for a long time. Accordingly, the memory cell 32 can retain data for a long time. In addition, data can be retained in the memory cell 32 by turning off the transistor MW1; thus, power is not consumed for data retention. Therefore, the memory cell 32 is a memory cell with low power consumption that can retain data for a long time, and the semiconductor device 10 can be used as a nonvolatile memory device.

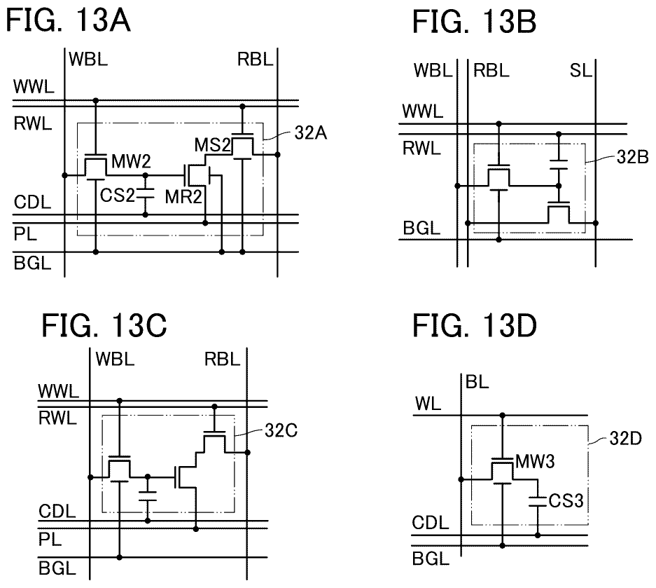

Other configuration examples of the memory cell 32 are described with reference to FIG. 13A to FIG. 13D.

A memory cell 32A illustrated in FIG. 13A is a 3T gain cell, which includes transistors MW2 and MR2, a transistor MS2, and a capacitor CS2. The transistor MW2, the transistor MR2, and the transistor MS2 are a write transistor, a read transistor, and a selection transistor, respectively. A back gate of the transistor MW2, a back gate of the transistor MR2, and a back gate of the transistor MS2 are electrically connected to the wiring BGL. The memory cell 32A is electrically connected to the word line RWL, the word line WWL, the bit line RBL, the bit line WBL, a capacitor line CDL, and a power supply line PL. A low potential, specifically, a ground potential, for example, is supplied to the capacitor line CDL and the power supply line PL.

FIG. 13B illustrates another configuration example of a 2T gain cell. In the memory cell 32B illustrated in FIG. 13B, the read transistor is an OS transistor not including a back gate.

FIG. 13C illustrates another configuration example of a 3T gain cell. In the memory cell 32C illustrated in FIG. 13C, the read transistor and the selection transistor are OS transistors not including a back gate.

In the above-described gain cells, a bit line serving as both the bit line RBL and the bit line WBL may be provided.

A memory cell having the circuit configuration illustrated in FIG. 12B, FIG. 13A, FIG. 13B, or FIG. 13C and including an OS transistor is referred to as a NOSRAM (registered trademark). NOSRAM is an abbreviation for “Nonvolatile Oxide Semiconductor Random Access Memory (RAM)”.

FIG. 13D illustrates an example of a 1T1C (capacitor) memory cell. A memory cell 32D illustrated in FIG. 13D is electrically connected to a word line WL, a bit line BL, the capacitor line CDL, and the wiring BGL. The memory cell 32D includes the transistor MW3 and the capacitor CS3. A back gate of the transistor MW3 is electrically connected to the wiring BGL.

A memory cell having the circuit configuration illustrated in FIG. 13D and including an OS transistor is referred to as a DOSRAM (registered trademark). DOSRAM is an abbreviation for “Dynamic Oxide Semiconductor RAM”.

The configurations, structures, methods, and the like described in this embodiment can be used in combination as appropriate with the configurations, structures, methods, and the like described in the other embodiments.

### Embodiment 2

In this embodiment, structures of transistors that can be used in the semiconductor device described in the above embodiment will be described. For example, a structure in which transistors having different electrical characteristics are stacked and provided will be described. With such a structure, the degree of freedom in design of a semiconductor device can be increased. In addition, providing transistors having different electrical characteristics to be stacked can increase the integration degree of the semiconductor device.

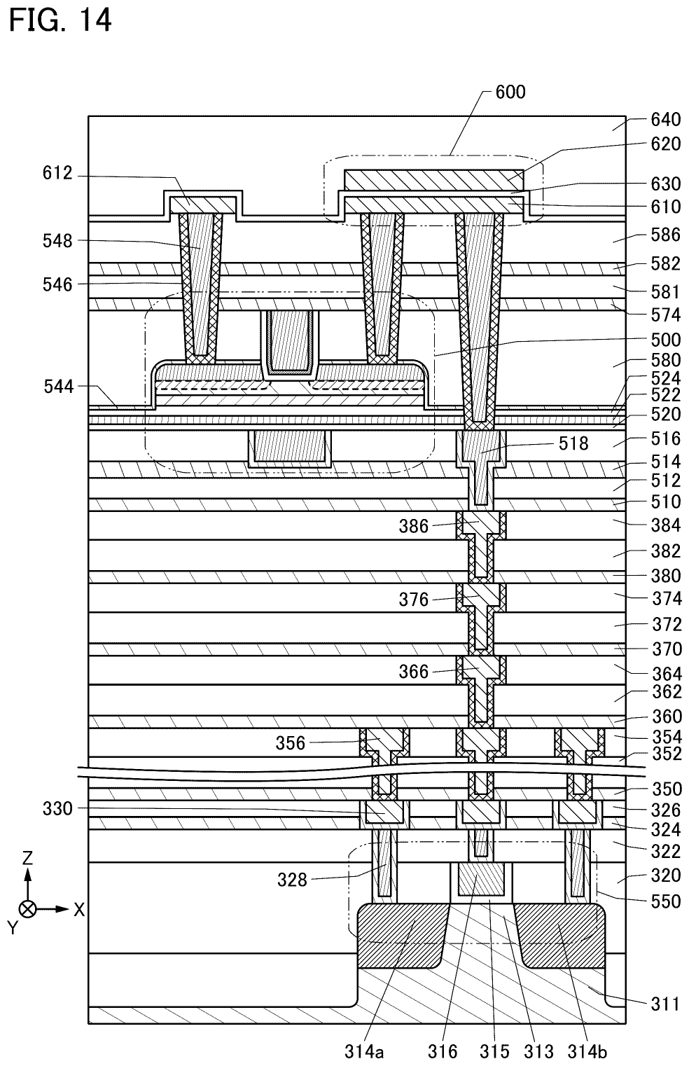

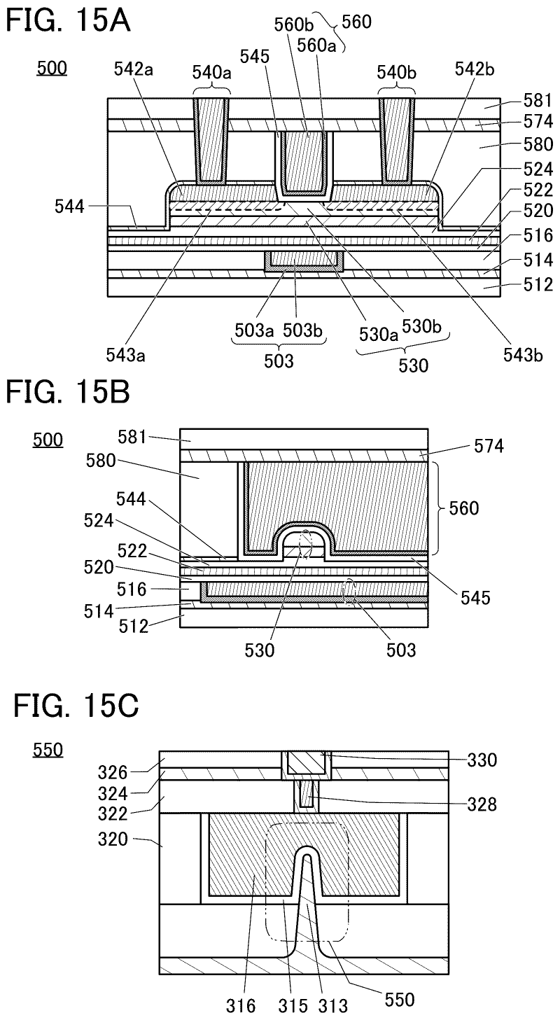

FIG. 14 illustrates part of a cross-sectional structure of a semiconductor device. The semiconductor device illustrated in FIG. 14 includes a transistor 550, a transistor 500, and a capacitor 600. FIG. 15A is a cross-sectional view of the transistor 500 in a channel length direction, FIG. 15B is a cross-sectional view of the transistor 500 in a channel width direction, and FIG. 15C is a cross-sectional view of the transistor 550 in a channel width direction. For example, the transistor 500 corresponds to the Si transistor described in the above embodiment, and the transistor 550 corresponds to an OS transistor.

Note that in this specification and the like, one of the row direction and the column direction in which memory cells are provided is referred to as an X direction, and the other of the row direction and the column direction is referred to as a Y direction. Furthermore, a direction perpendicular to both the X direction and the Y direction is referred to as a Z direction. The Z direction is also referred to as a height direction.

In FIG. 14, the transistor 500 is provided above the transistor 550, and the capacitor 600 is provided above the transistor 550 and the transistor 500.

The transistor 550 is provided on a substrate 311 and includes a conductor 316, an insulator 315, a semiconductor region 313 that is part of the substrate 311, and a low-resistance region 314a and a low-resistance region 314b each functioning as a source region or a drain region.

As illustrated in FIG. 15C, in the transistor 550, a top surface and a side surface in the channel width direction of the semiconductor region 313 are covered with the conductor 316 with the insulator 315 therebetween. The use of such a Fin-type transistor as the transistor 550 can increase the effective channel width and thus improve on-state characteristics of the transistor 550. In addition, contribution of the electric field of a gate electrode can be increased, so that the off-state characteristics of the transistor 550 can be improved.

Note that the transistor 550 may be either a p-channel transistor or an n-channel transistor.

A region of the semiconductor region 313 where a channel is formed, a region in the vicinity thereof, the low-resistance region 314a and the low-resistance region 314b each functioning as a source region or a drain region, and the like preferably contain a semiconductor such as a silicon-based semiconductor, and preferably contain single crystal silicon. Alternatively, the regions may be formed using a material containing Ge (germanium), SiGe (silicon germanium), GaAs (gallium arsenide), GaAlAs (gallium aluminum arsenide), or the like. A structure using silicon whose effective mass is controlled by applying stress to a crystal lattice and changing lattice spacing may be employed. Alternatively, the transistor 550 may be a HEMT (High Electron Mobility Transistor) using GaAs and GaAlAs, for example.

The low-resistance region 314a and the low-resistance region 314b contain an element that imparts n-type conductivity, such as arsenic or phosphorus, or an element that imparts p-type conductivity, such as boron, in addition to the semiconductor material used for the semiconductor region 313.

For the conductor 316 functioning as a gate electrode, a semiconductor material such as silicon containing the element that imparts n-type conductivity, such as arsenic or phosphorus, or the element that imparts p-type conductivity, such as boron, or a conductive material such as a metal material, an alloy material, or a metal oxide material can be used.

Note that since a work function depends on the material of the conductor, the threshold voltage of the transistor can be adjusted by selecting the material of the conductor. Specifically, it is preferable to use a material such as titanium nitride or tantalum nitride for the conductor. Moreover, in order to ensure both conductivity and embeddability, it is preferable to use stacked layers of metal materials such as tungsten and aluminum for the conductor, and it is particularly preferable to use tungsten in terms of heat resistance.

The transistor 550 may be formed using an SOI (silicon on Insulator) substrate, for example.

In addition, as the SOI substrate, the following substrate may be used: a SIMOX (Separation by Implanted Oxygen) substrate that is formed in such a manner that after an oxygen ion is implanted into a mirror-polished wafer, an oxide layer is formed at a certain depth from a surface and defects generated in a surface layer are eliminated by high-temperature annealing, or an SOI substrate formed by using a Smart-Cut method in which a semiconductor substrate is cleaved by utilizing growth of a minute void, which is formed by implantation of a hydrogen ion, by heat treatment; an ELTRAN method (a registered trademark: Epitaxial Layer Transfer); or the like. A transistor formed using a single crystal substrate contains a single crystal semiconductor in a channel formation region.

An insulator 320, an insulator 322, an insulator 324, and an insulator 326 are sequentially stacked and provided to cover the transistor 550.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, aluminum nitride, or the like is used, for example.

Note that in this specification, silicon oxynitride refers to a material that has a higher oxygen content than a nitrogen content, and silicon nitride oxide refers to a material that has a higher nitrogen content than an oxygen content. Moreover, in this specification, aluminum oxynitride refers to a material that has a higher oxygen content than a nitrogen content, and aluminum nitride oxide refers to a material that has a higher nitrogen content than an oxygen content.

The insulator 322 may have a function of a planarization film for eliminating a level difference caused by, for example, the transistor 550 provided below the insulator 322. For example, a top surface of the insulator 322 may be planarized by planarization treatment using a chemical mechanical polishing (CMP) method or the like to increase planarity.

In addition, for the insulator 324, it is preferable to use a film having a barrier property that prevents diffusion of hydrogen, impurities, and the like from the substrate 311, the transistor 550, or the like into a region where the transistor 500 is provided.

For the film having a barrier property against hydrogen, for example, silicon nitride formed by a CVD method can be used. Here, diffusion of hydrogen into a semiconductor element including an oxide semiconductor, such as the transistor 500, degrades the characteristics of the semiconductor element in some cases. Therefore, a film that inhibits hydrogen diffusion is preferably used between the transistor 500 and the transistor 550. The film that inhibits hydrogen diffusion is specifically a film from which a small amount of hydrogen is released.

The amount of released hydrogen can be measured by thermal desorption spectroscopy (TDS), for example. The amount of hydrogen released from the insulator 324 that is converted into hydrogen atoms per area of the insulator 324 is less than or equal to 1×10¹⁶ atoms/cm², preferably less than or equal to 5×10¹⁵ atoms/cm², in TDS analysis in a film-surface temperature range of 50° C. to 500° C., for example.

Note that the permittivity of the insulator 326 is preferably lower than that of the insulator 324. For example, the relative permittivity of the insulator 326 is preferably lower than 4, further preferably lower than 3. In addition, the relative permittivity of the insulator 326 is, for example, preferably 0.7 times or less, further preferably 0.6 times or less the relative permittivity of the insulator 324. When a material with low permittivity is used for the interlayer film, parasitic capacitance generated between wirings can be reduced.

In addition, a conductor 328, a conductor 330, and the like that are connected to the capacitor 600 or the transistor 500 are embedded in the insulator 320, the insulator 322, the insulator 324, and the insulator 326. Note that the conductor 328 and the conductor 330 each have a function of a plug or a wiring. Furthermore, a plurality of conductors functioning as plugs or wirings are collectively denoted by the same reference numeral in some cases. Moreover, in this specification and the like, a wiring and a plug connected to the wiring may be a single component. That is, part of a conductor functions as a wiring in some cases and part of a conductor functions as a plug in other cases.

As a material for each of the plugs and wirings (the conductor 328, the conductor 330, and the like), a single layer or a stacked layer of a conductive material such as a metal material, an alloy material, a metal nitride material, or a metal oxide material can be used. It is preferable to use a high-melting-point material that has both heat resistance and conductivity, such as tungsten or molybdenum, and it is particularly preferable to use tungsten. Alternatively, it is preferable to form the plugs and wirings with a low-resistance conductive material such as aluminum or copper. The use of a low-resistance conductive material can reduce wiring resistance.

A wiring layer may be provided over the insulator 326 and the conductor 330. For example, in FIG. 14, an insulator 350, an insulator 352, and an insulator 354 are sequentially stacked and provided. Furthermore, a conductor 356 is formed in the insulator 350, the insulator 352, and the insulator 354. The conductor 356 has a function of a plug connected to the transistor 550 or a wiring. Note that the conductor 356 can be provided using a material similar to those for the conductor 328 and the conductor 330.

A wiring layer may be provided over the insulator 354 and the conductor 356. For example, in FIG. 14, an insulator 360, an insulator 362, and an insulator 364 are sequentially stacked and provided. Furthermore, a conductor 366 is formed in the insulator 360, the insulator 362, and the insulator 364. The conductor 366 has a function of a plug or a wiring. Note that the conductor 366 can be provided using a material similar to those for the conductor 328 and the conductor 330.

A wiring layer may be provided over the insulator 364 and the conductor 366. For example, in FIG. 14, an insulator 370, an insulator 372, and an insulator 374 are sequentially stacked and provided. Furthermore, a conductor 376 is formed in the insulator 370, the insulator 372, and the insulator 374. The conductor 376 has a function of a plug or a wiring. Note that the conductor 376 can be provided using a material similar to those for the conductor 328 and the conductor 330.

A wiring layer may be provided over the insulator 374 and the conductor 376. For example, in FIG. 14, an insulator 380, an insulator 382, and an insulator 384 are sequentially stacked and provided. Furthermore, a conductor 386 is formed in the insulator 380, the insulator 382, and the insulator 384. The conductor 386 has a function of a plug or a wiring. Note that the conductor 386 can be provided using a material similar to those for the conductor 328 and the conductor 330.

An insulator having a barrier property against hydrogen is preferably used for the insulator 350, the insulator 360, the insulator 370, the insulator 380, and the like, as for the insulator 324. Furthermore, the conductor 356 preferably includes a conductor having a barrier property against hydrogen. In particular, the conductor having a barrier property against hydrogen is formed in an opening portion of the insulator 350 having a barrier property against hydrogen. With this structure, the transistor 550 and the transistor 500 can be separated with a barrier layer, so that hydrogen diffusion from the transistor 550 into the transistor 500 can be inhibited.

Note that for the conductor having a barrier property against hydrogen, or tantalum nitride is preferably used, for example. In addition, by stacking tantalum nitride and tungsten, which has high conductivity, diffusion of hydrogen from the transistor 550 can be inhibited while the conductivity as a wiring is kept. In that case, a structure in which a tantalum nitride layer having a barrier property against hydrogen is in contact with the insulator 350 having a barrier property against hydrogen is preferable.

Although the wiring layer including the conductor 356, the wiring layer including the conductor 366, the wiring layer including the conductor 376, and the wiring layer including the conductor 386 are described above, the semiconductor device according to this embodiment is not limited thereto. Three or less wiring layers that are similar to the wiring layer including the conductor 356 may be provided, or five or more wiring layers that are similar to the wiring layer including the conductor 356 may be provided.

An insulator 510, an insulator 512, an insulator 514, and an insulator 516 are sequentially stacked and provided over the insulator 384. A substance having a barrier property against oxygen, hydrogen, or the like is preferably used for any of the insulator 510, the insulator 512, the insulator 514, and the insulator 516.

For example, for each of the insulator 510 and the insulator 514, it is preferable to use a film having a barrier property that prevents diffusion of hydrogen, impurities, or the like from the substrate 311, a region where the transistor 550 is provided, or the like into a region where the transistor 500 is provided. Therefore, a material similar to that for the insulator 324 can be used.

For the film having a barrier property against hydrogen, silicon nitride formed by a CVD method can be used, for example. Here, diffusion of hydrogen into a semiconductor element including an oxide semiconductor, such as the transistor 500, degrades the characteristics of the semiconductor element in some cases. Therefore, a film that inhibits hydrogen diffusion is preferably provided between the transistor 500 and the transistor 550. The film that inhibits hydrogen diffusion is specifically a film from which a small amount of hydrogen is released.

In addition, for the film having a barrier property against hydrogen, a metal oxide such as aluminum oxide, hafnium oxide, or tantalum oxide is preferably used for each of the insulator 510 and the insulator 514, for example.

In particular, aluminum oxide has an excellent blocking effect that prevents passage of both oxygen and impurities such as hydrogen and moisture which are factors of fluctuation in electrical characteristics of the transistor. Accordingly, aluminum oxide can prevent mixing of impurities such as hydrogen and moisture into the transistor 500 during and after a manufacturing process of the transistor. In addition, release of oxygen from the oxide included in the transistor 500 can be inhibited. Therefore, aluminum oxide is suitably used for a protective film of the transistor 500.

In addition, for each of the insulator 512 and the insulator 516, a material similar to that for the insulator 320 can be used, for example. Furthermore, when a material with comparatively low permittivity is used for these insulators, parasitic capacitance generated between wirings can be reduced. A silicon oxide film, a silicon oxynitride film, or the like can be used for each of the insulator 512 and the insulator 516, for example.

Furthermore, a conductor 518, a conductor included in the transistor 500 (a conductor 503, for example), and the like are embedded in the insulator 510, the insulator 512, the insulator 514, and the insulator 516. Note that the conductor 518 has a function of a plug or a wiring that is connected to the capacitor 600 or the transistor 550. The conductor 518 can be provided using a material similar to those for the conductor 328 and the conductor 330.

In particular, the conductor 518 in a region in contact with the insulator 510 and the insulator 514 is preferably a conductor having a barrier property against oxygen, hydrogen, and water. With this structure, the transistor 550 and the transistor 500 can be separated with a layer having a barrier property against oxygen, hydrogen, and water, so that hydrogen diffusion from the transistor 550 into the transistor 500 can be inhibited.

The transistor 500 is provided above the insulator 516.

As illustrated in FIG. 15A and FIG. 15B, the transistor 500 includes the conductor 503 positioned to be embedded in the insulator 514 and the insulator 516; an insulator 520 positioned over the insulator 516 and the conductor 503; an insulator 522 positioned over the insulator 520; an insulator 524 positioned over the insulator 522; an oxide 530a positioned over the insulator 524; an oxide 530b positioned over the oxide 530a; a conductor 542a and a conductor 542b positioned apart from each other over the oxide 530b; an insulator 580 that is positioned over the conductor 542a and the conductor 542b and is provided with an opening formed to overlap a region between the conductor 542a and the conductor 542b; an insulator 545 positioned on a bottom surface and a side surface of the opening; and a conductor 560 positioned on a formation surface of the insulator 545.

In addition, as illustrated in FIG. 15A and FIG. 15B, an insulator 544 is preferably positioned between the insulator 580 and the oxide 530a, the oxide 530b, the conductor 542a, and the conductor 542b. Furthermore, as illustrated in FIG. 15A and FIG. 15B, the conductor 560 preferably includes a conductor 560a provided inside the insulator 545 and a conductor 560b provided to be embedded inside the conductor 560a. Moreover, as illustrated in FIG. 15A and FIG. 15B, an insulator 574 is preferably positioned over the insulator 580, the conductor 560, and the insulator 545.

Note that in this specification and the like, the oxide 530a and the oxide 530b are sometimes collectively referred to as an oxide 530.

Note that the transistor 500 is illustrated to have a structure in which two layers, the oxide 530a and the oxide 530b, are stacked in the region where the channel is formed and its vicinity; however, the present invention is not limited thereto. For example, a structure may be employed in which a single layer of the oxide 530b or a stacked-layer structure of three or more layers is provided.

In addition, although the conductor 560 has a stacked-layer structure of two layers in the transistor 500, the present invention is not limited thereto. For example, the conductor 560 may have a single-layer structure or a stacked-layer structure of three or more layers. Furthermore, the transistor 500 illustrated in FIG. 14 and FIG. 15A is an example and the structure is not limited thereto; an appropriate transistor is used in accordance with a circuit structure, a driving method, or the like.

Here, the conductor 560 functions as a gate electrode of the transistor, and the conductor 542a and the conductor 542b each function as a source electrode or a drain electrode. As described above, the conductor 560 is formed to be embedded in the opening of the insulator 580 and the region sandwiched between the conductor 542a and the conductor 542b. The positions of the conductor 560, the conductor 542a, and the conductor 542b with respect to the opening of the insulator 580 are selected in a self-aligned manner. That is, in the transistor 500, the gate electrode can be positioned between the source electrode and the drain electrode in a self-aligned manner. Thus, the conductor 560 can be formed without an alignment margin, which results in a reduction in the area occupied by the transistor 500. Accordingly, miniaturization and high integration of the semiconductor device can be achieved.

In addition, since the conductor 560 is formed in the region between the conductor 542a and the conductor 542b in a self-aligned manner, the conductor 560 does not have a region overlapping the conductor 542a or the conductor 542b. Thus, parasitic capacitance formed between the conductor 560 and each of the conductor 542a and the conductor 542b can be reduced. As a result, the switching speed of the transistor 500 can be increased, and the transistor 500 can have high frequency characteristics.

The conductor 560 sometimes functions as a first gate (also referred to as top gate) electrode. In addition, the conductor 503 sometimes functions as a second gate (also referred to as bottom gate) electrode. In that case, by changing a potential applied to the conductor 503 not in synchronization with but independently of a voltage applied to the conductor 560, the threshold voltage of the transistor 500 can be controlled. In particular, when a negative potential is applied to the conductor 503, the threshold voltage of the transistor 500 can be made higher than 0 V, and the off-state current can be reduced. Thus, drain current at the time when a potential applied to the conductor 560 is 0 V can be made lower in the case where a negative potential is applied to the conductor 503 than in the case where a negative potential is not applied to the conductor 503.

The conductor 503 is positioned to overlap the oxide 530 and the conductor 560. Thus, when a potential is applied to the conductor 560 and the conductor 503, an electric field generated from the conductor 560 and an electric field generated from the conductor 503 are connected, so that the channel formation region formed in the oxide 530 can be covered.

In this specification and the like, a transistor structure where a channel formation region is electrically surrounded by an electric field of a first gate electrode is referred to as a surrounded channel (S-channel) structure. In addition, the S-channel structure disclosed in this specification and the like has a structure different from a Fin-type structure and a planar structure. Meanwhile, the S-channel structure disclosed in this specification and the like can also be regarded as a kind of Fin-type structure. Note that in this specification and the like, the Fin-type structure refers to a structure where at least two or more surfaces (specifically, two surfaces, three surfaces, four surfaces, or the like) of a channel are covered with a gate electrode. With the Fin-type structure and the S-channel structure, resistance to a short-channel effect can be increased, that is, a transistor in which a short-channel effect is less likely to occur can be provided.

When the transistor has the S-channel structure, the channel formation region can be electrically surrounded. Note that since the S-channel structure is a structure where the channel formation region is electrically surrounded, it can also be said that the S-channel structure is a structure substantially equivalent to a GAA (Gate All Around) structure or an LGAA (Lateral Gate All Around) structure. When the transistor has the S-channel structure, the GAA structure, or the LGAA structure, a channel formation region that is formed at an interface between the oxide 530 and a gate insulator or in the vicinity of the interface can be the entire bulk of the oxide 530. Accordingly, the density of current flowing through the transistor can be improved, which can be expected to improve the on-state current of the transistor or increase the field-effect mobility of the transistor.

In addition, the conductor 503 has a structure similar to that of the conductor 518; a conductor 503a is formed in contact with an inner wall of an opening in the insulator 514 and the insulator 516, and a conductor 503b is formed on the inner side. Note that although the conductor 503a and the conductor 503b are stacked in the transistor 500, the present invention is not limited thereto. For example, the conductor 503 may be provided as a single layer or to have a stacked-layer structure of three or more layers.

Here, for the conductor 503a, a conductive material that has a function of inhibiting diffusion of impurities such as a hydrogen atom, a hydrogen molecule, a water molecule, and a copper atom (through which the impurities are less likely to pass) is preferably used. Alternatively, it is preferable to use a conductive material that has a function of inhibiting diffusion of oxygen (e.g., at least one of an oxygen atom, an oxygen molecule, and the like) (through which oxygen is less likely to pass). Note that in this specification and the like, the function of inhibiting diffusion of impurities or oxygen means a function of inhibiting diffusion of any one or all of the impurities and oxygen.

For example, when the conductor 503a has a function of inhibiting diffusion of oxygen, a reduction in conductivity of the conductor 503b due to oxidation can be inhibited.

In addition, in the case where the conductor 503 also functions as a wiring, a conductive material with high conductivity that contains tungsten, copper, or aluminum as its main component is preferably used for the conductor 503b. Note that although the conductor 503 is illustrated to have a stacked layer of the conductor 503a and the conductor 503b in this embodiment, the conductor 503 may have a single-layer structure.

The insulator 520, the insulator 522, and the insulator 524 have a function of a second gate insulating film.

Here, an insulator containing oxygen more than that in the stoichiometric composition is preferably used as the insulator 524 in contact with the oxide 530. Such oxygen is easily released from the insulator by heating. In this specification and the like, oxygen released by heating is sometimes referred to as “excess oxygen.” That is, a region containing excess oxygen (also referred to as an “excess-oxygen region”) is preferably formed in the insulator 524. When such an insulator containing excess oxygen is provided in contact with the oxide 530, oxygen vacancies (Vo) in the oxide 530 can be reduced and the reliability of the transistor 500 can be improved. Note that when hydrogen enters the oxygen vacancies in the oxide 530, such defects (hereinafter, referred to as VoH in some cases) serve as donors and generate electrons serving as carriers in some cases. In addition, in some cases, bonding of part of hydrogen to oxygen bonded to a metal atom generates electrons serving as carriers. Thus, a transistor using an oxide semiconductor that contains a large amount of hydrogen is likely to be normally-on (a state where a channel exists even without application of voltage to a gate electrode and current flows through the transistor). Moreover, hydrogen in an oxide semiconductor is easily transferred by stress such as heat or an electric field; thus, the reliability of the transistor might be reduced when the oxide semiconductor contains a large amount of hydrogen. In one embodiment of the present invention, VoH in the oxide 530 is preferably reduced as much as possible so that the oxide 530 becomes a highly purified intrinsic or substantially highly purified intrinsic oxide. It is important to remove impurities such as moisture and hydrogen in an oxide semiconductor (this treatment is also referred to as “dehydration” or “dehydrogenation treatment”) and to compensate for oxygen vacancies by supplying oxygen to the oxide semiconductor (this treatment is also referred to as “oxygen adding treatment”) in order to obtain an oxide semiconductor whose VoH is sufficiently reduced. When an oxide semiconductor with sufficiently reduced impurities such as VoH is used for a channel formation region of a transistor, stable electrical characteristics can be given.

As the insulator including the excess-oxygen region, specifically, an oxide material that releases part of oxygen by heating is preferably used. An oxide that releases oxygen by heating is an oxide film in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. Note that the temperature of the film surface in the TDS analysis is preferably within the range of higher than or equal to 100° C. and lower than or equal to 700° C., or higher than or equal to 100° C. and lower than or equal to 400° C.

In addition, any one or more of heat treatment, microwave treatment, and RF treatment may be performed in a state in which the insulator including the excess-oxygen region and the oxide 530 are in contact with each other. By the treatment, water or hydrogen in the oxide 530 can be removed. For example, in the oxide 530, dehydrogenation can be performed when reaction in which a bond of VoH is cut occurs, i.e., reaction of “VoH→Vo+H” occurs. Part of hydrogen generated at this time is bonded to oxygen and is removed as H₂O from the oxide 530 or an insulator in the vicinity of the oxide 530 in some cases. In other cases, part of hydrogen is gettered by a conductor 542.

In addition, for the microwave treatment, for example, it is suitable to use an apparatus including a power supply that generates high-density plasma or an apparatus including a power supply that applies RF to a substrate side. For example, high-density oxygen radicals can be generated with the use of an oxygen-containing gas and high-density plasma, and by applying RF to the substrate side, the oxygen radicals generated by the high-density plasma can be efficiently introduced into the oxide 530 or the insulator in the vicinity of the oxide 530. Furthermore, pressure in the microwave treatment is higher than or equal to 133 Pa, preferably higher than or equal to 200 Pa, further preferably higher than or equal to 400 Pa. Moreover, as a gas introduced into an apparatus for performing the microwave treatment, for example, oxygen and argon are used and the oxygen flow rate ratio (O₂/(O₂+Ar)) is lower than or equal to 50%, preferably higher than or equal to 10% and lower than or equal to 30%.

In addition, in the manufacturing process of the transistor 500, it is suitable to perform the heat treatment with the surface of the oxide 530 exposed. The heat treatment is performed at higher than or equal to 100° C. and lower than or equal to 450° C., further preferably higher than or equal to 350° C. and lower than or equal to 400° C., for example. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, the heat treatment is preferably performed in an oxygen atmosphere. Accordingly, oxygen can be supplied to the oxide 530 to reduce oxygen vacancies (Vo). Alternatively, the heat treatment may be performed under reduced pressure. Alternatively, the heat treatment may be performed in such a manner that heat treatment is performed in a nitrogen gas or inert gas atmosphere, and then heat treatment is performed in an atmosphere containing an oxidizing gas at higher than or equal to 10 ppm, higher than or equal to 1%, or higher than or equal to 10% in order to compensate for released oxygen. Alternatively, the heat treatment may be performed in such a manner that heat treatment is performed in an atmosphere containing an oxidizing gas at higher than or equal to 10 ppm, higher than or equal to 1%, or higher than or equal to 10%, and then heat treatment is successively performed in a nitrogen gas or inert gas atmosphere.

Note that oxygen adding treatment performed on the oxide 530 can promote reaction in which oxygen vacancies in the oxide 530 are filled with supplied oxygen, i.e., reaction of “Vo+O→null.” Furthermore, hydrogen remaining in the oxide 530 reacts with supplied oxygen, so that the hydrogen can be removed as H₂O (dehydration). This can inhibit recombination of hydrogen remaining in the oxide 530 with oxygen vacancies and formation of VoH.

In addition, in the case where the insulator 524 includes an excess-oxygen region, it is preferable that the insulator 522 have a function of inhibiting diffusion of oxygen (e.g., an oxygen atom, an oxygen molecule, or the like) (through which oxygen is less likely to pass).

When the insulator 522 has a function of inhibiting diffusion of oxygen, impurities, or the like, oxygen contained in the oxide 530 is not diffused into the insulator 520 side, which is preferable. Furthermore, the conductor 503 can be inhibited from reacting with oxygen contained in the insulator 524, the oxide 530, or the like.

For the insulator 522, a single layer or stacked layers of an insulator containing what is called a high-k material such as aluminum oxide, hafnium oxide, an oxide containing aluminum and hafnium (hafnium aluminate), tantalum oxide, zirconium oxide, lead zirconate titanate (PZT), strontium titanate (SrTiO₃), or (Ba,Sr)TiO₃ (BST) are preferably used, for example. As miniaturization and high integration of transistors progress, a problem such as leakage current might arise because of a thinner gate insulating film. When a high-k material is used for an insulator functioning as the gate insulating film, a gate potential during transistor operation can be reduced while the physical thickness is maintained.

It is particularly preferable to use an insulator containing an oxide of one or both of aluminum and hafnium, which is an insulating material having a function of inhibiting diffusion of impurities, oxygen, and the like (through which oxygen is less likely to pass). Aluminum oxide, hafnium oxide, an oxide containing aluminum and hafnium (hafnium aluminate), or the like is preferably used for the insulator containing an oxide of one or both of aluminum and hafnium. In the case where the insulator 522 is formed using such a material, the insulator 522 functions as a layer that inhibits release of oxygen from the oxide 530 or mixing of impurities such as hydrogen from the periphery of the transistor 500 into the oxide 530.

Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators may be subjected to nitriding treatment. The insulator over which silicon oxide, silicon oxynitride, or silicon nitride is stacked may be used.

In addition, it is preferable that the insulator 520 be thermally stable. For example, silicon oxide and silicon oxynitride are suitable because they are thermally stable. Furthermore, the combination of an insulator that is a high-k material and silicon oxide or silicon oxynitride enables the insulator 520 to have a stacked-layer structure that has thermal stability and high relative permittivity.

Note that in the transistor 500 in FIG. 15A and FIG. 15B, the insulator 520, the insulator 522, and the insulator 524 are illustrated as the second gate insulating film having a stacked-layer structure of three layers; however, the second gate insulating film may be a single layer or may have a stacked-layer structure of two layers or four or more layers. In that case, without limitation to a stacked-layer structure formed of the same material, a stacked-layer structure formed of different materials may be employed.

In the transistor 500, a metal oxide functioning as an oxide semiconductor is used as the oxide 530 including the channel formation region. For example, as the oxide 530, a metal oxide such as an In-M-Zn oxide (the element M is one kind or a plurality of kinds selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like) is preferably used.

The metal oxide functioning as an oxide semiconductor may be formed by a sputtering method or an ALD (Atomic Layer Deposition) method. Note that the metal oxide functioning as an oxide semiconductor will be described in detail in another embodiment.

In addition, as the metal oxide functioning as the channel formation region in the oxide 530, a metal oxide whose bandgap is wider than or equal to 2 eV, preferably wider than or equal to 2.5 eV is preferably used. The use of a metal oxide having such a wide bandgap can reduce the off-state current of the transistor.

When the oxide 530 includes the oxide 530a under the oxide 530b, it is possible to inhibit diffusion of impurities into the oxide 530b from the components formed below the oxide 530a.

Note that the oxide 530 preferably has a plurality of oxide layers that differ in the atomic ratio of metal atoms. Specifically, the atomic ratio of the element M to the constituent elements in the metal oxide used as the oxide 530a is preferably higher than the atomic ratio of the element M to the constituent elements in the metal oxide used as the oxide 530b. In addition, the atomic ratio of the element M to In in the metal oxide used as the oxide 530a is preferably higher than the atomic ratio of the element M to In in the metal oxide used as the oxide 530b. Furthermore, the atomic ratio of In to the element Min the metal oxide used as the oxide 530b is preferably higher than the atomic ratio of In to the element Min the metal oxide used as the oxide 530a.

In addition, the energy of the conduction band minimum of the oxide 530a is preferably higher than the energy of the conduction band minimum of the oxide 530b. In other words, the electron affinity of the oxide 530a is preferably smaller than the electron affinity of the oxide 530b.

Here, the energy level of the conduction band minimum gradually changes at a junction portion of the oxide 530a and the oxide 530b. In other words, the energy level of the conduction band minimum at the junction portion of the oxide 530a and the oxide 530b continuously changes or is continuously connected. To change the energy level gradually, the density of defect states in a mixed layer formed at an interface between the oxide 530a and the oxide 530b is preferably made low.

Specifically, when the oxide 530a and the oxide 530b contain a common element (as a main component) in addition to oxygen, a mixed layer with a low density of defect states can be formed. For example, in the case where the oxide 530b is an In—Ga—Zn oxide, an In—Ga—Zn oxide, a Ga—Zn oxide, gallium oxide, or the like is preferably used for the oxide 530a.

At this time, the oxide 530b serves as a main carrier path. When the oxide 530a has the above structure, the density of defect states at the interface between the oxide 530a and the oxide 530b can be made low. Thus, the influence of interface scattering on carrier conduction is small, and the transistor 500 can have high on-state current.

The conductor 542a and the conductor 542b functioning as the source electrode and the drain electrode are provided over the oxide 530b. For the conductor 542a and conductor 542b, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing the above metal element; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. In addition, tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that retain their conductivity even after absorbing oxygen. Furthermore, a metal nitride film of tantalum nitride or the like is preferable because it has a barrier property against hydrogen or oxygen.

In addition, although the conductor 542a and the conductor 542b each having a single-layer structure are illustrated in FIG. 15A, a stacked-layer structure of two or more layers may be employed. For example, it is preferable to stack a tantalum nitride film and a tungsten film. Alternatively, a titanium film and an aluminum film may be stacked. Alternatively, a two-layer structure where an aluminum film is stacked over a tungsten film, a two-layer structure where a copper film is stacked over a copper-magnesium-aluminum alloy film, a two-layer structure where a copper film is stacked over a titanium film, or a two-layer structure where a copper film is stacked over a tungsten film may be employed.

Other examples include a three-layer structure where a titanium film or a titanium nitride film is formed, an aluminum film or a copper film is stacked over the titanium film or the titanium nitride film, and a titanium film or a titanium nitride film is formed over the aluminum film or the copper film; and a three-layer structure where a molybdenum film or a molybdenum nitride film is formed, an aluminum film or a copper film is stacked over the molybdenum film or the molybdenum nitride film, and a molybdenum film or a molybdenum nitride film is formed over the aluminum film or the copper film. Note that a transparent conductive material containing indium oxide, tin oxide, or zinc oxide may be used.

In addition, as illustrated in FIG. 15A, a region 543a and a region 543b are sometimes formed as low-resistance regions at an interface between the oxide 530 and the conductor 542a (the conductor 542b) and in the vicinity of the interface. In that case, the region 543a functions as one of a source region and a drain region, and the region 543b functions as the other of the source region and the drain region. Furthermore, the channel formation region is formed in a region between the region 543a and the region 543b.

When the conductor 542a (the conductor 542b) is provided to be in contact with the oxide 530, the oxygen concentration in the region 543a (the region 543b) sometimes decreases. In addition, a metal compound layer that contains the metal contained in the conductor 542a (the conductor 542b) and the component of the oxide 530 is sometimes formed in the region 543a (the region 543b). In such a case, the carrier density of the region 543a (the region 543b) increases, and the region 543a (the region 543b) becomes a low-resistance region.

The insulator 544 is provided to cover the conductor 542a and the conductor 542b and inhibits oxidation of the conductor 542a and the conductor 542b. In this case, the insulator 544 may be provided to cover a side surface of the oxide 530 and to be in contact with the insulator 524.

A metal oxide containing one kind or two or more kinds selected from hafnium, aluminum, gallium, yttrium, zirconium, tungsten, titanium, tantalum, nickel, germanium, neodymium, lanthanum, magnesium, and the like can be used for the insulator 544. Alternatively, silicon nitride oxide, silicon nitride, or the like can be used for the insulator 544.

It is particularly preferable to use an insulator containing an oxide of one or both of aluminum and hafnium, such as aluminum oxide, hafnium oxide, or an oxide containing aluminum and hafnium (hafnium aluminate), as the insulator 544. In particular, hafnium aluminate has higher heat resistance than a hafnium oxide film. Therefore, hafnium aluminate is preferable because it is less likely to be crystallized by heat treatment in a later step. Note that the insulator 544 is not an essential component when the conductor 542a and the conductor 542b are oxidation-resistant materials or materials that do not significantly lose their conductivity even after absorbing oxygen. Design is appropriately set in consideration of required transistor characteristics.

When the insulator 544 is included, diffusion of impurities such as water and hydrogen contained in the insulator 580 into the oxide 530b can be inhibited. Furthermore, oxidation of the conductor 542 due to excess oxygen contained in the insulator 580 can be inhibited.

The insulator 545 functions as a first gate insulating film. Like the insulator 524, the insulator 545 is preferably formed using an insulator that contains excess oxygen and releases oxygen by heating.

Specifically, silicon oxide containing excess oxygen, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride are preferable because they are thermally stable.

When an insulator containing excess oxygen is provided as the insulator 545, oxygen can be effectively supplied from the insulator 545 to the channel formation region of the oxide 530b. Furthermore, as in the insulator 524, the concentration of impurities such as water or hydrogen in the insulator 545 is preferably reduced. The thickness of the insulator 545 is preferably greater than or equal to 1 nm and less than or equal to 20 nm.

Furthermore, to efficiently supply excess oxygen contained in the insulator 545 to the oxide 530, a metal oxide may be provided between the insulator 545 and the conductor 560. The metal oxide preferably inhibits diffusion of oxygen from the insulator 545 to the conductor 560. Providing the metal oxide that inhibits diffusion of oxygen inhibits diffusion of excess oxygen from the insulator 545 to the conductor 560. That is, a reduction in the amount of excess oxygen supplied to the oxide 530 can be inhibited. Moreover, oxidation of the conductor 560 due to excess oxygen can be inhibited. For the metal oxide, a material that can be used for the insulator 544 is used.

Note that the insulator 545 may have a stacked-layer structure like the second gate insulating film. As miniaturization and high integration of transistors progress, a problem such as leakage current might arise because of a thinner gate insulating film. For that reason, when the insulator functioning as the gate insulating film has a stacked-layer structure of a high-k material and a thermally stable material, a gate potential during transistor operation can be reduced while the physical thickness is maintained. Furthermore, the stacked-layer structure can be thermally stable and have high relative permittivity.

Although the conductor 560 that functions as the first gate electrode and has a two-layer structure is illustrated in FIG. 15A and FIG. 15B, a single-layer structure or a stacked-layer structure of three or more layers may be employed.

For the conductor 560a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, and the like), and a copper atom. Alternatively, it is preferable to use a conductive material having a function of inhibiting diffusion of oxygen (e.g., at least one of an oxygen atom, an oxygen molecule, and the like). When the conductor 560a has a function of inhibiting diffusion of oxygen, it is possible to inhibit a reduction in conductivity of the conductor 560b due to oxidation caused by oxygen contained in the insulator 545. As a conductive material having a function of inhibiting diffusion of oxygen, for example, tantalum, tantalum nitride, ruthenium, ruthenium oxide, or the like is preferably used. Alternatively, for the conductor 560a, the oxide semiconductor that can be used as the oxide 530 can be used. In that case, when the conductor 560b is deposited by a sputtering method, the conductor 560a can have a reduced electrical resistance value to be a conductor. Such a conductor can be referred to as an OC (Oxide Conductor) electrode.

In addition, a conductive material containing tungsten, copper, or aluminum as its main component is preferably used for the conductor 560b. Furthermore, the conductor 560b also functions as a wiring and thus a conductor having high conductivity is preferably used. For example, a conductive material containing tungsten, copper, or aluminum as its main component can be used. Moreover, the conductor 560b may have a stacked-layer structure, for example, a stacked-layer structure of the above conductive material and titanium or titanium nitride.

The insulator 580 is provided over the conductor 542a and the conductor 542b with the insulator 544 therebetween. The insulator 580 preferably includes an excess-oxygen region. For example, the insulator 580 preferably contains silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, resin, or the like. In particular, silicon oxide and silicon oxynitride are preferable because they are thermally stable. In particular, silicon oxide and porous silicon oxide are preferable because an excess-oxygen region can be easily formed in a later step.

The insulator 580 preferably includes an excess-oxygen region. When the insulator 580 that releases oxygen by heating is provided, oxygen in the insulator 580 can be efficiently supplied to the oxide 530. Note that the concentration of impurities such as water or hydrogen in the insulator 580 is preferably reduced.

The opening of the insulator 580 is formed to overlap with the region between the conductor 542a and the conductor 542b. Accordingly, the conductor 560 is formed to be embedded in the opening of the insulator 580 and the region between the conductor 542a and the conductor 542b.

The gate length needs to be short for miniaturization of the semiconductor device, but it is necessary to prevent a reduction in conductivity of the conductor 560. When the conductor 560 is made thick to achieve this, the conductor 560 might have a shape with a high aspect ratio. In this embodiment, the conductor 560 is provided to be embedded in the opening of the insulator 580; thus, even when the conductor 560 has a shape with a high aspect ratio, the conductor 560 can be formed without collapsing during the process.

The insulator 574 is preferably provided in contact with a top surface of the insulator 580, a top surface of the conductor 560, and a top surface of the insulator 545. When the insulator 574 is deposited by a sputtering method, excess-oxygen regions can be provided in the insulator 545 and the insulator 580. Accordingly, oxygen can be supplied from the excess-oxygen regions to the oxide 530.

For example, a metal oxide containing one kind or two or more kinds selected from hafnium, aluminum, gallium, yttrium, zirconium, tungsten, titanium, tantalum, nickel, germanium, magnesium, and the like can be used as the insulator 574.

In particular, aluminum oxide has a high barrier property, and even a thin aluminum oxide film having a thickness of greater than or equal to 0.5 nm and less than or equal to 3.0 nm can inhibit diffusion of hydrogen and nitrogen. Accordingly, aluminum oxide deposited by a sputtering method serves as an oxygen supply source and can also have a function of a barrier film against impurities such as hydrogen.

In addition, an insulator 581 functioning as an interlayer film is preferably provided over the insulator 574. As in, for example, the insulator 524, the concentration of impurities such as water or hydrogen in the insulator 581 is preferably reduced.

Furthermore, a conductor 540a and a conductor 540b are positioned in openings formed in the insulator 581, the insulator 574, the insulator 580, and the insulator 544. The conductor 540a and the conductor 540b are provided to face each other with the conductor 560 therebetween. The structures of the conductor 540a and the conductor 540b are similar to those of a conductor 546 and a conductor 548 that will be described later.

An insulator 582 is provided over the insulator 581. A substance having a barrier property against oxygen, hydrogen, or the like is preferably used for the insulator 582. Therefore, a material similar to that for the insulator 514 can be used for the insulator 582. For the insulator 582, a metal oxide such as aluminum oxide, hafnium oxide, or tantalum oxide is preferably used, for example.

In particular, aluminum oxide has an excellent blocking effect that prevents the passage of both oxygen and impurities such as hydrogen and moisture which are factors of fluctuation in electrical characteristics of the transistor. Accordingly, aluminum oxide can prevent mixing of impurities such as hydrogen and moisture into the transistor 500 during and after the manufacturing process of the transistor. In addition, release of oxygen from the oxide included in the transistor 500 can be inhibited. Therefore, aluminum oxide is suitably used for the protective film of the transistor 500.

In addition, an insulator 586 is provided over the insulator 582. For the insulator 586, a material similar to that for the insulator 320 can be used. Furthermore, when a material with comparatively low permittivity is used for these insulators, parasitic capacitance between wirings can be reduced. A silicon oxide film, a silicon oxynitride film, or the like can be used for the insulator 586, for example.

Furthermore, the conductor 546, the conductor 548, and the like are embedded in the insulator 520, the insulator 522, the insulator 524, the insulator 544, the insulator 580, the insulator 574, the insulator 581, the insulator 582, and the insulator 586.

The conductor 546 and the conductor 548 have functions of plugs or wirings that are connected to the capacitor 600, the transistor 500, or the transistor 550. The conductor 546 and the conductor 548 can be provided using materials similar to those for the conductor 328 and the conductor 330.

In addition, after the transistor 500 is formed, an opening may be formed to surround the transistor 500 and an insulator having a high barrier property against hydrogen or water may be formed to cover the opening. Surrounding the transistor 500 by the insulator having a high barrier property can prevent entry of moisture and hydrogen from the outside. Alternatively, a plurality of transistors 500 may be collectively surrounded by the insulator having a high barrier property against hydrogen or water. Note that when an opening is formed to surround the transistor 500, for example, formation of an opening reaching the insulator 522 or the insulator 514 and formation of the insulator having a high barrier property to be in contact with the insulator 522 or the insulator 514 are suitable because these formation steps can also serve as some of the manufacturing steps of the transistor 500. Note that the insulator having a high barrier property against hydrogen or water is formed using a material similar to that for the insulator 522 or the insulator 514, for example.

Next, the capacitor 600 is provided above the transistor 500. The capacitor 600 includes a conductor 610, a conductor 620, and an insulator 630.

In addition, a conductor 612 may be provided over the conductor 546 and the conductor 548. The conductor 612 has a function of a plug or a wiring that is connected to the transistor 500. The conductor 610 has a function of an electrode of the capacitor 600. Note that the conductor 612 and the conductor 610 can be formed in parallel.

For the conductor 612 and the conductor 610, a metal film containing an element selected from molybdenum, titanium, tantalum, tungsten, aluminum, copper, chromium, neodymium, and scandium; a metal nitride film containing the above element as its component (a tantalum nitride film, a titanium nitride film, a molybdenum nitride film, or a tungsten nitride film); or the like can be used. Alternatively, it is possible to employ a conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added.

Although the conductor 612 and the conductor 610 each having a single-layer structure are illustrated in this embodiment, the structure is not limited thereto; a stacked-layer structure of two or more layers may be employed. For example, between a conductor having a barrier property and a conductor having high conductivity, a conductor that is highly adhesive to the conductor having a barrier property and the conductor having high conductivity may be formed.

The conductor 620 is provided to overlap the conductor 610 with the insulator 630 therebetween. Note that a conductive material such as a metal material, an alloy material, or a metal oxide material can be used for the conductor 620. It is preferable to use a high-melting-point material that has both heat resistance and conductivity, such as tungsten or molybdenum, and it is particularly preferable to use tungsten. In the case where the conductor 620 is formed in parallel with another component such as a conductor, copper (Cu), aluminum (Al), or the like, which is a low-resistance metal material, may be used.

An insulator 640 is provided over the conductor 620 and the insulator 630. The insulator 640 can be provided using a material similar to that for the insulator 320. In addition, the insulator 640 may function as a planarization film that covers an uneven shape therebelow.

With the use of this structure, a semiconductor device using a transistor including an oxide semiconductor can be miniaturized or highly integrated.

As a substrate that can be used for the semiconductor device according to one embodiment of the present invention, a glass substrate, a quartz substrate, a sapphire substrate, a ceramic substrate, a metal substrate (e.g., a stainless steel substrate, a substrate including stainless steel foil, a tungsten substrate, a substrate including tungsten foil, or the like), a semiconductor substrate (e.g., a single crystal semiconductor substrate, a polycrystalline semiconductor substrate, a compound semiconductor substrate, or the like), an SOI (silicon on Insulator) substrate, or the like can be given. Alternatively, a plastic substrate having heat resistance to processing temperature in this embodiment may be used. Examples of the glass substrate include barium borosilicate glass, aluminosilicate glass, aluminoborosilicate glass, and soda lime glass. Alternatively, crystallized glass can be used, for example.

Alternatively, a flexible substrate; an attachment film; paper or a base film including a fibrous material; or the like can be used as the substrate. As examples of the flexible substrate, the attachment film, the base material film, and the like, the following can be given. Examples include plastics typified by polyethylene terephthalate (PET), polyethylene naphthalate (PEN), polyether sulfone (PES), and polytetrafluoroethylene (PTFE). Another example is a synthetic resin such as acrylic. Other examples include polypropylene, polyester, polyvinyl fluoride, and polyvinyl chloride. Other examples include polyamide, polyimide, an aramid resin, an epoxy resin, an inorganic evaporated film, and paper. In particular, the use of a semiconductor substrate, a single crystal substrate, an SOI substrate, or the like for the manufacture of transistors enables the manufacture of small-sized transistors with a small variation in characteristics, size, shape, or the like and high current capability. When a circuit is formed with such transistors, lower power consumption of the circuit or higher integration of the circuit can be achieved.

Alternatively, a flexible substrate may be used as the substrate, and a transistor, a resistor, a capacitor, and/or the like may be formed directly on the flexible substrate. Alternatively, a separation layer may be provided between the substrate and the transistor, the resistor, the capacitor, and/or the like. After part or the whole of a semiconductor device is completed over the separation layer, the separation layer can be used for separation from the substrate and transfer to another substrate. In such a case, the transistor, the resistor, the capacitor, and/or the like can be transferred to a substrate having low heat resistance or a flexible substrate. Note that as the separation layer, a stacked-layer structure of a tungsten film and a silicon oxide film that are inorganic films, a structure in which an organic resin film of polyimide or the like is formed over a substrate, a silicon film containing hydrogen, or the like can be used, for example.

That is, a semiconductor device may be formed over one substrate and then transferred to another substrate. Examples of a substrate to which a semiconductor device is transferred include, in addition to the above substrates over which transistors can be formed, a paper substrate, a cellophane substrate, an aramid film substrate, a polyimide film substrate, a stone substrate, a wood substrate, a cloth substrate (including a natural fiber (silk, cotton, or hemp), a synthetic fiber (nylon, polyurethane, or polyester), a regenerated fiber (acetate, cupro, rayon, or regenerated polyester), or the like), a leather substrate, and a rubber substrate. With the use of these substrates, the manufacture of a flexible semiconductor device, the manufacture of a robust semiconductor device, provision of high heat resistance, a reduction in weight, or a reduction in thickness can be achieved.

Providing a semiconductor device over a flexible substrate can inhibit an increase in weight and can provide a robust semiconductor device.

Note that the transistor 550 illustrated in FIG. 14 is an example and the structure is not limited thereto; an appropriate transistor is used in accordance with a circuit structure, a driving method, or the like. For example, when the semiconductor device is a circuit having single polarity that is composed of only OS transistors, which means the same-polarity transistors such as n-channel transistors only, for example, the transistor 550 has a structure similar to that of the transistor 500.

The configurations, structures, methods, and the like described in this embodiment can be used in combination as appropriate with the configurations, structures, methods, and the like described in the other embodiments.

### Embodiment 3

In this embodiment, cross-sectional structure examples of semiconductor devices including the OS transistors described in the above embodiments, such as a DOSRAM and a NOSRAM, are described.

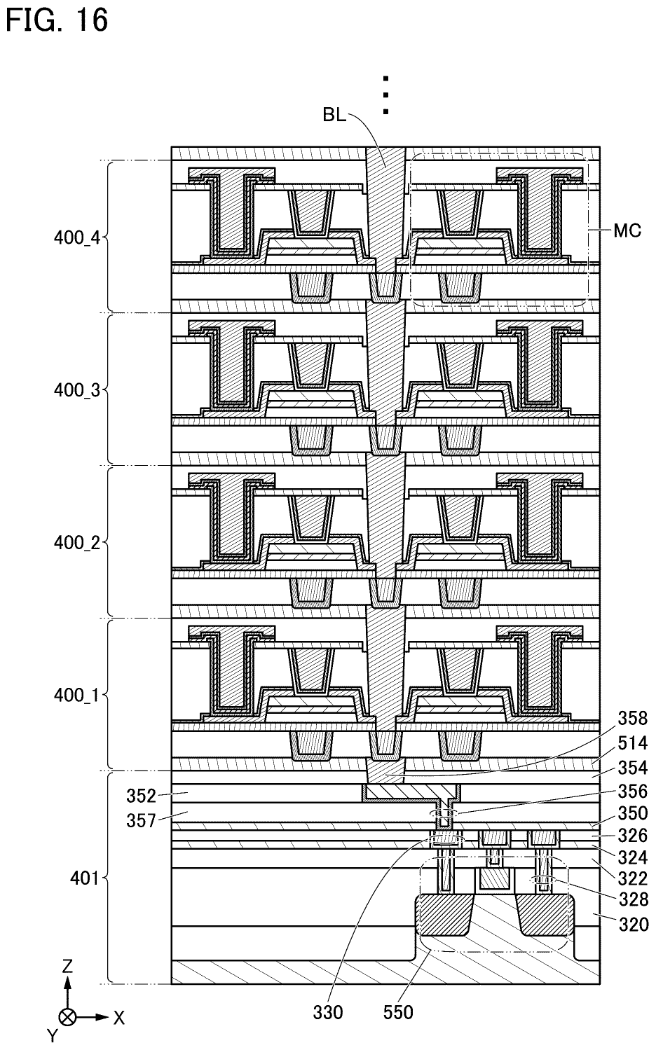

FIG. 16 illustrates a cross-sectional structure example of the case of using a DOSRAM circuit structure. In the example illustrated in FIG. 16, a memory layer 400_1 to a memory layer 400_4 are stacked over a driver circuit layer 401.

FIG. 16 also illustrates an example of the transistor 550 included in the driver circuit layer 401. As the transistor 550, the transistor 550 described in the above embodiment can be used.

Note that the transistor 550 illustrated in FIG. 16 is an example and is not limited to the structure illustrated therein; an appropriate transistor can be used in accordance with a circuit structure or a driving method.

A wiring layer provided with an interlayer film, a wiring, a plug, and the like may be provided between the driver circuit layer 401 and the memory layers 400 or between a h-th memory layer 400 and a (h+1)-th memory layer 400. Note that in this embodiment, for example, the h-th memory layer 400 is referred to as a memory layer 400_h, and the (h+1)-th memory layer 400 is referred to as a memory layer 400_h+1, in some cases. Here, in the example illustrated in FIG. 16, h is an integer greater than or equal to 1 and less than or equal to 3. In addition, in this embodiment, for example, the solutions of “h+α, (α is an integer greater than or equal to 1)” and “h−α” are each an integer greater than or equal to 1 and less than or equal to 4.

In addition, a plurality of wiring layers can be provided in accordance with design. Furthermore, in this specification and the like, a wiring and a plug electrically connected to the wiring may be a single component. That is, part of a conductor functions as a wiring in some cases, and part of a conductor functions as a plug in other cases.

For example, the insulator 320, the insulator 322, the insulator 324, and the insulator 326 are sequentially stacked and provided over the transistor 550 as interlayer films. In addition, for example, the conductor 328 is embedded in the insulator 320 and the insulator 322. Furthermore, for example, the conductor 330 is embedded in the insulator 324 and the insulator 326. Note that the conductor 328 and the conductor 330 each function as a contact plug or a wiring.

In addition, the insulators functioning as interlayer films may also function as planarization films that cover uneven shapes therebelow. For example, a top surface of the insulator 320 may be planarized by planarization treatment using, for example, a chemical mechanical polishing (CMP) method to increase planarity.

A wiring layer may be provided over the insulator 326 and the conductor 330. For example, in FIG. 16, the insulator 350, an insulator 357, the insulator 352, and the insulator 354 are sequentially stacked and provided over the insulator 326 and the conductor 330. Furthermore, the conductor 356 is formed in the insulator 350, the insulator 357, and the insulator 352. The conductor 356 functions as a contact plug or a wiring.

The insulator 514 included in the memory layer 400_1 is provided over the insulator 354. In addition, a conductor 358 is embedded in the insulator 514 and the insulator 354. The conductor 358 functions as a contact plug or a wiring. For example, a bit line BL and the transistor 550 are electrically connected through the conductor 358, the conductor 356, the conductor 330, and the like.

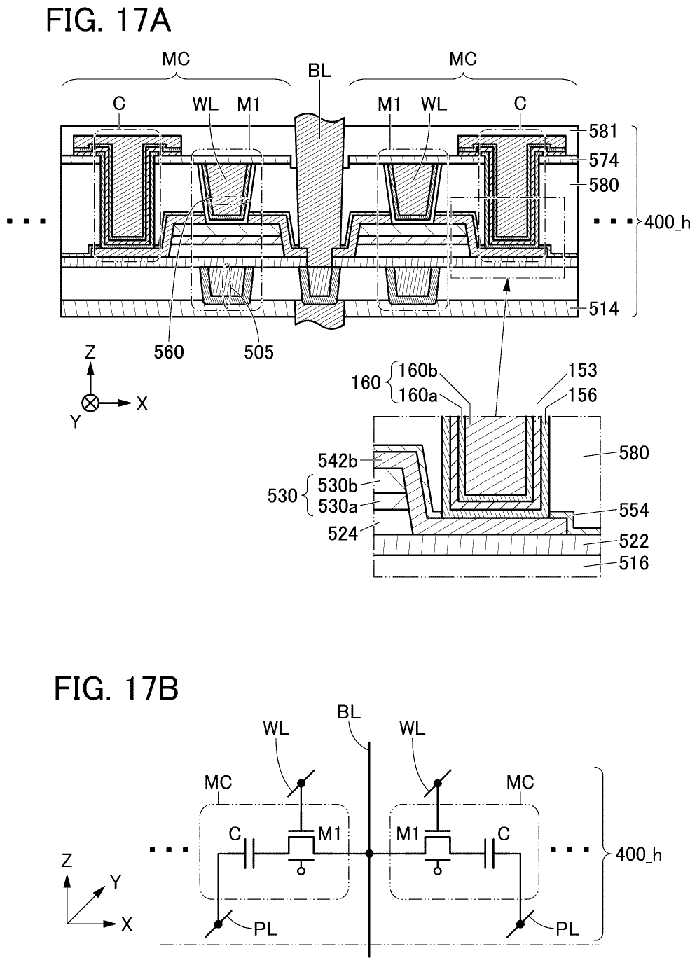

FIG. 17A illustrates a cross-sectional structure example of the memory layer 400_h. In addition, FIG. 17B illustrates an equivalent circuit diagram of FIG. 17A. FIG. 17A illustrates an example where two memory cells MC are electrically connected to one bit line BL.

The memory cells MC illustrated in FIG. 16 and FIG. 17A each include the transistor M1 and a capacitor C. For example, the transistor 500 illustrated in the above embodiment can be used as the transistor M1.

Note that in this embodiment, a modification example of the transistor 500 is illustrated as the transistor M1. Specifically, the transistor M1 differs from the transistor 500 in that the conductor 542a and the conductor 542b extend beyond an edge of the oxide 530.

In addition, the memory cells MC illustrated in FIG. 16 and FIG. 17A each include a conductor 156 that functions as one terminal of the capacitor C, an insulator 153 that functions as a dielectric, and a conductor 160 (a conductor 160a and a conductor 160b) that functions as the other terminal of the capacitor C. The conductor 156 is electrically connected to part of the conductor 542b. Furthermore, the conductor 160 is electrically connected to a wiring PL (not illustrated in FIG. 17A).

The capacitor C is formed in an opening portion that is provided by removal of part of the insulator 574, the insulator 580, and an insulator 554. Since the conductor 156, the insulator 580, and the insulator 554 are formed along a side surface of the opening portion, the conductor 156, the insulator 580, and the insulator 554 are preferably deposited by an ALD method, a CVD method, or the like.

In addition, a conductor that can be used as a conductor 505 or the conductor 560 is used for each of the conductor 156 and the conductor 160. For example, titanium nitride formed by an ALD method is used for the conductor 156. Furthermore, titanium nitride formed by an ALD method is used for the conductor 160a, and tungsten formed by a CVD method is used for the conductor 160b. Note that in the case where the adhesion of tungsten to the insulator 153 is sufficiently high, a single-layer film of tungsten formed by a CVD method may be used for the conductor 160.

An insulator of a high permittivity (high-k) material (a material with high relative permittivity) is preferably used for the insulator 153. As the insulator of a high permittivity material, an oxide, an oxynitride, a nitride oxide, or a nitride containing one or more kinds of metal element selected from aluminum, hafnium, zirconium, gallium, and the like can be used, for example. In addition, the oxide, the oxynitride, the nitride oxide, or the nitride may contain silicon. Furthermore, insulators each formed of the above material can be stacked to be used.

As the insulator of a high permittivity material, aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, an oxide containing silicon and zirconium, an oxynitride containing silicon and zirconium, an oxide containing hafnium and zirconium, an oxynitride containing hafnium and zirconium, or the like can be used, for example. Using such a high permittivity material allows the insulator 153 to be thick enough to inhibit leakage current and can ensure sufficient capacitance of the capacitor C.

In addition, it is preferable to use stacked insulators each formed of the above materials. A stacked structure using a high permittivity material and a material having higher dielectric strength than the high permittivity material is preferably used. An insulating film in which zirconium oxide, aluminum oxide, and zirconium oxide are stacked in this order can be used for the insulator 153, for example. Alternatively, an insulating film in which zirconium oxide, aluminum oxide, zirconium oxide, and aluminum oxide are stacked in this order can be used, for example. Alternatively, an insulating film in which hafnium zirconium oxide, aluminum oxide, hafnium zirconium oxide, and aluminum oxide are stacked in this order can be used. The use of stacked insulators with comparatively high dielectric strength, such as aluminum oxide, can improve the dielectric strength and can inhibit electrostatic breakdown of the capacitor C.

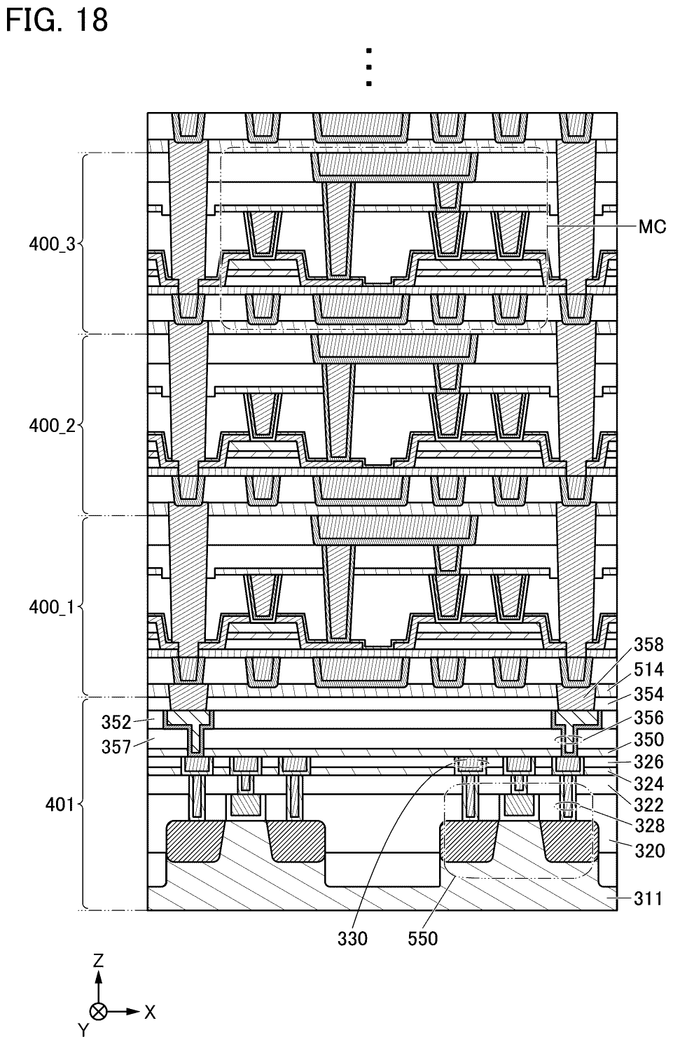

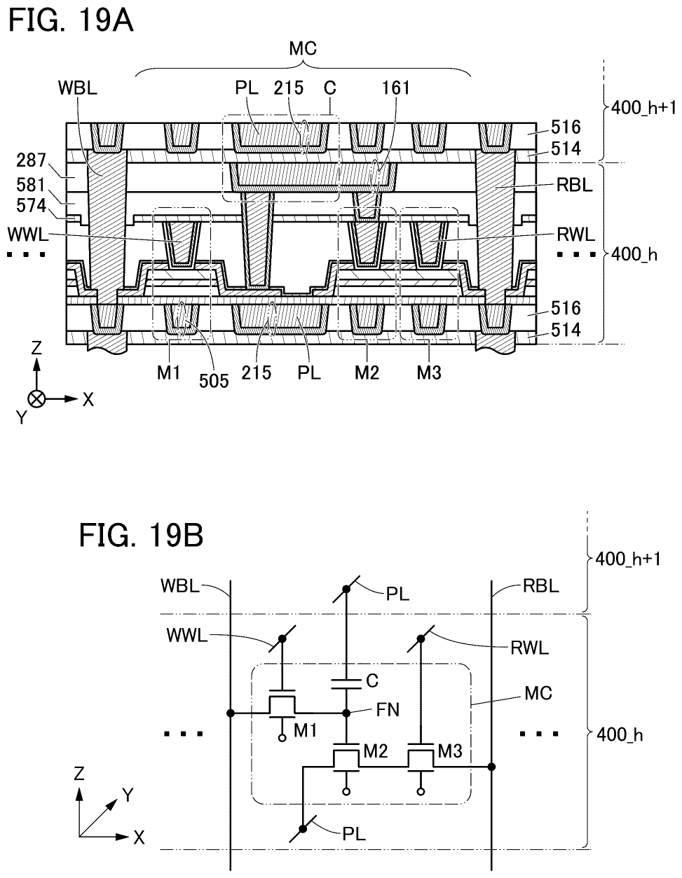

FIG. 18 illustrates a cross-sectional structure example of the case of using a NOSRAM memory cell circuit structure. Note that FIG. 18 is also a modification example of FIG. 16. In addition, FIG. 19A illustrates a cross-sectional structure example of the memory layer 400_h. Furthermore, FIG. 19B illustrates an equivalent circuit diagram of FIG. 19A.

The memory cells MC illustrated in FIG. 18 and FIG. 19A each include the transistor M1, a transistor M2, and a transistor M3 over the insulator 514. In addition, a conductor 215 is provided over the insulator 514. The conductor 215 can be formed using the same material in the same process as those of the conductor 505.

In addition, the transistor M2 and the transistor M3 illustrated in FIG. 18 and FIG. 19A share one island-shaped oxide 530. In other words, part of the one island-shaped oxide 530 functions as a channel formation region of the transistor M2, and another part thereof functions as a channel formation region of the transistor M3. Furthermore, a source of the transistor M2 and a drain of the transistor M3 are shared, or a drain of the transistor M2 and a source of the transistor M3 are shared. Thus, the area occupied by the transistor M2 and the transistor M3 is smaller than that of the case where the transistor M2 and the transistor M3 are independently provided.

In addition, in each of the memory cells MC illustrated in FIG. 18 and FIG. 19A, an insulator 287 is provided over the insulator 581, and a conductor 161 is embedded in the insulator 287. Furthermore, the insulator 514 of the memory layer 400_h+1 is provided over the insulator 287 and the conductor 161.

In FIG. 18 and FIG. 19A, the conductor 215 of the memory layer 400_h+1 functions as one terminal of the capacitor C, the insulator 514 of the memory layer 400_h+1 functions as a dielectric of the capacitor C, and the conductor 161 functions as the other terminal of the capacitor C. Furthermore, the other of a source and a drain of the transistor M1 is electrically connected to the conductor 161 through a contact plug, and a gate of the transistor M2 is electrically connected to the conductor 161 through another contact plug.

The configurations, structures, methods, and the like described in this embodiment can be used in combination as appropriate with the configurations, structures, methods, and the like described in the other embodiments.

### Embodiment 4

In this embodiment, an OS transistor will be described. In the description of the OS transistor, comparison with the Si transistor will also be briefly described.

### [Os Transistor]

An oxide semiconductor having a low carrier concentration is preferably used for an OS transistor. For example, the carrier concentration in an oxide semiconductor in a channel formation region is lower than or equal to 1×10¹⁸ cm⁻³, preferably lower than 1×10¹⁷ cm³, further preferably lower than 1×10¹⁶ cm⁻³, still further preferably lower than 1×10¹³ cm⁻³, yet further preferably lower than 1×10¹⁰ cm³, and higher than or equal to 1×10⁻⁹ cm³. Note that in the case where the carrier concentration of an oxide semiconductor film is lowered, the impurity concentration in the oxide semiconductor film is lowered to decrease the density of defect states. In this specification and the like, a state with a low impurity concentration and a low density of defect states is referred to as a highly purified intrinsic or substantially highly purified intrinsic state. Note that an oxide semiconductor having a low carrier concentration is sometimes referred to as a highly purified intrinsic or substantially highly purified intrinsic oxide semiconductor.

In addition, a highly purified intrinsic or substantially highly purified intrinsic oxide semiconductor has a low density of defect states and accordingly has a low density of trap states in some cases. Furthermore, electric charge captured by the trap states in the oxide semiconductor takes a long time to disappear and might behave like fixed electric charge. Thus, a transistor whose channel formation region is formed in an oxide semiconductor having a high density of trap states has unstable electrical characteristics in some cases.

Accordingly, in order to stabilize electrical characteristics of the transistor, reducing the impurity concentration in the oxide semiconductor is effective. In addition, in order to reduce the impurity concentration in the oxide semiconductor, it is preferable that the impurity concentration in an adjacent film be also reduced. Examples of impurities include hydrogen and nitrogen. Note that impurities in an oxide semiconductor refer to, for example, elements other than main components of the oxide semiconductor. For example, an element having a concentration lower than 0.1 atomic % can be regarded as an impurity.

In addition, the OS transistor is likely to change its electrical characteristics when impurities and oxygen vacancies exist in the channel formation region in the oxide semiconductor, which might worsen reliability. In some cases, the OS transistor has a defect that is an oxygen vacancy in the oxide semiconductor into which hydrogen enters (hereinafter sometimes referred to as VoH), which generates an electron serving as a carrier. Furthermore, formation of VoH in the channel formation region might increase the donor concentration in the channel formation region. An increase in the donor concentration in the channel formation region might lead to a variation in threshold voltage. Therefore, when the channel formation region in the oxide semiconductor includes oxygen vacancies, the transistor is likely to have normally-on characteristics (characteristics with which, even when no voltage is applied to a gate electrode, a channel exists and current flows through the transistor). Therefore, impurities, oxygen vacancies, and VoH are preferably reduced as much as possible in the channel formation region in the oxide semiconductor.

Furthermore, the bandgap of the oxide semiconductor is preferably wider than the bandgap of silicon (typically 1.1 eV), further preferably wider than or equal to 2 eV, still further preferably wider than or equal to 2.5 eV, yet still further preferably wider than or equal to 3.0 eV. With the use of an oxide semiconductor having a wider bandgap than silicon, the off-state current (also referred to as Ioff) of the transistor can be reduced.

Moreover, in a Si transistor, a short-channel effect (also referred to as an SCE) appears as miniaturization of the transistor proceeds. Thus, it is difficult to miniaturize the Si transistor. One factor in causing the short-channel effect is a narrow bandgap of silicon. In contrast, the OS transistor uses an oxide semiconductor that is a semiconductor material having a wide bandgap, and thus can suppress the short-channel effect. In other words, the OS transistor is a transistor where the short-channel effect does not appear or hardly appears.

Note that the short-channel effect refers to degradation of electrical characteristics that becomes obvious along with miniaturization of a transistor (a decrease in channel length). Specific examples of the short-channel effect include a decrease in threshold voltage, an increase in a subthreshold swing value (sometimes referred to as an S value or S.S.), and an increase in leakage current. Here, the S value refers to the amount of change in gate voltage which makes drain current change by one digit in a subthreshold region at constant drain voltage.

In addition, characteristic length is widely used as an indicator of resistance to a short-channel effect. The characteristic length is an indicator of the curvature of a potential in a channel formation region. The smaller the characteristic length is, the more steeply the potential rises, which means that smaller characteristic length has higher resistance to the short-channel effect.

The OS transistor is an accumulation-type transistor, and the Si transistor is an inversion-type transistor. Thus, the OS transistor has shorter characteristic length between a source region and the channel formation region and shorter characteristic length between a drain region and the channel formation region than the Si transistor. Accordingly, the OS transistor has higher resistance to the short-channel effect than the Si transistor. That is, the OS transistor is more suitable than the Si transistor in the case where a short-channel transistor is to be manufactured.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, a difference in energy of the conduction band minimum between the channel formation region and the source region or the drain region might decrease to higher than or equal to 0.1 eV and lower than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source region and the drain region become n⁺-type regions.

The OS transistor with the above structure can have favorable electrical characteristics even when a semiconductor device is miniaturized or highly integrated. For example, the OS transistor can have favorable electrical characteristics even when the gate length of the OS transistor is less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. In contrast, it is sometimes difficult for the Si transistor to have a gate length less than or equal to 20 nm or less than or equal to 15 nm due to appearance of the short-channel effect. Thus, the OS transistor can be more suitably used as a short-channel transistor than the Si transistor. Note that the gate length refers to the length of a gate electrode in a direction in which carriers move inside a channel formation region during operation of a transistor, which corresponds to the width of a bottom surface of the gate electrode in a plan view of the transistor.

In addition, miniaturization of the OS transistor can improve the high-frequency characteristics of the transistor. Specifically, the cutoff frequency of the transistor can be improved. When the gate length of the OS transistor is within any of the above ranges, the cutoff frequency of the transistor can be made higher than or equal to 50 GHz, preferably higher than or equal to 100 GHz, further preferably higher than or equal to 150 GHz in a room temperature environment, for example.

As described above, the OS transistor has advantageous effects such as low off-state current and capability of being manufactured with short channel length compared to the Si transistor.

The configurations, structures, methods, and the like described in this embodiment can be used in combination as appropriate with the configurations, structures, methods, and the like described in the other embodiments.

### Embodiment 5

This embodiment describes an electronic component, an electronic device, a large computer, space equipment, and a data center (also referred to as a DC) that can use the semiconductor device described in the above embodiment. An electronic component, an electronic device, a large computer, space equipment, and a data center each using the semiconductor device according to one embodiment of the present invention are effective in achieving high performance, e.g., reducing power consumption.

### [Electronic Component]

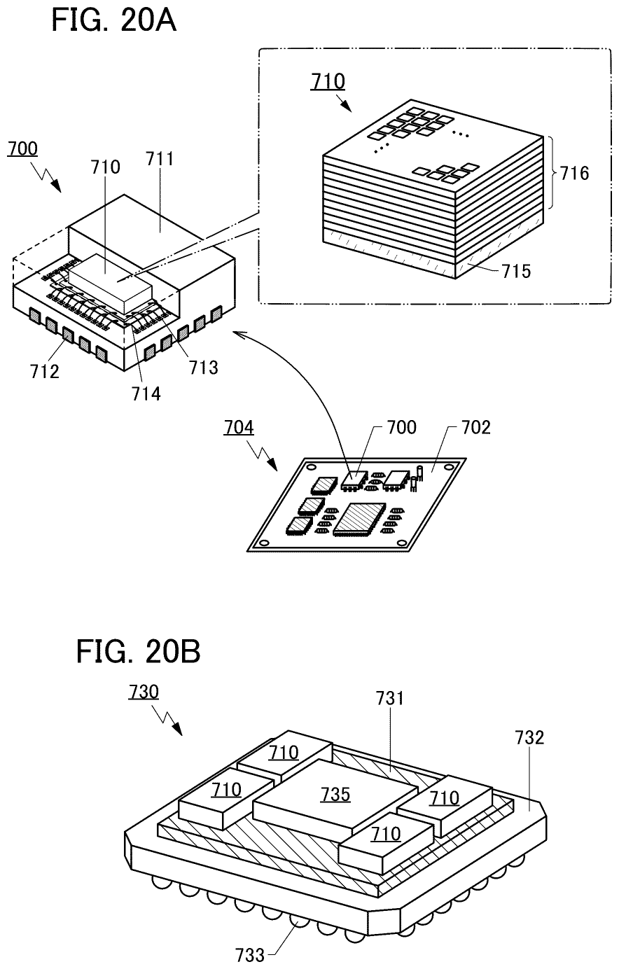

FIG. 20A illustrates a perspective view of a substrate (a mount board 704) on which an electronic component 700 is mounted. The electronic component 700 illustrated in FIG. 20A includes a semiconductor device 710 in a mold 711. FIG. 20A omits illustrations of some parts to show the inside of the electronic component 700. The electronic component 700 includes lands 712 outside the mold 711. The land 712 is electrically connected to an electrode pad 713, and the electrode pad 713 is electrically connected to the semiconductor device 710 via a wire 714. The electronic component 700 is mounted on a printed circuit board 702, for example. A plurality of such electronic components are combined and electrically connected on the printed circuit board 702, so that the mount board 704 is completed.

In addition, the semiconductor device 710 includes a driver circuit layer 715 and a memory layer 716. Note that the memory layer 716 has a structure where a plurality of memory cell arrays are stacked. A stacked-layer structure of the driver circuit layer 715 and the memory layer 716 can be a monolithic stacked-layer structure. In the monolithic stacked-layer structure, layers can be connected without using a through electrode technique such as a TSV (Through Silicon Via) and a bonding technique such as Cu—Cu direct bonding. The monolithic stacked-layer structure of the driver circuit layer 715 and the memory layer 716 enables, for example, what is called an on-chip memory structure where a memory is directly formed on a processor. The on-chip memory structure allows an interface portion between the processor and the memory to operate at high speed.

In addition, with the on-chip memory structure, the size of, for example, a connection wiring can be made smaller than that when the technique using through electrodes such as TSVs is employed; thus, the number of connection pins can be increased. The increase in the number of connection pins enables parallel operation, which can improve the bandwidth of the memory (also referred to as memory bandwidth).

Furthermore, it is preferable that the plurality of memory cell arrays included in the memory layer 716 be formed using OS transistors and be monolithically stacked. The monolithic stacked-layer structure of a plurality of memory cell arrays can improve one or both of the bandwidth of the memory and the access latency of the memory. Note that the bandwidth refers to the data transfer amount per unit time, and the access latency refers to time between data access and start of data transmission. Note that in the case where Si transistors are used for the memory layer 716, the monolithic stacked-layer structure is difficult to form as compared with the case where OS transistors are used for the memory layer 716. Therefore, the OS transistors are superior to the Si transistors in the monolithic stacked-layer structure.

Moreover, the semiconductor device 710 may be called a die. Note that examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

Next, FIG. 20B illustrates a perspective view of an electronic component 730. The electronic component 730 is an example of a SiP (System in Package) or an MCM (Multi Chip Module). In the electronic component 730, an interposer 731 is provided on a package substrate 732 (a printed circuit board), and a semiconductor device 735 and a plurality of semiconductor devices 710 are provided on the interposer 731.

The electronic component 730 using the semiconductor devices 710 as high bandwidth memories (HBM) is illustrated as an example. In addition, the semiconductor device 735 can be used for an integrated circuit such as a CPU, a GPU, or an FPGA.

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. The interposer 731 also has a function of electrically connecting an integrated circuit provided on the interposer 731 to an electrode provided on the package substrate 732. Accordingly, the interposer is sometimes referred to as a “redistribution substrate” or an “intermediate substrate.” Furthermore, a through electrode is provided in the interposer 731 and the through electrode is used to electrically connect an integrated circuit and the package substrate 732 in some cases. Moreover, in a silicon interposer, a TSV can also be used as the through electrode.

In an HBM, many wirings need to be connected to achieve wide memory bandwidth. Therefore, an interposer on which an HBM is mounted requires minute and densely formed wirings. For this reason, a silicon interposer is preferably used as the interposer on which an HBM is mounted.

In addition, in a SiP, an MCM, and the like each using a silicon interposer, a decrease in reliability due to a difference in an expansion coefficient between an integrated circuit and the interposer is less likely to occur. Furthermore, a surface of a silicon interposer has high planarity, and poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected using a silicon interposer, a TSV, and the like, a space for the width of the terminal pitch and the like is needed. Accordingly, in the case where the size of the electronic component 730 is to be reduced, the width of the terminal pitch becomes an issue, which sometimes makes it difficult to provide a large number of wirings for achieving wide memory bandwidth. For this reason, the monolithic stacked-layer structure using the OS transistors is suitable. A composite structure where memory cell arrays stacked using a TSV and monolithically stacked memory cell arrays are combined may be employed.

In addition, a heat sink (a radiator plate) may be provided to overlap the electronic component 730. In the case where a heat sink is provided, the heights of integrated circuits provided on the interposer 731 are preferably aligned with each other. For example, in the electronic component 730 described in this embodiment, the heights of the semiconductor devices 710 and the semiconductor device 735 are preferably aligned with each other.

Electrodes 733 may be provided on a bottom portion of the package substrate 732 to mount the electronic component 730 on another substrate. FIG. 20B illustrates an example where the electrodes 733 are formed of solder balls. When the solder balls are provided in a matrix on the bottom portion of the package substrate 732, BGA (Ball Grid Array) mounting can be achieved. Alternatively, the electrodes 733 may be formed of conductive pins. When the conductive pins are provided in a matrix on the bottom portion of the package substrate 732, PGA (Pin Grid Array) mounting can be achieved.

The electronic component 730 can be mounted on another substrate by a variety of mounting methods not limited to BGA and PGA. Examples of mounting methods include SPGA (Staggered Pin Grid Array), LGA (Land Grid Array), QFP (Quad Flat Package), QFJ (Quad Flat J-leaded package), and QFN (Quad Flat Non-leaded package).

### [Electronic Device]

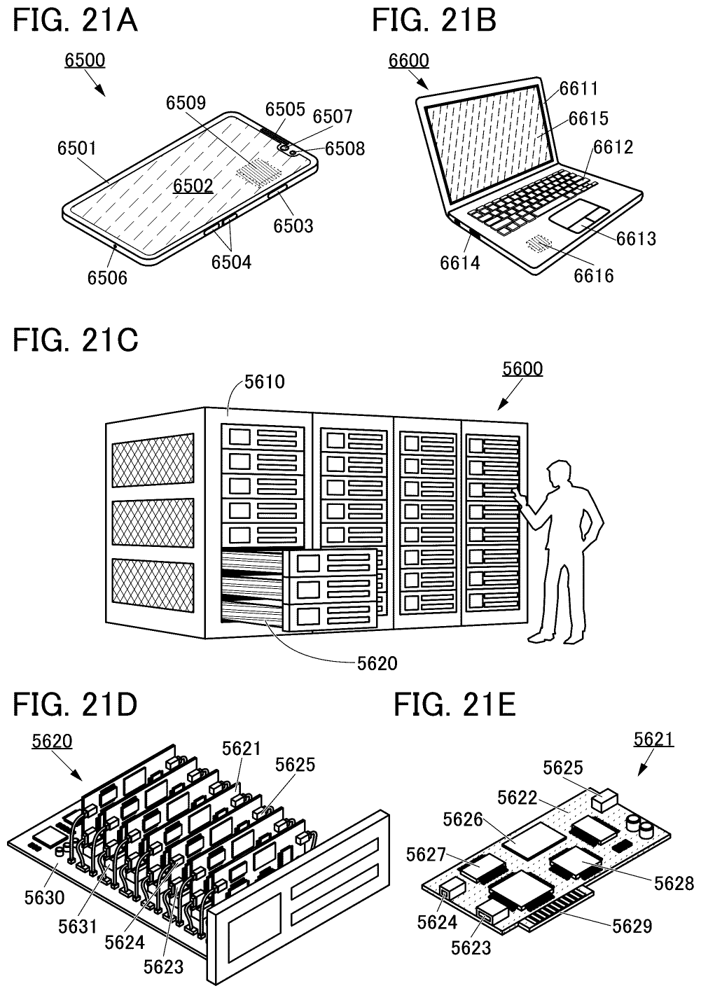

Next, FIG. 21A illustrates a perspective view of an electronic device 6500. The electronic device 6500 illustrated in FIG. 21A is a portable information terminal that can be used for a smartphone. The electronic device 6500 includes a housing 6501, a display portion 6502, a power button 6503, buttons 6504, a speaker 6505, a microphone 6506, a camera 6507, a light source 6508, a control device 6509, and the like. Note that the control device 6509 includes one or more selected from a CPU, a GPU, and a memory device, for example. The semiconductor device according to one embodiment of the present invention can be employed for the display portion 6502, the control device 6509, or the like.

An electronic device 6600 illustrated in FIG. 21B is an information terminal that can be used for a laptop personal computer. The electronic device 6600 includes a housing 6611, a keyboard 6612, a pointing device 6613, an external connection port 6614, a display portion 6615, a control device 6616, and the like. Note that the control device 6616 includes one or more selected from a CPU, a GPU, and a memory device, for example. The semiconductor device according to one embodiment of the present invention can be employed for the control device 6509, the control device 6616, or the like. Note that the semiconductor device according to one embodiment of the present invention is suitably used for each of the control device 6509 and the control device 6616 because power consumption can be reduced.

### [Large Computer]

Next, FIG. 21C illustrates a perspective view of a large computer 5600. In the large computer 5600 illustrated in FIG. 21C, a plurality of rack mount computers 5620 are stored in a rack 5610. Note that the large computer 5600 may also be referred to as a supercomputer.

The computer 5620 can have a structure in a perspective view illustrated in FIG. 21D, for example. In FIG. 21D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 21E is an example of a processing board provided with a CPU, a GPU, a memory device, and the like. The PC card 5621 includes a board 5622. In addition, the board 5622 includes the connection terminal 5623, the connection terminal 5624, the connection terminal 5625, a semiconductor device 5626, a semiconductor device 5627, a semiconductor device 5628, and a connection terminal 5629. Note that FIG. 21E also illustrates semiconductor devices other than the semiconductor device 5626, the semiconductor device 5627, and the semiconductor device 5628; the following description of the semiconductor device 5626, the semiconductor device 5627, and the semiconductor device 5628 is referred to for these semiconductor devices.

The connection terminal 5629 has a shape that can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can each serve as, for example, an interface for performing power supply and signal input to the PC card 5621. As another example, the connection terminal 5623, the connection terminal 5624, and the connection terminal 5625 can each serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In addition, in the case where video signals are output from the connection terminal 5623, the connection terminal 5624, and the connection terminal 5625, an example of the standard for each of the connection terminal 5623, the connection terminal 5624, and the connection terminal 5625 is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected.

The semiconductor device 5627 includes a plurality of terminals, and when the terminals are reflow-soldered, for example, to wirings of the board 5622, the semiconductor device 5627 and the board 5622 can be electrically connected. Examples of the semiconductor device 5627 include an FPGA, a GPU, and a CPU. The electronic component 730 can be used for the semiconductor device 5627, for example.

The semiconductor device 5628 includes a plurality of terminals, and when the terminals are reflow-soldered, for example, to wirings of the board 5622, the semiconductor device 5628 and the board 5622 can be electrically connected. An example of the semiconductor device 5628 is a memory device. The electronic component 700 can be used for the semiconductor device 5628, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device according to one embodiment of the present invention can be suitably used for space equipment such as equipment that processes and stores information.

The semiconductor device according to one embodiment of the present invention can include an OS transistor. A change in electrical characteristics of the OS transistor due to exposure to radiation is small. That is, the OS transistor is highly resistant to radiation and thus can be suitably used even in an environment where radiation can enter. For example, the OS transistor can be suitably used in the case of being used in outer space.

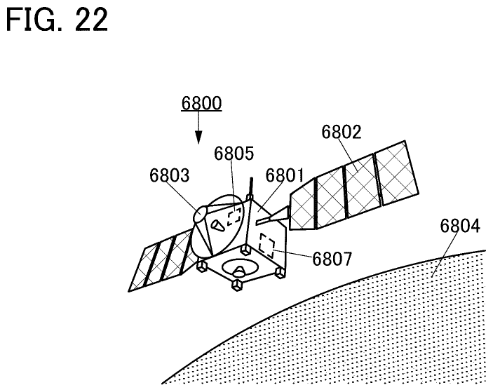

FIG. 22 illustrates an artificial satellite 6800 as an example of space equipment. The artificial satellite 6800 includes a body 6801, solar panels 6802, an antenna 6803, a secondary battery 6805, and a control device 6807. Note that FIG. 22 illustrates a planet 6804 in outer space, for example. Note that outer space refers to, for example, space at an altitude greater than or equal to 100 km, and outer space described in this specification and the like may include the thermosphere, the mesosphere, and the stratosphere.

In addition, although not illustrated in FIG. 22, a battery management system (also referred to as a BMS) or a battery control circuit may be provided in the secondary battery 6805. An OS transistor is suitably used in the battery management system or the battery control circuit because low power consumption and high reliability even in outer space are achieved.

Furthermore, the amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for the operation of the artificial satellite 6800 is generated. However, for example, in a situation where the solar panel is not irradiated with sunlight or in a situation where the amount of sunlight with which the solar panel is irradiated is small, the amount of generated electric power is small. Accordingly, electric power required for the operation of the artificial satellite 6800 might not be generated. In order to operate the artificial satellite 6800 even in the situation where the amount of generated electric power is small, the artificial satellite 6800 is preferably provided with the secondary battery 6805. Note that the solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

In addition, the control device 6807 has a function of controlling the artificial satellite 6800. The control device 6807 is formed using one or more selected from a CPU, a GPU, and a memory device, for example. Note that the semiconductor device according to one embodiment of the present invention is suitably used for the control device 6807. A change in electrical characteristics due to exposure to radiation is smaller in an OS transistor than in a Si transistor. That is, the OS transistor has high reliability and thus can be suitably used even in an environment where radiation can enter.

Alternatively, the artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can have a function of an earth observing satellite, for example.

Note that although the artificial satellite is illustrated as an example of space equipment in this embodiment, the present invention is not limited thereto. The semiconductor device according to one embodiment of the present invention can be suitably used for space equipment such as a spacecraft, a space capsule, or a space probe, for example.

As described above, the OS transistor has excellent effects of achieving wide memory bandwidth and being highly resistant to radiation as compared with the Si transistor.

### [Data Center]

The semiconductor device according to one embodiment of the present invention can be suitably used for, for example, a storage system employed in a data center or the like. Long-term data management, such as a guarantee for data immutability, is required for the data center. The long-term data management needs increasing the scale of the data center, such as installing a storage and a server for storing an enormous amount of data, ensuring a stable power source for data retention, and ensuring cooling equipment required for data retention.

With the use of the semiconductor device according to one embodiment of the present invention for a storage system employed in a data center, electric power required for data retention can be reduced and a semiconductor device that retains data can be downsized. Accordingly, downsizing of the storage system, downsizing of a power source for data retention, downscaling of cooling equipment, and the like can be achieved. Therefore, space saving of the data center can be achieved.

In addition, since the semiconductor device according to one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device according to one embodiment of the present invention can achieve a data center that stably operates even in a high-temperature environment. Thus, the reliability of the data center can be increased.

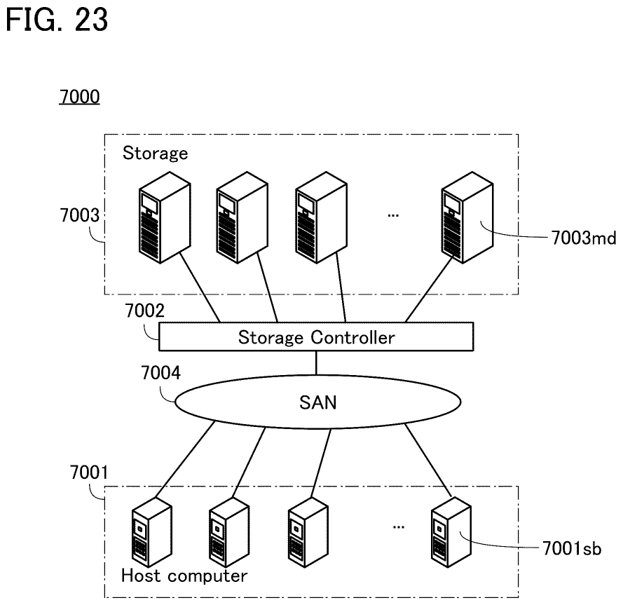

FIG. 23 illustrates a storage system applicable to a data center. A storage system 7000 illustrated in FIG. 23 includes a plurality of servers 7001sb as a host 7001 (indicated as “Host Computer” in the diagram). In addition, the storage system 7000 includes a plurality of memory devices 7003md as a storage 7003 (indicated as “Storage” in the diagram). In the illustrated example, the host 7001 and the storage 7003 are connected through a storage area network 7004 (indicated as “SAN” in the diagram) and a storage control circuit 7002 (indicated as “Storage Controller” in the diagram).

The host 7001 corresponds to a computer that accesses data stored in the storage 7003. The hosts 7001 may be connected to each other through a network.

The data access speed, i.e., the time taken for storing and outputting data, of the storage 7003 is shortened by using a flash memory, but is considerably longer than the data access speed of a DRAM that can be used as a cache memory in a storage. In the storage system, in order to solve the problem of low access speed of the storage 7003, a cache memory is usually provided in a storage to shorten the time taken for storing and outputting data.

The cache memories are used in the storage control circuit 7002 and the storage 7003. Data transmitted between the host 7001 and the storage 7003 are stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

Note that the use of the semiconductor device according to one embodiment of the present invention for one or more selected from an electronic component, an electronic device, a large computer, space equipment, and a data center is expected to produce an effect of reducing power consumption. While the demand for energy is expected to increase with higher performance or higher integration of semiconductor devices, the emission amount of greenhouse effect gases typified by carbon dioxide (CO₂) can be reduced with the use of the semiconductor device according to one embodiment of the present invention. Furthermore, the semiconductor device according to one embodiment of the present invention has low power consumption and thus is effective as a global warming countermeasure.

The configurations, structures, methods, and the like described in this embodiment can be used in combination as appropriate with the configurations, structures, methods, and the like described in the other embodiments.

(Supplementary Notes on the Description in this Specification and the Like)

The description of the above embodiments and each structure in the embodiments are noted below.

One embodiment of the present invention can be constituted by combining, as appropriate, the structure described in each embodiment with the structures described in the other embodiments. In addition, in the case where a plurality of structure examples are described in one embodiment, the structure examples can be combined as appropriate.

Note that content (or may be part of the content) described in one embodiment can be applied to, combined with, or replaced with another content (or may be part of the content) described in the embodiment and/or content (or may be part of the content) described in another embodiment or other embodiments.

Note that in each embodiment, content described in the embodiment is content described using a variety of diagrams or content described with text disclosed in the specification.

Note that by combining a diagram (or may be part thereof) described in one embodiment with another part of the diagram, a different diagram (or may be part thereof) described in the embodiment, and/or a diagram (or may be part thereof) described in another embodiment or other embodiments, much more diagrams can be formed.

In addition, in this specification and the like, components are classified on the basis of the functions, and shown as blocks independent of one another in block diagrams. However, for example, in an actual circuit, it is difficult to separate components on the basis of the functions, and there is such a case where one circuit is associated with a plurality of functions or a case where a plurality of circuits are associated with one function. Therefore, blocks in the block diagrams are not limited by the components described in this specification, and the description can be changed appropriately depending on the situation.

Furthermore, in the drawings, the size, the layer thickness, or the region is shown with given magnitude for description convenience. Therefore, the size, the layer thickness, or the region is not necessarily limited to the illustrated scale. Note that the drawings are schematically shown for clarity, and embodiments of the present invention are not limited to shapes, values or the like shown in the drawings. For example, variation in signal, potential, or current due to noise, variation in signal, potential, or current due to difference in timing, or the like can be included.

Moreover, in this specification and the like, terms for describing arrangement, such as “over” and “under”, are used for convenience for describing the positional relationship between components with reference to drawings. The positional relationship between components changes as appropriate in accordance with the direction in which the components are described. Thus, without limitation to terms described in the specification, the description can be changed appropriately depending on the situation.

In this specification and the like, expressions “one of a source and a drain” (or a first electrode or a first terminal) and “the other of the source and the drain” (or a second electrode or a second terminal) are used in the description of the connection relationship of a transistor. This is because the source and the drain of the transistor change depending on the structure, operating conditions, or the like of the transistor. Note that the source or the drain of the transistor can also be referred to as a source (drain) terminal, a source (drain) electrode, or the like as appropriate depending on the situation.

In addition, in this specification and the like, the term “electrode” or “wiring” does not limit the function of the component. For example, an “electrode” is used as part of a “wiring” in some cases, and vice versa. Furthermore, the term “electrode” or “wiring” also includes the case where a plurality of “electrodes” or “wirings” are formed in an integrated manner, for example.

Furthermore, in this specification and the like, “voltage” and “potential” can be interchanged with each other as appropriate. The voltage refers to a potential difference from a reference potential, and when the reference potential is a ground voltage, for example, the voltage can be rephrased into the potential. The ground potential does not necessarily mean 0 V. Note that potentials are relative values, and a potential applied to, for example, a wiring is sometimes changed depending on the reference potential.

Note that in this specification and the like, the terms such as “film” and “layer” can be interchanged with each other depending on the case or according to circumstances. For example, the term “conductive layer” can be changed into the term “conductive film” in some cases. As another example, the term “insulating film” can be changed into the term “insulating layer” in some cases.

In this specification and the like, a switch has a function of controlling whether current flows or not by being in a conduction state (an on state) or a non-conduction state (an off state). Alternatively, a switch has a function of selecting and changing a current path.

In this specification and the like, channel length refers to, for example, the distance between a source and a drain in a region where a semiconductor (or a portion where current flows in a semiconductor when a transistor is in an on state) and a gate overlap each other or a region where a channel is formed in a plan view of the transistor.

In this specification and the like, channel width refers to, for example, the length of a portion where a source and a drain face each other in a region where a semiconductor (or a portion where current flows in a semiconductor when a transistor is in an on state) and a gate electrode overlap each other or a region where a channel is formed.

In this specification and the like, a node can be referred to as a terminal, a wiring, an electrode, a conductive layer, a conductor, an impurity region, or the like depending on a circuit structure, a device structure, or the like. Furthermore, a terminal, a wiring, or the like can be referred to as a node.

In this specification and the like, the expression “A and B are connected” means the case where A and B are electrically connected. Here, the expression “A and B are electrically connected” means connection that enables electrical signal transmission between A and B in the case where an object (that refers to an element such as a switch, a transistor element, or a diode, a circuit including the element and a wiring, or the like) exists between A and B. Note that the case where A and B are electrically connected includes the case where A and B are directly connected. Here, the expression “A and B are directly connected” means connection that enables electrical signal transmission between A and B through, for example, a wiring (or an electrode), not through the above object. In other words, direct connection refers to connection that can be regarded as the same circuit diagram when indicated as an equivalent circuit.

### REFERENCE NUMERALS

10: semiconductor device, 11: block, 20: layer, 21: reference signal generation circuit, 22: selection signal generation circuit, 23: delay signal generation circuit, 24: row circuit, 25: column circuit, 27: sense amplifier circuit, 30: layer, 31: memory portion, 32: memory cell, 33: selection signal, 35: delay addition circuit, 37: buffer circuit, 41: circuit, 42: multiplexer circuit, 43: flip-flop circuit, 44: through electrode, 45: metal bump, 46: electrode, 47: transistor, 48: electrode, 49: transistor, 51: delay circuit, 53: flip-flop circuit, 55: encoder circuit, 57: inverter circuit, 60: circuit, 61: delay circuit, 63: selection signal, 71: circuit, 73: inverter circuit, 75a: transistor, 75b: transistor, 81: transistor, 82: transistor, 84: transistor, 85: transistor, 86: transistor, 87: transistor, 100: IC chip, 101: package substrate, 102: solder ball, 153: insulator, 156: conductor, 160a: conductor, 160b: conductor, 160: conductor, 161: conductor, 215: conductor, 287: insulator, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 352: insulator, 354: insulator, 356: conductor, 357: insulator, 358: conductor, 360: insulator, 362: insulator, 364: insulator, 366: conductor, 370: insulator, 372: insulator, 374: insulator, 376: conductor, 380: insulator, 382: insulator, 384: insulator, 386: conductor, 400: memory layer, 401: driver circuit layer, 500: transistor, 503a: conductor, 503b: conductor, 503: conductor, 505: conductor, 510: insulator, 512: insulator, 514: insulator, 516: insulator, 518: conductor, 520: insulator, 522: insulator, 524: insulator, 530a: oxide, 530b: oxide, 530: oxide, 540a: conductor, 540b: conductor, 542a: conductor, 542b: conductor, 542: conductor, 543a: region, 543b: region, 544: insulator, 545: insulator, 546: conductor, 548: conductor, 550: transistor, 554: insulator, 560a: conductor, 560b: conductor, 560: conductor, 574: insulator, 580: insulator, 581: insulator, 582: insulator, 586: insulator, 600: capacitance, 610: conductor, 612: conductor, 620: conductor, 630: insulator, 640: insulator, 700: electronic component, 702: printed circuit board, 704: circuit board, 710: semiconductor device, 711: mold, 712: land, 713: electrode pad, 714: wire, 715: driver circuit layer, 716: memory layer, 730: electronic component, 731: interposer, 732: package substrate, 733: electrode, 735: semiconductor device, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic device, 6501: housing, 6502: display portion, 6503: power supply button, 6504: button, 6505: speaker, 6506: microphone, 6507: camera, 6508: light source, 6509: control device, 6600: electronic device, 6611: housing, 6612: keyboard, 6613: pointing device, 6614: external connection port, 6615: display portion, 6616: control device, 6800: artificial satellite, 6801: body, 6802: solar panel, 6803: antenna, 6804: planet, 6805: secondary battery, 6807: control device, 7000: storage system, 7001sb: server, 7001: host, 7002: storage control circuit, 7003md: memory device, 7003: storage

1. A semiconductor device comprising:
a first layer;
a second layer over the first layer; and
a third layer over the second layer,
wherein the first layer comprises a delay signal generation circuit and a row circuit,
wherein the second layer comprises a first delay addition circuit and a first memory portion where first memory cells are arranged in a matrix,
wherein the third layer comprises a second delay addition circuit and a second memory portion where second memory cells are arranged in a matrix,
wherein the delay signal generation circuit is configured to generate a first delay signal representing a first delay time and supply it to the first delay addition circuit and is configured to generate a second delay signal representing a second delay time and supply it to the second delay addition circuit,
wherein the row circuit is configured to generate a row selection signal for selecting the first memory cell or the second memory cell performing reading operation and supply it to the first delay addition circuit or the second delay addition circuit,
wherein the first delay addition circuit is configured to supply the row selection signal supplied to the first delay addition circuit to the first memory portion after the first delay time elapses,
wherein the second delay addition circuit is configured to supply the row selection signal supplied to the second delay addition circuit to the second memory portion after the second delay time elapses, and
wherein the first delay time is longer than the second delay time.

2. A semiconductor device comprising:
a first layer;
a second layer over the first layer; and
a third layer over the second layer,
wherein the first layer comprises a selection signal generation circuit, a delay signal generation circuit, and a row circuit,
wherein the second layer comprises a first selection circuit, a first delay addition circuit, and a first memory portion where first memory cells are arranged in a matrix,
wherein the third layer comprises a second selection circuit, a second delay addition circuit, and a second memory portion where second memory cells are arranged in a matrix,
wherein the selection signal generation circuit is configured to generate a selection signal and supply it to the delay signal generation circuit, the first selection circuit, and the second selection circuit,
wherein the delay signal generation circuit is configured to generate a first delay signal representing a first delay time and is configured to generate a second delay signal representing a second delay time,
wherein the delay signal generation circuit is configured to output one of the first delay signal and the second delay signal on the basis of the selection signal and supply it to the first delay addition circuit and the second delay addition circuit,
wherein the row circuit is configured to generate a row selection signal for selecting the first memory cell or the second memory cell performing reading operation,
wherein the row circuit is configured to supply the row selection signal to the first selection circuit and the second selection circuit,
wherein the first selection circuit is configured to supply the row selection signal to the first delay addition circuit in the case where the delay signal generation circuit outputs the first delay signal,
wherein the second selection circuit is configured to supply the row selection signal to the second delay addition circuit in the case where the delay signal generation circuit outputs the second delay signal,
wherein the first delay addition circuit is configured to supply the row selection signal supplied to the first delay addition circuit to the first memory portion after the first delay time elapses,
wherein the second delay addition circuit is configured to supply the row selection signal supplied to the second delay addition circuit to the second memory portion after the second delay time elapses, and
wherein the first delay time is longer than the second delay time.

3. The semiconductor device according to claim 1,
wherein the first layer comprises a reference signal generation circuit,
wherein the second layer comprises a first buffer circuit,
wherein the third layer comprises a second buffer circuit,
wherein the reference signal generation circuit is configured to generate a reference signal and supply it to the delay signal generation circuit, the first buffer circuit, and the second buffer circuit,
wherein the first buffer circuit is configured to supply the reference signal supplied to the first buffer circuit to the delay signal generation circuit as a first delay time detection signal,
wherein the second buffer circuit is configured to supply the reference signal supplied to the second buffer circuit to the delay signal generation circuit as a second delay time detection signal,
wherein the delay signal generation circuit is configured to generate a first digital signal representing a difference between a first moment when the reference signal is input and a second moment when the first delay time detection signal is input and generate the first delay signal on the basis of the first digital signal, and
wherein the delay signal generation circuit is configured to generate a second digital signal representing a difference between the first moment and a third moment when the second delay time detection signal is input and generate the second delay signal on the basis of the second digital signal.

4. The semiconductor device according to claim 3,
wherein the delay signal generation circuit comprises a first inverter circuit and a second inverter circuit,
wherein the first inverter circuit is configured to generate the first delay signal in the case where the first digital signal is supplied to the first inverter circuit, and
wherein the second inverter circuit is configured to generate the second delay signal in the case where the second digital signal is supplied to the second inverter circuit.

5. The semiconductor device according to claim 1,
wherein the delay signal generation circuit comprises a first transistor,
wherein the first memory cell comprises a second transistor,
wherein the second memory cell comprises a third transistor,
wherein the first transistor comprises silicon in a channel formation region, and
wherein the second transistor and the third transistor each comprise metal oxide in a channel formation region.

6. A semiconductor device comprising:
a first block; and
a second block,
wherein the first block comprises a first layer, a second layer over the first layer, and a third layer over the second layer,
wherein the second block comprises a fourth layer, a fifth layer over the fourth layer, and a sixth layer over the fifth layer,
wherein the first layer comprises a first delay signal generation circuit and a first row circuit,
wherein the second layer comprises a first delay addition circuit and a first memory portion where first memory cells are arranged in a matrix,
wherein the third layer comprises a second delay addition circuit and a second memory portion where second memory cells are arranged in a matrix,
wherein the fourth layer comprises a second delay signal generation circuit and a second row circuit,
wherein the fifth layer comprises a third delay addition circuit and a third memory portion where third memory cells are arranged in a matrix,
wherein the sixth layer comprises a fourth delay addition circuit and a fourth memory portion where fourth memory cells are arranged in a matrix,
wherein the first delay signal generation circuit is configured to generate a first delay signal representing a first delay time and supply it to the first delay addition circuit and is configured to generate a second delay signal representing a second delay time and supply it to the second delay addition circuit,
wherein the second delay signal generation circuit is configured to generate a third delay signal representing a third delay time and supply it to the third delay addition circuit and is configured to generate a fourth delay signal representing a fourth delay time and supply it to the fourth delay addition circuit,
wherein the first row circuit is configured to generate a first row selection signal for selecting the first memory cell or the second memory cell performing reading operation and supply it to the first delay addition circuit or the second delay addition circuit,
wherein the second row circuit is configured to generate a second row selection signal for selecting the third memory cell or the fourth memory cell performing reading operation and supply it to the third delay addition circuit or the fourth delay addition circuit,
wherein the first delay addition circuit is configured to supply the first row selection signal supplied to the first delay addition circuit to the first memory portion after the first delay time elapses,
wherein the second delay addition circuit is configured to supply the first row selection signal supplied to the second delay addition circuit to the second memory portion after the second delay time elapses,
wherein the third delay addition circuit is configured to supply the second row selection signal supplied to the third delay addition circuit to the third memory portion after the third delay time elapses,
wherein the fourth delay addition circuit is configured to supply the second row selection signal supplied to the fourth delay addition circuit to the fourth memory portion after the fourth delay time elapses,
wherein the first delay time is longer than the second delay time, and
wherein the third delay time is longer than the fourth delay time.

7. (canceled)

8. The semiconductor device according to claim 6,
wherein the first layer comprises a first reference signal generation circuit,
wherein the second layer comprises a first buffer circuit,
wherein the third layer comprises a second buffer circuit,
wherein the fourth layer comprises a second reference signal generation circuit,
wherein the fifth layer comprises a third buffer circuit,
wherein the sixth layer comprises a fourth buffer circuit,
wherein the first reference signal generation circuit is configured to generate a first reference signal and supply it to the first delay signal generation circuit, the first buffer circuit, and the second buffer circuit,
wherein the second reference signal generation circuit is configured to generate a second reference signal and supply it to the second delay signal generation circuit, the third buffer circuit, and the fourth buffer circuit,
wherein the first buffer circuit is configured to supply the first reference signal supplied to the first buffer circuit to the first delay signal generation circuit as a first delay time detection signal,
wherein the second buffer circuit is configured to supply the first reference signal supplied to the second buffer circuit to the first delay signal generation circuit as a second delay time detection signal,
wherein the third buffer circuit is configured to supply the second reference signal supplied to the third buffer circuit to the second delay signal generation circuit as a third delay time detection signal,
wherein the fourth buffer circuit is configured to supply the second reference signal supplied to the fourth buffer circuit to the second delay signal generation circuit as a fourth delay time detection signal,
wherein the first delay signal generation circuit is configured to generate a first digital signal representing a difference between a first moment when the first reference signal is input and a second moment when the first delay time detection signal is input and generate the first delay signal on the basis of the first digital signal,
wherein the first delay signal generation circuit is configured to generate a second digital signal representing a difference between the first moment and a third moment when the second delay time detection signal is input and generate the second delay signal on the basis of the second digital signal,
wherein the second delay signal generation circuit is configured to generate a third digital signal representing a difference between a third moment when the second reference signal is input and a fourth moment when the third delay time detection signal is input and generate the third delay signal on the basis of the third digital signal, and
wherein the second delay signal generation circuit is configured to generate a fourth digital signal representing a difference between the third moment and a fourth moment when the fourth delay time detection signal is input and generate the fourth delay signal on the basis of the fourth digital signal.

9. The semiconductor device according to claim 8,
wherein the first delay signal generation circuit comprises a first inverter circuit and a second inverter circuit,
wherein the second delay signal generation circuit comprises a third inverter circuit and a fourth inverter circuit,
wherein the first inverter circuit is configured to generate the first delay signal in the case where the first digital signal is supplied to the first inverter circuit,
wherein the second inverter circuit is configured to generate the second delay signal in the case where the second digital signal is supplied to the second inverter circuit,
wherein the third inverter circuit is configured to generate the third delay signal in the case where the third digital signal is supplied to the third inverter circuit, and
wherein the fourth inverter circuit is configured to generate the fourth delay signal in the case where the fourth digital signal is supplied to the fourth inverter circuit.

10. The semiconductor device according to claim 6,
wherein the first delay signal generation circuit comprises a first transistor,
wherein the first memory cell comprises a second transistor,
wherein the second memory cell comprises a third transistor,
wherein the second delay signal generation circuit comprises a fourth transistor,
wherein the third memory cell comprises a fifth transistor,
wherein the fourth memory cell comprises a sixth transistor,
wherein the first transistor and the fourth transistor each comprise silicon in a channel formation region, and
wherein the second transistor, the third transistor, the fifth transistor, and the sixth transistor each comprise metal oxide in a channel formation region.

11. The semiconductor device according to claim 6,
wherein a timing when the first row circuit outputs the first row selection signal and a timing when the second row circuit outputs the second row selection signal are synchronized.

12. The semiconductor device according to claim 2,
wherein the first layer comprises a reference signal generation circuit,
wherein the second layer comprises a first buffer circuit,
wherein the third layer comprises a second buffer circuit,
wherein the reference signal generation circuit is configured to generate a reference signal and supply it to the delay signal generation circuit, the first buffer circuit, and the second buffer circuit,
wherein the first buffer circuit is configured to supply the reference signal supplied to the first buffer circuit to the delay signal generation circuit as a first delay time detection signal,
wherein the second buffer circuit is configured to supply the reference signal supplied to the second buffer circuit to the delay signal generation circuit as a second delay time detection signal,
wherein the delay signal generation circuit is configured to generate a first digital signal representing a difference between a first moment when the reference signal is input and a second moment when the first delay time detection signal is input and generate the first delay signal on the basis of the first digital signal, and
wherein the delay signal generation circuit is configured to generate a second digital signal representing a difference between the first moment and a third moment when the second delay time detection signal is input and generate the second delay signal on the basis of the second digital signal.

13. The semiconductor device according to claim 12,
wherein the delay signal generation circuit comprises a first inverter circuit and a second inverter circuit,
wherein the first inverter circuit is configured to generate the first delay signal in the case where the first digital signal is supplied to the first inverter circuit, and
wherein the second inverter circuit is configured to generate the second delay signal in the case where the second digital signal is supplied to the second inverter circuit.

14. The semiconductor device according to claim 2,
wherein the delay signal generation circuit comprises a first transistor,
wherein the first memory cell comprises a second transistor,
wherein the second memory cell comprises a third transistor,
wherein the first transistor comprises silicon in a channel formation region, and
wherein the second transistor and the third transistor each comprise metal oxide in a channel formation region.
